(19) United States
(12) Patent Application Publication
(10) Pub. No.: US 2005/0201439 A1
(43) Pub. Date: Sep. 15, 2005

(54) Semiconductor light emitting device and semiconductor light emitting device module

(75) Inventor: Hideyoshi Horie, Ushiku-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI CHEMICAL CORPORATION, Minato-ku (JP)

(21) Appl. No.: 11/072,273

(22) Filed: Mar. 7, 2005

Related U.S. Application Data
(63) Continuation of application No. PCT/JP03/11351, filed on Sep. 5, 2003.

(30) Foreign Application Priority Data
Sep. 6, 2002 (JP) 2002-260863
Sep. 6, 2002 (JP) 2002-260864
Sep. 6, 2002 (JP) 2002-260865

(51) Int. Cl. H01S 5/00

(52) U.S. Cl. 372/43.01

(57) ABSTRACT

A semiconductor light emitting device capable of easy optical coupling to an optical fiber, etc. and excellent in high power operation characteristics is disclosed. The semiconductor light emitting device is provided by controlling the relation between the thickness and the refractive index of a clad layer and an optical guide layer.

The present application is a continuation of PCT/JP2003/011351 with a filing date of Sep. 5, 2003, which claims the priority from Japanese Patent Application No. 260863/2002 filed on Sep. 6, 2002, Japanese Patent Application No. 260864/2002 filed on Sep. 6, 2002, and Japanese Patent Application No. 260865/2002 filed on Sep. 6, 2002.

### BACKGROUND OF THE INVENTION

1. Field of the Invention

The present invention relates to a semiconductor light emitting device. The invention can be utilized suitably in a case where high coupling efficiency to an optical system is desired such as an excitation light source for an optical fiber amplifier, a light source for optical information processing and a semiconductor laser for medical use.

2. Description of the Related Art

Remarkable progress has been made in recent technologies in optical information processing and optical communication.

For example, in the field of electro- and/or optical-communication, vigorous studies have been made in large capacity optical fiber communication systems for future information transmission, as well as optical fiber amplifiers doped with rare earth element such as Er³⁺ (EDFA) as signal amplifiers having flexibility to the transmission methods. Then, it is desired to develop an excellent semiconductor laser for an excitation light source, which is an indispensable element as a component of EDFA.

As the oscillation wavelength of the excitation light source that can be served to the EDFA application, there are three kinds of wavelengths, i.e., 800 nm, 980 nm and 1480 nm in principle. It has been known that excitation at 980 nm is most desirable among them, in view of the characteristics of amplifiers when gains and/or noise figures are taken into consideration. It has been demanded for such semiconductor lasers (LD) having an oscillation wavelength at 980 nm to satisfy conflicting characteristics that they have long life while providing high power as the excitation light source. Further, since it is also essential for the excitation light source for optical amplifiers to attain good coupling efficiency to optical fibers, single transverse-mode oscillation is generally desired. Accordingly, in a case of high power operation, worsening of the device life characteristics by the effect of heat generation is worried particularly. Further, since the optical density during high power operation is extremely high, undesired effect caused by light is not negligible.

For example, in most of 980 nm band LDs reported so far, AlGaAs material systems are used for clad layers and optical guide layers, while InGaAs material systems are used for active layers. In this case, the Al composition in AlGaAs clad layer was usually larger than about 0.40 in most of LDs. 980 nm band LDs with the Al composition in the clad layer of 0.6 are described for example, by M. Okayasu, et al., in Electronics Letters, vol. 25, No. 23 (1989) p. 1563 or R. J. Fu, et al., IEEE Photonics Technology Letters, vol. 3, No. 4 (1991) p. 308. Further, 980 nm band LDs with the Al composition in the clad layer of 0.48 are described by A. Shima, et al., in IEEE Journal of Elected Topics in Quantum Electronics, vol. 1, No. 2 (1995) p. 102. Such Al composition of the clad layer are selected in order to attain a sufficient optical confinement between the active layer and the clad layer, and ensure a band offset between the optical guide layer and the clad layer.

On the other hand, however, LDs having such AlGaAs clads involve the following problems.

As pointed out by M. A, Afomowitz, in Journal of Applied Physics, vol. 44, No. 3 (1973) p. 1292, thermal resistivity of AlGaAs material systems is maximum as about 8 cm·deg/watt at an Al composition of about 0.5. On the other hand, thermal resistivity of GaAs or AlAs is about from ¼ to ⅕. It can be said that the LDs described above have a structure of using a material having the highest thermal resistivity among the AlGaAs material systems for the clad layer which is most thick in the constituent elements with the view point described above. That is, such existent LDs can not always be said to have a structure suitable for high power operation.

In view of the technical situations described above, it is a main object of the present invention to provide a semiconductor light emitting device capable of easy optical coupling to optical fibers or the like and excellent in high power operation characteristics (main object).

Further, it is a subordinate object of the invention to provide a semiconductor light emitting device in which a main layer constituent portion of the semiconductor light emitting device is constituted with a material having a relatively excellent heat conducting property, while moderating the extremely high optical density during high power operation, as well as attain the decrease of extremely high current injection density during high power operation (first subordinate object).

By the way, it is desired for the far field pattern (the FFP) of a light emitted from a semiconductor laser that the vertical/horizontal ratio in the direction vertical to a substrate (vertical direction) and the direction parallel with the substrate (horizontal direction) is nearly 1 and further that the absolute value for a radiation angle is also narrow. While semiconductor lasers have been applied variously in the field of communication, SHG light sources, heat sources for laser printers, and medical field, lights emitted from semiconductor lasers are often coupled to various kinds of optical systems also in such fields, and it is an extremely important characteristic that the value for the FFP in the vertical direction and the value for the FFP in the horizontal direction are narrow and that the vertical/horizontal ratio is nearly 1.

In a semiconductor laser designed to allow propagation only in the fundamental-mode with respect to the vertical direction, that is, a semiconductor laser with the normalized frequency in the vertical direction of π/2 or less, optical confinement is extremely different between the vertical direction and the horizontal direction. In the optical confinement along the horizontal direction, since the width for the current injection region is from several μm to several hundreds μm and the waveguide structure also has about the same extent of size, it is relatively wide generally compared with the oscillation wavelength and the effect of diffraction is relatively small generally for the FFP (the FFP_{H}) in the horizontal direction of an emitted light to the emission pattern near the facet (near field pattern; NFP). On the contrary, since the optical confinement in the vertical direction is attained by an active layer structure which is extremely thinner than the oscillation wavelength, an extreme effect of diffraction generally appears to the FFP (the FFP_{V}) in the vertical direction of the emitted light and the full width of the half maximum of the FFP_{V} is usually wider than that of the FFP_{H}. Accordingly, in order to improve the coupling characteristic to an external optical system, it is desired to narrow the effective full width of the half maximum of the FFP_{V}.

Further, if the semiconductor laser as described above can be attained, since the size for NFP in the vertical direction (NFP_{V}) is expanded, it is considered that the optical density at the facet is lowered and the high power operation characteristics of the semiconductor laser are also improved.

As discussed in Hetero-structure Lasers written by H. C. Casey, Jr., M. B. Panish (Academic Press, 1978), Chapter 2, it is known that the FFP_{V} depends on the thickness of the active layer or the optical guide layer. However, even when a semiconductor laser of narrow FFP_{V} is attained by the method of merely decreasing the thickness thereof, it results in a problem of worsening other device-characteristics.

In view of the technical situations described above, the present invention secondarily intends to decrease the full width of the half maximum of the FFP effectively without extremely worsening the important characteristics of the semiconductor laser, attain good coupling between an optical system constituted with an optical fiber and lens, and also improve high power operation characteristics of the semiconductor laser per se (secondary subordinate object).

### SUMMARY OF THE INVENTION

The present inventors have made earnest studies and, as a result, have found that the main object can be attained by a semiconductor light emitting device according to the present invention.

The semiconductor light emitting device of a light emission wavelength λ (nm) according to the invention has a structure in which at least a first-conduction-type first clad layer, a first-conduction-type second clad layer, an active layer structure, a second-conduction-type second clad layer, and a second-conduction-type first clad layer are formed in this order on a first-conduction-type substrates and is characterized by satisfying at least one of the following conditions 1 to 3.

<Condition 1>

The first-conduction-type first clad layer is an AlₓₙGa₁₋ₓₙAs layer (0<xn<0.40) at a thickness of tₓₙ (nm),
the first-conduction-type second clad layer is an AlₓₙGa₁₋ₓₙAs layer (0<xn<1) at a thickness of tₓₙ (nm),
a first optical guide layer at a thickness of t_{gn} (nm) comprising Al_{gn}Ga_{1-gn}As layer (0≦gn<0.40) is present between the first-conduction-type second clad layer and the active layer structure,
the second optical guide layer at a thickness of t_{gp} (nm) comprising Al_{gp}Ga_{1-gp}As layer (0≦gp<0.40) between the active layer structure and second-conduction-type second clad layer,
the second-conduction-type second clad layer is an AlₛₚGa₁₋ₛₚAs layer (0<sp≦1) at a thickness of tₛₚ (nm),
a second-conduction-type first clad layer is an AlₓₚGa₁₋ₓₚAs layer (0<xp<0.40) at a thickness of tₓₚ (nm), and the following formulae are satisfied:
   gn<xn<sn gp<xp<sp
   0.08<sn−xn 0.08<sp−xp
   tₛₙ/t_{gn}<1.0 tₛₚ/t_{gp}<1.0
   <Condition 2>

The semiconductor light emitting device is a semiconductor laser in which
only the fundamental-mode propagation is allowed with respect to the vertical direction,
the radiation pattern of a light emitted from a semiconductor laser having a main peak with a maximum intensity of I_{Vmain} and two sub peaks with maximal intensities of I_{Vsub-} and I_{Vsub+} respectively are present in the far field pattern in the vertical direction to the substrate (the FFP_{V}), and
the following formula is satisfied:
   0<I_{Vsub}/I_{Vmain}<0.5
   wherein I_{Vsub} represents I_{Vsub-} or I_{Vsub+} which has a higher intensity;
   <Condition 3>

The first-conduction-type first clad layer has an average refractive index nₙ₁ and a thickness of tₙ₁ (nm),
the first-conduction-type second clad layer has an average refractive index nₙ₂ and a thickness of tₙ₂ (nm),
a first optical guide layer with an average refractive index of n_{ng} and a thickness of t_{ng} (nm) is present between the first-conduction-type second clad layer and the active layer structure,
the active layer structure has an average refractive index nₐ and the total thickness of tₐ (nm),
a second optical guide layer with an average refractive index n_{pg} and at a thickness of t_{pg} (nm) is present between the active layer structure and the second-conduction-type second clad layer,
the second-conduction-type second clad layer has an average refractive index nₚ₂ and a thickness of tₚ₂ (nm),
the second-conduction-type first clad layer has an average refractive index nₚ₁ and a thickness of tₚ₁ (nm) and, in a case where the wave number k, Vₙ, Vₚ, and Rₙ and Rₚ are defined as (formulae 1):
   k=2π/λ
   Vₙ=k/2×(tₐ+t_{ng}+t_{pg})×(n_{ng}²−nₙ₁²)^{1/2}
   Vₚ=k/2×(tₐ+t_{ng}+t_{pg})×(n_{pg}²−nₚ₁²)^{1/2}
   Rₙ=tₙ₂/t_{ng}
   Rₚ=tₚ₂/t_{pg} (formulae 1)
   each of the relations for (formulae 2) is satisfied:
   nₙ₂<nₙ₁<n_{ng}<nₐ
   nₚ₂<nₚ₁<n_{pg}<nₐ
   0.35<Vₙ<0.75
   0.35<Vₚ<0.75
   0.3<Rₙ<0.7
   0.3<Rₚ<0.7 (formulae 2)

The semiconductor light emitting device of the invention satisfying the condition 1 can particularly attain the first subordinate object effectively, and the semiconductor light emitting device of the invention satisfying the condition 2 and the semiconductor light emitting device of the invention satisfying the condition 3 can particularly attain the secondary subordinate object, effectively.

The semiconductor light emitting device of the invention preferably satisfies two or more of the conditions 1 to 3 and, more preferably, satisfies all the conditions 1 to 3.

### BRIEF DESCRIPTION OF DRAWINGS

FIG. 1 is a cross sectional view showing an embodiment of a semiconductor light emitting device according to the present invention from the light emitting direction.

FIG. 2 is a cross sectional view showing an embodiment of a semiconductor light emitting device according to the present invention from the light emitting direction.

FIG. 3 is a perspective view showing an embodiment of a semiconductor light emitting device according to the invention.

FIG. 4 is a view explaining the definition for the position of the FFP.

FIG. 5 is a cross sectional view showing an embodiment of a semiconductor light emitting device according to the present invention from the light emitting direction.

FIG. 6 is a chart showing the FFP_{V} of an existent semiconductor light emitting device.

FIG. 7 is a chart showing the FFP_{V} of a light emitting device according to the invention.

FIG. 8 is a cross sectional view showing an embodiment of a semiconductor light emitting device according to the present invention from the light emitting direction.

FIG. 9 is a cross sectional view showing an embodiment of a semiconductor light emitting device according to the present invention from the light emitting direction.

FIG. 10 is a cross sectional view showing an embodiment of a semiconductor light emitting device according to the present invention from the light emitting direction.

FIG. 11 is a graph comparing the current-light output power characteristics of a semiconductor light emitting devices for Example 1 and Comparative Example 1.

FIG. 12 is a graph comparing a relation between the driving time and the driving current in semiconductor light emitting devices for Example 1 and Comparative Example 1.

FIG. 13 is a graph showing current-light output power characteristics of a semiconductor light emitting device for Example 3.

### BEST MODE FOR CARRYING OUT THE INVENTION

At first, several expressions used in the present specification are to be described.

In the present specification, the expression “a B layer formed over an A layer” includes both a case where the B layer is formed such that the bottom of the B layer is in contact with the upper surface of the A layer and a case where one or more layer is formed on the upper surface of the A layer, and the B layer is formed further on the layer. In addition, the expression also includes a case where the upper surface of the A layer and the bottom of the B layer are in partially in contact with each other and one or more layer is present in other portions between the A layer and the B layer. Specific embodiments are apparent from the following descriptions for each of the layers and specific examples for the examples.

Further, the refractive index for each of the layers in the present specification basically means a refractive index at the oscillation wavelength of the device. However, since the oscillation wavelength per se changes depending on the driving temperature, the light output power, etc. of the device, the wavelength for defining the refractive index is sometimes represented by a specified wavelength near the oscillation wavelength. This content will be also apparent from specific examples for examples, etc.

Further, in a case where a single function is provided by plural layers, this is sometimes indicated by a single nomination in which the refractive index or the like is defined according to an average refractive index. For example, in a case where a clad layer comprises layers by the number of m and the nₜₕ layer has a refractive index n, and a thickness of tₙ (nm), the average refractive index nₘₑₐₙ of the clad layer is defined according to the following formula:
nₘₑₐₙ=(n₁t₁+n₂t₂+ . . . +nₘtₘ)/(t₁+t₂+ . . . +tₘ)

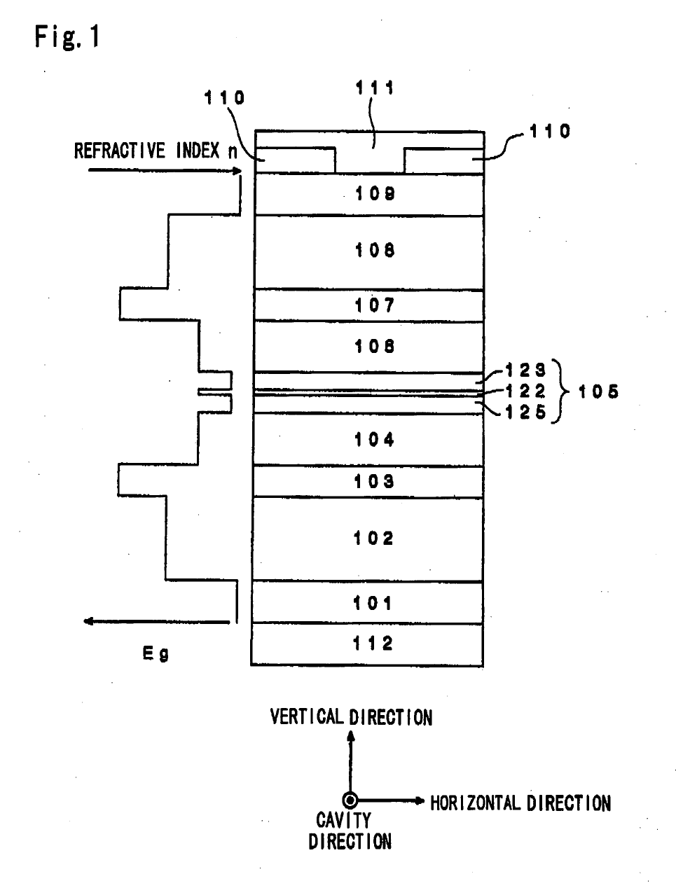

Further, in the present invention, the direction vertical to the substrate is defined as the vertical direction and the direction parallel with the substrate is defined as a horizontal direction as illustrated in a lower side of FIG. 1.

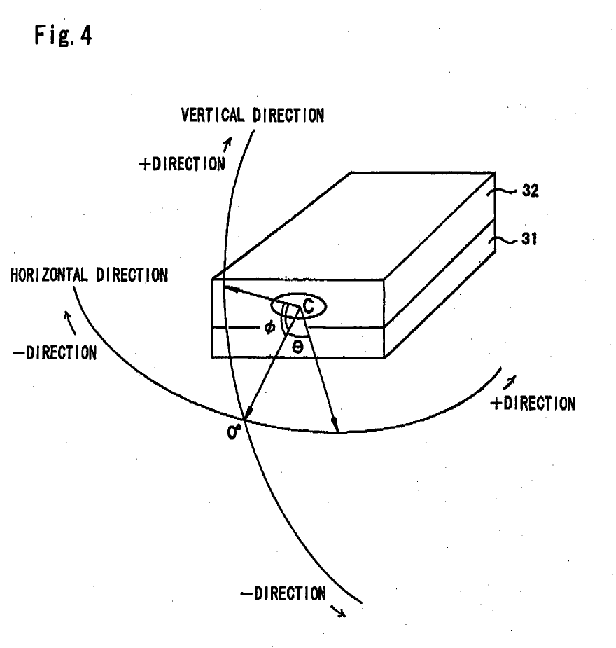

Further, the definition for the position of the FFP, when it is described, is in accordance with a usual method also in the present specification. This is to be described with reference to FIG. 4. At first, two circles each in the vertical direction and the horizontal direction to the substrate and intersecting each other are assumed. Further, the device is situated such that the center of each of the two circles is at the light emission center C in view of the device structure. In this case, the point at which a line extended in the physically vertical direction from the light emission center C in view of the device structure intersects the arcs of the two circles defines 0 degree when the FFP is described. That is, with the point as the original, the position for describing the FFP is defined by the angle formed by the line connecting the 0 degree and the light emission center in view of the device structure formed with respect to each of the arcs. FIG. 1 shows the position where vertical the FFP is at +φ degree and horizontal FFP is at +θ degree. The intensity distribution of light plotted as a function for the position defined by the angles is the FFP itself. The directions for “+”, “−” shown in the drawing are relative and the directions may be reversed generally.

The range for numeral values represented by using “to” in the present specification means a range including numerical values described before and after “to” as a lower limit value and an upper limit value. Further, while the sizes of the drawings appended to the present specification are intentionally changed in some portions for easy understanding of the constitution of the invention but actual sizes are as described in the present specification.

Preferred examples for constitution of the semiconductor light emitting device according to the invention and manufacturing method thereof are to be described specifically.

Semiconductor Light Emitting Device Satisfying Condition 1

At first, main features of a semiconductor light emitting device according to the invention satisfying the condition 1 are to be described with reference to an LD shown in FIG. 1. FIG. 1 shows the spatial distribution in the vertical direction of the refractive index obtained by the structure for each of the layers on the left thereof and FIG. 1 shows the designation for the directions used in the drawings on the lower side thereof.

FIG. 1 shows a broad area type LD constituted, on an n-type substrate (101), with an n-type first clad layer (102) comprising AlₓₙGa₁₋ₓₙAs at a thickness of tₓₙ (nm), an n-type second clad layer (103) comprising AlₛₙGa₁₋ₛₙAs at a thickness of tₛₙ (nm), a first optical guide layer (104) comprising undoped Al_{gn}Ga_{1-gn}As at a thickness of t_{gn} (nm), an active layer structure (105), a second optical guide layer (106) comprising undoped Al_{gp}Ga_{1-gp}As at a thickness of t_{gp} (nm), a p-type second clad layer (107) comprising AlₛₚGa₁₋ₛₚAs at a thickness of tₛₚ (nm), and a p-type first clad layer (108) comprising AlₓₚGa₁₋ₓₚAs at a thickness of tₓₚ (nm), and a contact layer (109) for lowering the contact resistance with an electrode, as well as an SiN layer (110) for restricting the current injection region relative to the horizontal direction, a p-side electrode (111) and an n-side electrode (112). The LD in FIG. 1 satisfies the following formulae.
xn=xp=x tₓₙ=tₓₚ=tₓ
sn=sp=s tₛₙ=tₛₚ=tₛ
gn=gp=g t_{gn}=t_{gp}=t_{g}

Further, the active layer structure (105) has a strained double quantum well structure in which an In_{0.16}Ga_{0.84}As strained quantum well layer (121) of 6 nm thickness, a GaAs barrier layer (122) of 8 nm thickness and an In_{0.16}Ga_{0.84}As strained double quantum well layer (123) of 6 nm thickness are stacked from the side of the substrate and the oscillation wavelength thereof is λ (nm).

The confinement of light in the vertical direction to the active layer structure (105) as the base of the optical confinement of LD is attained by the difference of the refractive index between two AlₓGa₁₋ₓAs first clad layers (102, 108) situated above and below the active layer and two Al_{g}Ga_{1-g}As optical guide layers (104, 106) including the active layer structure (105). In the invention, it is necessary that the Al composition x in the first clad layer (102, 108) comprising AlₓGa₁₋ₓAs is less than 0.4 and, preferably, less than 0.3 and, more preferably, less than 0.2. This is because thermal resistance of the entire device can be lowered to attain a structure suitable, for high power operation by decreasing the Al composition in the clad layer which is most thick in the LD constituent layers except for the substrate (101) and the contact layer (109).

The thickness for the first clad layer (102, 108) preferably satisfies the following formula relative to the oscillation wavelength λ (nm) since it is necessary to decay the light sufficiently in the direction that the layer recedes from the side of the active layer.
λ<tₓ

Particularly, in a case where the substrate (101) is transparent to the oscillation wavelength and has a refractive index larger than that of the n-type first clad layer (101) and the n-type second clad layer (103) as in a 980 nm band LD, since the light leaked from the clad layer (102, 103) to the substrate (101) propagates through the substrate, it is known that the substrate-mode overlaps the mode of the LD per se and, in order to suppress this, it is desirable to make the thickness for the n-type clad layer (102) thicker relative to the wavelength.

Further, for attaining the optical confinement, it is necessary that the optical guide layer (104, 106) is constituted with a material having a larger refractive index than that of the first clad layer (102, 108), that is, with a smaller Al composition than that of the first clad layer (102, 108). Further, it is necessary that the Al composition is less than 0.4 also in the optical guide layer (104, 106) and it is preferably less than 0.2 and, more preferably, less than 0.1. Most preferred is a case of using GaAs not containing Al. Particularly in view of the reliability, an optical guide layer not containing Al is desired. Further, the thickness t_{g} (nm) of the optical guide layer (104, 106) preferably satisfies the following formula in order that the second clad layer (103, 107) to be described later can provide the function sufficiently.
0.5×[/λ(4×n_{g})]nm<t_{g}<1.5×[λ/(4×n_{g})]nm

In the relation, n_{g} is a refractive index of the optical guide layer (104, 106). By restricting the thickness t_{g} for the optical guide layer (103, 106) to less than the upper limit of the formula described above, it is possible to particularly provide the overflow suppressing effect of carriers in the second clad layer (103, 107) to be described later, as well as effectively avoid lowering of the kink level, etc. Further, by controlling the thickness t_{g} of the optical guide layer (104, 106) to larger than the lower limit in the formula described above, it is possible to suppress excessive anti-waveguide property of the second clad layer (103, 107) to be described later.

In a case where a usual SCH structure (Separated Confinement Hetero-structure) is constituted with an AlGaAs material system, the first clad layer and the optical guide layer is in direct contact to each other. However, the invention has a feature in that second clad layers (103, 107) comprising Al_{g}Ga_{1-g}As with a thickness of t_{g} are present between the layers. It is necessary for the layer that the Al composition is set higher than that of the optical guide layer (104, 106) and, further, the first clad layer (102, 108) and it satisfies the following formula:
g<x<s.

As a result, as shown on the left of FIG. 1, the second clad layer (103, 107) is a layer having the smallest value for the refractive index. The direction of the arrow shown below “n” means a direction along which the refractive index increases. Further, the second clad layer (103, 107) has a function forming a barrier to electrons on the side of the conduction band (or also for holes in the valence band although not illustrated). The direction of the arrow shown above Eg means a direction along which the potential increases relative to electrons.

That is, the second clad layer (103, 107) has a function of suppressing thermal leakage (overflow) of carriers from the In_{0.16}Ga_{0.84}As strained quantum well layer (121, 123) to the first clad layer (102, 108) in a case, for example, where the LD is driven at high temperature or in a case where the temperature of the active layer increases considerably by the self heat generation of the LD during high power operation. In the invention, for decreasing thermal resistance of the entire device, it is at first important that the Al composition in the first clad layer (102, 108) is less than 0.4, preferably, less than 0.3 and, more preferably, less than 0.2 as described above. For this purpose, in the AlₛGa₁₋ₛAs second clad layer (103, 107), the Al composition is selected from the range such that it is more than 0 and equal to or less than 1 so as to compensate the low barrier height between the optical guide layer (104, 106) and the first clad layer (102, 108) in view of carriers that leak from the active layer structure (105) through the optical guide layer (104, 106). However, also in the second clad layer (103, 107), it is desired that the Al compositions is less than 0.5 in view of thermal resistance, or with an aim of avoiding oxidation deterioration generally observed in the AlGaAs material systems of higher Al composition and, thus, worsening of the device life. Further, for suppressing the overflow of carriers from the active layer structure (105) to the first clad layer (102, 108) sufficiently by the second clad layer (103, 107) within a range up to about 100° C. at which the semiconductor laser is usually used, it is necessary to satisfy the following formula:
0.08<s−x

However, since an extremely large barrier height inhibits injection of carriers injected from the first clad layer to the active layer structure, it is preferred to satisfy the following formula:
s−x<0.4

Further, the second clad layer (103, 107) has an extremely important function with respect to the optical confinement in the vertical direction as described below. Since AlₛGa₁₋ₛAs of lower refractive index than that of the optical guide layer (104, 106) and, further, than that of the first clad layer (102, 10B) is selected for the second clad layer (103, 107) as described above, the near field pattern (NFP) in the vertical direction at the LD facet is expanded to decrease the optical density and narrow the far field pattern (the FFP) and, thus, it is possible to make the device suitable for the high power operation and also expect the improvement for the life characteristics.

The second clad layer (103, 107) provides a function of expand the distribution of light to the outside of the layer in view of the relative refractive index as described above. Therefore, the near field pattern in the vertical direction at the LD facet is expanded in the vertical direction to lower the optical density, and this is extremely desirable in view of the high power operation. However, since extreme lowering of the refractive index or extreme increase of the thickness for the second clad layer (103, 107) is not desired because the waveguide exhibits excessively anti-waveguide property and the optical confinement in the vertical direction in the LD structure becomes excessively weak, to result in excessive increase of the threshold current, lowering of the slope efficiency, increase of the drive current, etc. Accordingly, the thickness tₛ for the second clad layer (103, 107) has to satisfy the following formula in view of the relative relation with the thickness t_{g} for the optical guide layer (104, 106).
tₛ/t_{g}<1.0

Further, in order to obtain the NFP expanding effect in the vertical direction appropriately, it is preferred to satisfy the following formula.
0.3<tₛ/t_{g}

Further, in the second clad layer (103, 107), it is desirable to satisfy not only the relative relation for the thickness to the optical guide layer (104, 106) but also the following formula as the absolute value.
10 nm<tₛ<100 nm

This is because the optical effect is reduced particularly in a case where the second clad layer (103,107) is extremely thin and the optical confinement is weakened extremely in a case where the layer is excessively thick and the LD oscillates no more.

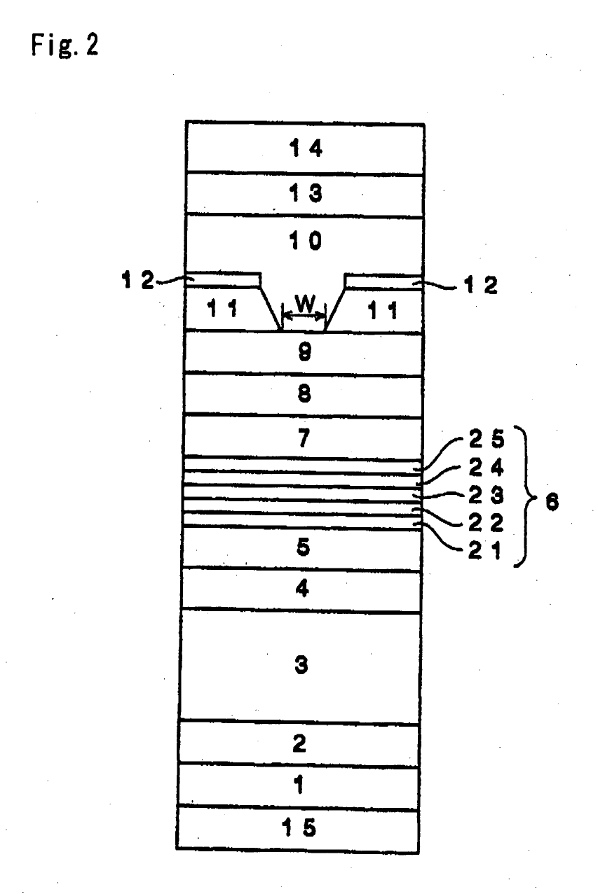

Next, a semiconductor laser capable of single transverse-mode operation as an example of a semiconductor light emitting device according to the invention satisfying the condition 1 is to be described with reference to FIG. 2. FIG. 2 is a schematic cross sectional view showing the constitution of a buried-stripe type semiconductor laser as an example of an epitaxial structure in the semiconductor laser according to the invention.

The semiconductor laser is formed over the semiconductor substrate (1) and has a refractive-index-guided structure in which the second-conduction-type first clad layer consists of two layers of a second-conduction-type upper first clad layer (10) and a second-conduction type lower first clad layer (9), the second-conduction-type upper first clad layer (10) and a current block layer (11)/cap layer (12) form a current injection region and, further, has a contact layer (13) for lowering the contact resistance with an electrode. For the manufacturing methods of basic epitaxial structures of various lasers including this example, JP-A No. 8-130344, etc. can be referred to. The laser of this type is used as a light source for optical fiber amplifiers used in optical communication and a pick-up light source of a large-scaled opto-magnetic memory for information processing and can be applied to further various uses by appropriately selecting the layer constitutions, materials to be used, etc.

As the substrate (1), a GaAs substrate is preferably used in the invention. For the substrate (1), not only a so-called just substrate but also a so-called off angle substrate (miss oriented substrate) can be used with the view point of improving the crystasllinity upon epitaxial growth. The off angle substrate has an effect of promoting the crystal growth in a step-flow mode and is used generally. For the off angle substrate, those having a gradient of about 0.5 to 2 degree are used generally and the gradient may sometimes be about 10 degrees depending on the materials constituting the quantum well structure.

The substrate (1) may be previously applied with chemical etching or heat treatment for manufacturing a light emitting device by utilizing the crystal growth technique such as MBE or MOCVD. The thickness of the substrate (1) to be used is usually about 350 μm, so as to ensure the mechanical strength during the manufacturing process for the device and it is usually polished thinly to about 100 μm in the course of the process for forming the facet of the semiconductor light emitting device.

The buffer layer (2) is preferably disposed for moderating the incompleteness of substrate bulk crystals and facilitating the formation of a thin epitaxial film with the crystallographic axis being identical. The buffer layer (2) is preferably constituted with a compound identical with that for the substrate (1) and, in a case where the substrate (1) comprises GaAs, the buffer layer (2) uses GaAs. However, a super lattice layer is also used generally for the buffer layer (2) and it is not sometimes formed with an identical compound. On the other hand, in a case of using a dielectric substrate, it is not always formed of an identical material with the substrate and a material different from the substrate is sometimes selected properly in view of the desired emission wavelength thereof and the structure of the entire device.

The first-conduction-type first clad layer (3) comprises AlₓₙGa₁₋ₓₙAs. In order to lower thermal resistance of the entire device and obtain a structure suitable for high power operation, the Al composition xn in the first-conduction-type first clad layer (3) is constituted so as to satisfy: 0<xn<0.40. xn is, preferably, 0.3 or less and, more preferably, 0.2 or less. Further, the thickness tₓₙ (nm) of the first-conduction-type first clad layer (3) is preferably made larger than the oscillation wavelength λ (nm) since it is necessary to decay the light sufficiently in the direction receding from the active layer structure (6).

Further, in the first-conduction-type first clad layer (3) in the invention, since the Al composition in the AlₓₙGa₁₋ₓₙAs layer is less than that of the LD having a usual SCH structure or GRIN-SCH structure, an effect capable of increasing the activation ratio of the dopant can also be expected. Particularly, for example, in a case where the first conduction type is an n-type and Si is used as the dopant, when it is assumed to conduct crystal growth by an MBE method, it is known that the ionization energy of the Si doner greatly depends on the Al composition as described by N. Chand et al., in Physical Review B, vol. 30 (1984), p. 4481, and this is extremely desirable since a layer of a sufficiently low resistance can be formed even when the doping is set to a relatively low level in AlGaAs at less Al composition. Accordingly, the doping level in the first-conduction-type first clad layer (3) is, preferably, 1.0×10¹⁷ cm⁻³ to 1.0×10¹⁸ cm⁻³ and, more preferably, 3.0×10¹⁷ cm⁻³ to 7.5×10¹⁷ cm⁻³.

Further, it is not necessary that the doping is conducted uniformly in the first-conduction-type first clad layer (3) but it is preferably set such that the level is higher toward the substrate (1) and lower to the side near the active layer structure (6). This is an effective method of suppressing absorption by free electrons in the portion where the optical density is high.

The first-conduction-type second clad layer (4) comprises AlₛₙGa₁₋ₛₙAs (0<sn≦1). sn is preferably less than 0.5. The Al composition sn in the first-conduction-type second clad layer (4) has to be more than the Al composition xn of the first-conduction-type first clad layer (3) and the Al composition gn for the first optical guide layer (5) adjacent therewith. By adopting the constitution, the first-conduction-type second clad layer (4) becomes a layer with least refractive index and has a function as a barrier against electrons on the side of the conduction band and holes in the valence band. Further, the difference sn−xn between the Al composition en for the first-conduction-type second clad layer (4) and the Al composition xn for the first-conduction-type first clad layer (3) is made larger than 0.08. With this constitution, the first-conduction-type second clad layer (4) can sufficiently suppress the overflow of carriers from the active layer structure (6) to the first-conduction-type first clad layer (3). However, sn−xn is preferably smaller than 0.4 so as not to excessively inhibit the injection of carriers from the first-conduction-type first clad layer (3) to the active layer structure (6).

The thickness tₛₙ (nm) of the first-conduction-type second clad layer (4) is smaller than the thickness t_{gn} (nm) of the first optical guide layer (5). Use of such a constitution can avoid extreme increase of the threshold current, lowering of the slope efficiency and increase of the driving current. In order to obtain an appropriate NFP expanding effect in the vertical direction, it is preferred to satisfy the following formula:
0.3<tₛₙ/t_{gn}
Further, the thickness tₛₙ of the first-conduction-type second clad layer (4) is preferably larger than 10 nm and smaller than 100 nm. In a case where tₛₙ of the first-conduction-type second clad layer (4) is 10 nm or smaller, the optical effect is sometimes reduced. On the other hand, when it is 100 nm or larger, the optical confinement is sometimes weakened extremely and LD oscillates no more.

Further, in the first-conduction-type second clad layer (4), since the Al composition sn of the AlₛₙGa₁₋ₛₙAs layer is relatively large in the LD structure of the invention, the doping level for the dopant is preferably set higher compared with the first-conduction-type first clad layer (3). Particularly, assuming the crystal growth by the MBE method, for example, in a case where the first conduction type is an n-type and Si is used as the dopant, the doping level is, preferably, 3.0×10¹⁷ cm⁻³ to 1.0×10¹⁸ cm⁻³ and, more preferably, 4.0×10¹⁷ cm⁻³ to 7.5×10¹⁷ cm⁻³.

Although not illustrated in FIG. 2, a layer comprising an AlₜGa₁₋ₜAs material system in which the Al composition is gradually changed monotonously such that the composition t is: t=xn on the side of the first-conduction-type first clad layer (3) and t=sn on the side of the first-conduction-type second clad layer (4) can also be inserted between the first-conduction-type first clad layer (3) and the first-conduction-type second clad layer (4). The transition layer described above is particularly preferred since this can decrease the electric resistance upon injection of carriers from the first-conduction-type first clad layer (3) through the first-conduction-type second clad layer (4) to the active layer structure (6). Further, the composition in the transition layer can be changed variously and it is possible to adopt, for example, a form in which the Al composition t increases linearly from the first-conduction-type first clad layer (3) to the first-conduction-type second clad layer (4) or a form in which it increases monotonously in a curved profile.

The first optical guide layer (5) over the first-conduction-type second clad layer (4) comprises Al_{gn}Ga_{1-gn}As (0≦gn<0.40). For attaining the optical confinement, it is necessary that the first optical guide layer (5) is constituted with a material of a larger refractive index than that of the first-conduction-type first clad layer (3), that is, a material of less Al composition than that of the first-conduction-type first clad layer (3). Further, also in the first optical guide layer (5), it is necessary that the Al composition is less than 0.4, preferably, less than 0.2 and, more preferably, less than 0.1. Most preferred is a case of using GaAs not containing Al. Particularly, in view of the reliability, an optical guide layer not containing Al is desired.

Further, the thickness t_{gn} (nm) of the first optical guide layer (5) preferably satisfies the following formula in order that the first-conduction-type second clad layer (4) provides the function sufficiently.
0.5×[λ/(4×n_{gn})]nm<t_{gn}n1.5×[λ/(4×n_{gn})]nm
In the formula, n_{gn} is a refractive index of the first optical guide (5). By restricting the thickness t_{gn} of the first optical guide layer (5) to smaller than the upper limit in the formula, it is possible to sufficiently provide the effect of suppressing the overflow of carriers in the first-conduction-type second clad layer (4) and effectively avoid lowering of the kink level, etc. Further, by restricting the thickness t_{gn} of the first optical guide layer (5) to larger than the lower limit in the formula, it is possible to suppress the first-conduction-type second clad layer (4) from exhibiting excessive anti-waveguide property.

It is not always necessary that the first optical guide layer (5) comprising Al_{gn}Ga_{1-gn}As (0≦gn<0.40) with a thickness of t_{gn} is a layer having a constant Al composition but the Al composition can also be changed in the first optical guide layer (5). In a case where regions of different Al compositions are present in the first optical guide (5), an average refractive index thereof can be considered as the refractive index of the first optical guide layer.

The conduction type of the first optical guide layer (5) may be a p-type, n-type or undoped type and the effect of the invention does not change depending on the type.

The active layer structure (6) referred to in the invention preferably contains a strained quantum well layer containing In, Ga, and As and not lattice-matched to the substrate. Barrier layers having a larger band gap than that of the quantum well layer are provided on both sides of the strained quantum well layer in most cases.

The constitution for the active layer structure (6) can include a case of an InGaAs strained single quantum well layer (S-SQW) where the optical guide layer (5, 7) has a role as the barrier layer, and a case of comprising an identical SQW structure in which a GaAs barrier layer, an InGaAs strained quantum well layer and a GaAs barrier layer are stacked. Alternatively, the active layer structure (6) may be a so-called strained double quantum well structure (S-DQW) as shown in FIG. 2 in which a GaAs barrier layer (21), an InGaAs strained quantum well layer (22), a GaAs barrier layer (23), an InGaAs strained quantum well layer (24), and a GaAs barrier layer (25) are stacked from the side of the substrate (1). Further, it also includes a case of using a multi-quantum well structure in which three or more multiple quantum well layers are used in stack. Furthermore, it may be a structure in which a GaAs barrier layer, an InGaAs strained quantum well layer, an InGaAsP strain-compensation barrier layer, an InGaAs strained quantum well layer and a GaAs barrier layer are stacked and, in which strains present in the strained quantum well layer and the barrier layer are strained in the opposite direction.

The specific material for the strained quantum well layer can include, for example, InGaAs and GaInNAs. Increase of the optical gain, etc. can be expected for the quantum well layer having strains due to the strain effect thereof. Accordingly, even for appropriately weak optical confinement in the vertical direction between the first clad layer (3, 9, 10) of the low Al composition and the active layer structure (6), a sufficient LD characteristic can be attained. Therefore, the strained quantum well layer is indispensable in the invention.

While the effect of the invention does not change when the conduction type of the barrier layer (21, 23, 25) is a p-type, n-type or undoped type, it is desirable that the barrier layer (21, 23, 25) has a portion showing the n-conduction type. Under such a situation, since electrons from the barrier layer (21, 23, 25) are supplied to the quantum well layer (22, 24) in the active layer structure (6), the gain characteristics of the LD can be attained desirably for the wider band region effectively. In the device described above, the oscillation wavelength can be fixed effectively by an external cavity such as a grating fiber as will be described later. In this case, then-type dopant is preferably Si. Further, the n-type dopant such as Si is not doped uniformly in the barrier layer (21, 23, 25) but it is most preferred that doping is not applied near the boundary with respect to other layers such as the strained quantum well layer (22, 24) and doping is selectively applied near the center of the barrier layer (21, 23, 25).

The second optical guide layer (7) comprises Al_{gp}Ga_{1-gp}As (0≦gp<0.40). For attaining optical confinement, it is necessary that the second optical guide layer (7) is formed of a material with a larger refractive index than that of the second-conduction-type first clad layer (9, 10), that is, a material with a less Al composition than that of the second-conduction-type first clad layer (9, 10). Further, also in the second optical guide layer (7), the Al composition has to be less than 0.4, preferably, less than 0.2 and, more preferably, less than 0.1. A most preferred case is the use of GaAs not containing Al. In view of the reliability, an optical guide layer not containing Al is particularly desired.

Further, the thickness t_{gp} (nm) of the second optical guide layer (7) preferably satisfies the following formula in order that the second-conduction-type second clad layer (8) provides the function sufficiently.
0.5×[λ/(4×n_{gp})]nm<t_{gp}<1.5×[λ/(4×n_{gp})]nm
In the formula, n_{gp} is a refractive index of the second optical guide (7). By restricting the thickness t_{g}_{^{g}} of the first optical guide layer (7) to smaller than the upper limit in the formula, it is possible to sufficiently provide the effect of suppressing the overflow of carriers in the second-conduction-type second clad layer (8) and effectively avoid lowering of the kink level, etc. Further, by restricting the thickness t_{gp} of the second optical guide layer (7) to larger than the lower limit in the formula, it is possible to suppress the second-conduction-type second clad layer (9, 10) from exhibiting excessive anti-waveguide property.

It is not always necessary that the second optical guide layer (7) is a layer having constant Al composition but the Al composition can also be changed in the second optical guide layer (7). In a case where regions of different Al compositions are present in the second optical guide (7), an average refractive index thereof can be considered as the refractive index of the optical guide layer. The composition of the second optical guide layer (7) may be the same as or different from that of the first optical guide layer (5). In a case of a preferred embodiment of the invention, both the Al composition gp of the second optical guide layer (7) and the Al composition gn of the first optical guide layer (5) are 0.

The conduction type of the second optical guide layer (7) may be a p-type, n-type or undoped type and the effect of the invention does not change depending on the type.

The second-conduction-type second clad layer (8) comprises AlₛₚGa₁₋ₛₚAs (0<sp≦1). sp is preferably less than 0.5. The Al composition spin the second-conduction-type second clad layer (8) has to be more than the Al composition xp in the second-conduction-type lower first clad layer (9) and the Al composition gp in the second optical clad layer (7) adjacent therewith. By the use of such a constitution, the second-conduction-type second clad layer (8) becomes a layer with least refractive index and has a function as a barrier against electrons on the side of the conduction band and holes in the valence band. Further, the difference sp−xp between the Al composition sp of the second-conduction-type second clad layer (8) and the Al composition xp of the second-conduction-type lower first clad layer (9) is made more than 0.08. With this constitution, the second-conduction-type second clad layer (8) can sufficiently suppress the overflow of carriers from the active layer structure (6) to the second-conduction-type lower first clad layer (9). However, sp−xp is preferably less than 0.4 so as not to excessively inhibit the injection of carriers from the second-conduction-type lower first clad layer (9) to the active layer structure (6).

The thickness tₛₚ (nm) of the second-conduction-type second clad layer (8) is smaller than the thickness t_{gp} (nm) for the second optical guide layer (7). Use of such a constitution can avoid extreme increase of the threshold current, lowering of the slope efficiency and increase of the driving current. In order to obtain an appropriate NFP expanding effect in the vertical direction, it is preferred to satisfy the following formula:
0.3<tₛₚ/t_{gp}

Further, the thickness tₛₚ of the second-conduction-type second clad layer (E) is preferably larger than 10=m and smaller than 100 nm, In a case where the tₛₚ of the second-conduction-type second clad layer (8) is 10 nm or smaller, the optical effect is sometimes reduced. On the other hand, when it is 100 nm or larger, the optical confinement is sometimes weakened extremely and the LD oscillates no more.

It is not always necessary that the second-conduction-type second clad layer (8) has the same Al composition as in the first-conduction-type second clad layer (4), but it is desirable that the Al compositions are identical with an aim of ensuring the symmetricity of the beam in the vertical direction.

Particularly, assuming the crystal growth by the MBE method, for example, in a case where the second conduction type is a p-type and Si is used as the dopant, the doping level is, preferably, from 3.0×10¹⁷ cm⁻³ to 1.0×10¹⁸ cm⁻³ and, more preferably, from 4.0×10¹⁷ cm⁻³ to 7.5×10¹⁷ cm⁻³.

Although not illustrated in FIG. 2, a layer formed of an AlₜGa₁₋ₜAs material system in which the Al composition is gradually changed monotonously such that the composition t is: t=sp on the side of the second-conduction-type second clad layer (8) and t=xp on the side of the second-conduction-type lower first clad layer (4) can also be inserted between the second-conduction-type second clad layer (e) and the second-conduction-type lower first clad layer (9). Further, the composition in the transition layer can be changed variously and it is possible to adopt, for example, a form in which the Al composition t increases linearly or a form in which it increases monotonously in a curved profile from the second-conduction-type second clad layer (8) to the second-conduction-type lower first clad layer (9).

The second-conduction-type first clad layer consists of two layers of a second-conduction-type lower first clad layer (9) and a second-conduction-type upper first clad layer (10) in FIG. 2. In this case, the two layers may have an etching stop layer therebetween in order to facilitate the fabrication of the device.

The second-conduction-type first clad layer (9, 10) comprises AlₓₚGa₁₋ₓₚAs (0<xp<0.40). The Al composition xp in the second-conduction-type first clad layer (9, 10) is constituted so as to satisfy: 0<xp<0.40 in order to lower thermal resistance of the entire device and provide a structure suitable for high power operation. xp is, preferably, 0.3 or less and, more preferably, 0.2 or less. Further, the entire thickness tₓₚ of the second-conduction-type first clad layer (9, 10) is preferably made larger than the oscillation wavelength λ since it is necessary to sufficiently decay the light in the direction receding from the active layer structure (6).

The thickness of the second-conduction-type lower first clad layer (9) is preferably about from 10 nm to 200 nm so that current injection path to the active layer structure (6) is not widened extremely due to the horizontal diffusion of the current. More preferably, it is about from 20 nm to 70 nm.

Further, the doping level for the second-conduction-type lower first clad layer (9) and the second-conduction-type upper first clad layer (10) is, preferably, from 1.0×10¹⁷ cm⁻³ to 1.0×10¹⁸ cm⁻³ and, more preferably, from 3.0×10¹⁷ cm⁻³ to 7.5×10¹⁷ cm⁻³.

Further, it is not necessary that doping is conducted uniformly in the second-conduction-type lower first clad layer (9) or the second-conduction-type upper first clad layer (10) but it is set preferably higher on the side of the contact layer (13) and lower on the side nearer to the active layer structure (6). This is an effective method for suppressing the absorption by free electrons in a portion where the optical density is high. In the invention, it is preferred that the doping level is not uniform in the layer for at least one of the first-conduction-type first clad layer (3) or the second-conduction-type first clad layer (9, 10).

The second-conduction-type upper first clad layer (10) provides two functions of the current confinement and the optical confinement in the horizontal direction, together with the current block layer (11) formed on the side walls thereof. This is a preferred constitution when the invention is applied to an LD that operates in a single transverse-mode. For this purpose, the conduction type of the current block layer (11) is preferably a first conduction type or an undoped type with a view point of the current confinement in the horizontal direction. Further, with the view point of the optical confinement in the horizontal direction and, particularly, for satisfying the characteristics as the waveguide based on the index waveguide, the current block layer (11) is formed of a material having a refractive index smaller than that of the second-conduction-type first clad layer (9, 10). Further, in the invention, the current block layer (11) is preferably formed of an AlGaAs material system and, assuming the material as Al_{z}Ga_{1-z}As (0≦z≦1), the Al composition is, preferably, z>xp. Further, while the invention is utilized suitably to a semiconductor laser operating in the single transverse-mode, the effective refractive index difference in the horizontal direction defined mainly by the difference of refractive index between the current block layer (11) and the second-conduction-type upper first clad type (10) is preferably at the order of 10⁻³ order with the view point described above. Further, the width W in the horizontal direction for a portion where the second-conduction-type lower first clad layer (9) is in contact with the second-conduction-type upper first clad layer (10), which is the width for the current injection channel and correspondings to the width of the waveguide is preferably uniform within a range of an error in the direction of the cavity vertical to the drawing and the width is preferably 6 μm or smaller and, more preferably, 3 μm or smaller with a view point of operating the LD in the single transverse-mode. However, for making the high power operation and the single transverse-mode operation compatible, the waveguide is not necessarily uniform in the direction of the cavity and it is preferred that the width for the waveguide is relatively increased on the side of the front facet as the main light emitting direction of the semiconductor laser so as to be suitable for the high power operation, whereas the width for the waveguide is narrowed on the side of the back facet to enable the single transverse-mode operation. Further, in this case, it is desirable to satisfy the following formula assuming the width for the current injection channel near one of light emission points as Wₑₓₚ and the width for the narrowest current injection channel in the device as W_{std}:
1.5<Wₑₓₚ/W_{std}<5.0
It is further preferred to satisfy the following formula:
2.5<Wₑₓₚ/W_{std}<3.5

On the other hand, in the current block layer (11) comprising Al_{z}Ga_{1-z}As, the Al composition may suffice to be: z>xp only with the view point of optical confinement, but the Al composition is, preferably, less than 0.5, more preferably, less than 0.4 and, most preferably, the Al composition is less than 0.25, due to the same reason as other layers comprising AlGaAs.

The cap layer (12) is used as a protective layer for the current block layer in the first growth, as well as used for facilitating the growth of the second-conduction-type upper first clad layer (10) and it is partially or entirely removed before obtaining a device structure.

A contact layer (13) is preferably disposed over the second-conduction-type upper first clad layer (10) with an aim of lowering the contact resistivity relative to the electrode (14), etc. The contact layer (13) is usually constituted with a GaAs material system. In the layer, the carrier concentration is usually made higher than in other layers so as to lower the contact resistivity with respect to the electrode (14). Further, the conduction type is a second conduction type.

The thickness for each of the layers constituting the semiconductor laser is properly selected within such a range as of providing the function of the respective layers effectively.

Further, in the semiconductor light emitting device according to the invention, the first conduction type is preferably an n-type and the second conduction type is preferably a p-type. This is because an n-type substrate often has a good quality.

The semiconductor laser shown in FIG. 2 is fabricated by further forming electrodes (14) and (15). The electrode (14) on the side of the epitaxial layer is formed. For example, in a case where the second conduction type is the p-type, evaporated Ti/Pt/Au are successively formed on the surface of the contact layer (13) and then applying an alloying treatment. On the other hand, the electrode (15) on the side of the substrate is formed on the surface of the substrate (1). And, in a case where the first conduction type is the n-type, evaporated AuGe/Ni/Au are successively formed to the surface of the substrate (1) and then applying an alloying treatment.

A facet as a light emitting surface is formed to the fabricated semiconductor wafer. The facet is a mirror that constitutes a cavity. Preferably, the facet is formed by cleaving. Cleaving is a generally used method and the facet formed by cleaving is different depending on the orientation of the substrate to be used. For example, in a case of forming a device such as an edge-emission-type laser by using a substrate having a surface crystallographically equivalent with the nominally (100) plane utilized suitably, a (110) plane or a plane crystallographically equivalent therewith is a surface that forms a cavity. On the other hand, in a case of using an off angle substrate, the facet does not sometimes form 90 degrees with respect to the direction of the cavity depending on the relation between the inclined direction and the direction of the cavity. For example, when a substrate inclined by 2 degrees from the (100) plane towards the [1-10] direction is used, the facets will also incline by 2 degrees.

The cavity length of the device is also decided by cleaving. Generally, longer cavity length is suitable for the high power operation, and it is, preferably, from 600 μm or more and, more preferably, from 900 μm to 3000 μm in the semiconductor laser to which the invention is applied. The upper limit is defined for the cavity length as described above, because a semiconductor laser having an extremely long cavity length may rather result in deterioration of characteristics such as increase in the threshold current and lowering of the efficiency.

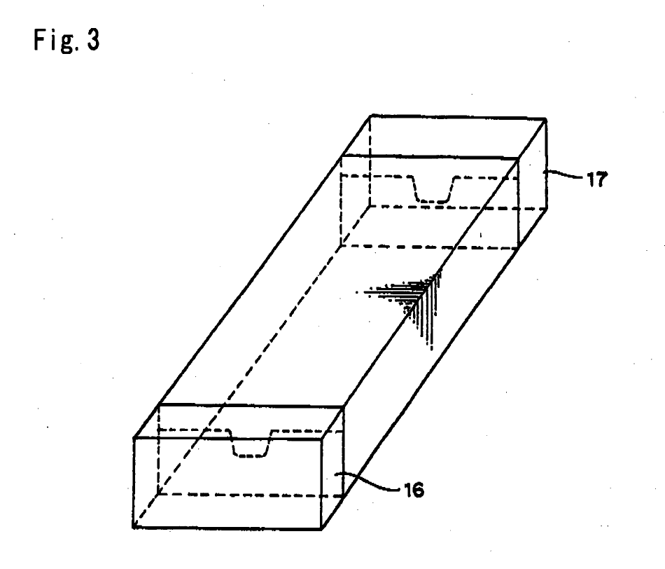

In the invention, coating layer (16, 17) comprising a dielectric material or a combination of a dielectric material and a semiconductor are formed preferably on the exposed facet of the semiconductor (FIG. 3). The coating layer (16, 17) is formed mainly for two purposes of increasing the efficiency for taking out a light from the semiconductor laser and for protecting the facet. Further, in order to take out the light output power from the device efficiently from the facet on one side, it is preferred to conduct asymmetric coating of applying a coating layer with low reflectivity (for example, 10% or less of reflectivity) relative to the oscillation wavelength to the front facet as the main light emission direction, while applying a coating layer with a high reflectivity (for example, 80% or more) relative to the oscillation wavelength to the other back facet. This is extremely important not only for enhancing the power of the device higher but also for positively taking a light returned from an external cavity such as a grating fiber used for the stabilization of wavelength into the laser thereby promoting the stabilization of the wavelength. Further, for the purposes described above, the reflectivity at the front facet is, preferably, 5% or lower and, more preferably, 2.5% or lower.

For the coating layer (16, 17), various materials can be used, For example, it is preferred to use one member selected from the group consisting of AlOₓ, TiOₓ, SiOₓ, SiN, Si and ZnS or a combination of two or more of them. AlOₓ, TiOₓ, SiOₓ, etc. are used for the coating layer at low reflectivity, while AlOₓ/Si multi-layered films, TiOₓ/SiOₓ multi-layered films, etc. are used for the coating layer at high reflectivity. An aimed reflectivity can be attained by controlling the respective film thickness. However, the film thickness of AlOₓ, TiOₓ, SiOₓ, etc. as the coating layer at low reflectivity is generally controlled so as to be near λ/4n, n being the real number portion of the refractive index at the wavelength λ. Further, also in a case of the highly reflective multi-layered film, each of the materials constituting the film is generally controlled so as to be near λ/4n.

By cleaving the laser bar again after completion of the coating again, respective devices can be separated as semiconductor lasers.

A semiconductor light emitting device module can be formed by disposing an optical fiber to the light emission end of the semiconductor light emitting device of the invention including the semiconductor laser fabricated as described above. It is preferred that the top end of the optical fiber is fabricated to show a light focusing effect and to be optically coupled directly to the front facet of the semiconductor light emitting device.

For stabilizing the wavelength of the semiconductor light emitting device according to the invention including the semiconductor laser, it is preferred to provide a mirror having a wavelength selectivity at the outside, and couple the external cavity and the semiconductor light emitting device of the invention. It is particularly preferred to form the external cavity by using a fiber grating. In this case, it is also possible to form a semiconductor light emitting device module incorporating a fiber grating, a cooler for temperature stabilization, etc. in addition to the semiconductor light emitting device. For the fiber grating, the center wavelength, the reflection or transmission region, reflectivity of light of the fiber grating to the side of the semiconductor light emitting device, etc. can be selected optionally in accordance with the purpose thereof. Particularly, the reflectivity of the light of the fiber grating to the side of the semiconductor light emitting device is, preferably, from 2 to 15%, more preferably, from 5 to 10% at the emission wavelength of the semiconductor light emitting device, and the reflection region is, preferably, from 0.1 to 5.0 nm and, more preferably, from 0.5 to 1.5 nm relative to the center wavelength.

Semiconductor Light Emitting Device Satisfying Condition 2

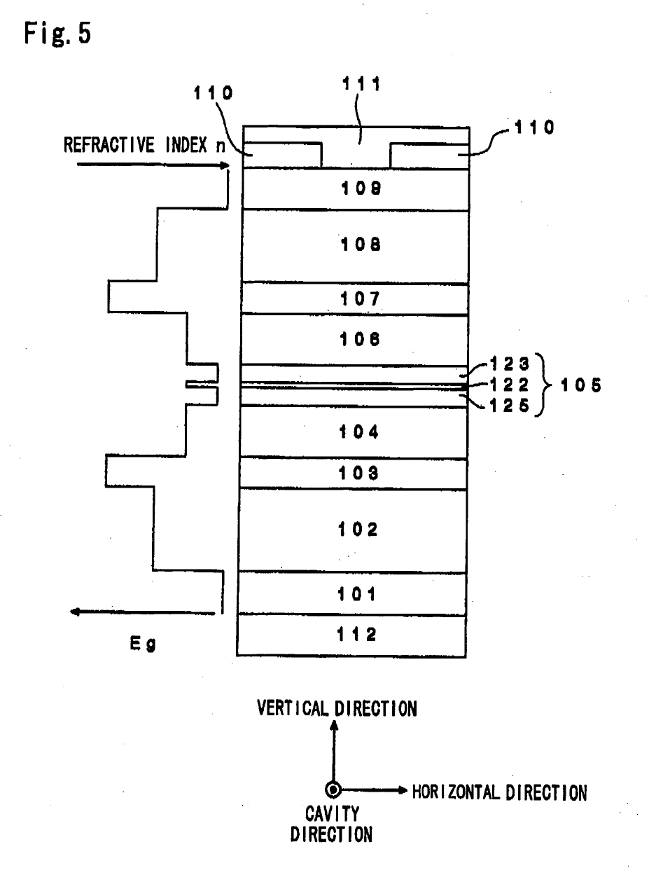

Next, main features of a semiconductor light emitting device according to the invention satisfying the condition 2 are to be described with reference to an LD shown in FIG. 5. FIG. 5 shows a spatial distribution in the vertical direction of the refractive index obtained by the structure for each of the layers on the left side, and FIG. 5 shows the designation for the directions used in the drawings on the lower side thereof.

FIG. 5 shows a broad area type LD comprising, on an n-type substrate (101), an n-type first clad layer (102) comprising Al_{0.25}Ga_{0.75}As at a thickness of tₓₙ (nm), an n-type second clad layer (103) comprising In_{0.49}Ga_{0.51}P at a thickness of tₛₙ (nm), a first optical guide layer (104) comprising undoped GaAs at a thickness of t_{gn} (nm), an active layer structure (105) at a thickness of tₛ (nm), a second optical guide layer (106) comprising undoped GaAs at a thickness of t_{gp} (nm), a p-type second clad layer (107) comprising In_{0.49}Ga_{0.51}P at a thickness of tₛₚ (nm), and a p-type first clad layer (108) comprising Al_{0.25}Ga_{0.75}As at a thickness of tₓₚ (nm), and a contact layer (109) for lowering the contact resistance with an electrode, as well as an SiN layer (110) for restricting the current injection region relative to the horizontal direction, a p-side electrode (111) and an n-side electrode (112). In the invention, while it is not always necessary that paired layers such as the n-type first clad layer (102) and the p-type first clad layer (108), etc. are symmetrical, they are constituted with the materials having the identical refractive index, and the thickness also satisfies the following condition in FIG. 5:
tₓₙ=tₓₚ=tₓ
tₛₙ=tₛₚ=tₛ
t_{gn}=t_{gp}=t_{g}

Further, active layer structure (105) is a strained double quantum well structure having a structure in which an In_{0.16}Ga_{0.84}As strained quantum well layer (121) of 6 nm thickness, a GaAs barrier layer (122) of 8 nm thickness, an In_{0.16}Ga_{0.64}As strained quantum well layer (123) of 6 nm thickness are stacked from the side of the substrate (101), and has an oscillation wavelength λ (nm).

In the invention, the confinement in the vertical direction to the active layer structure (105) as a basis for the optical confinement of the LD is attained by the difference of the refractive index between the two Al_{0.25}Ga_{0.75}As first clad layers (102, 108) situated over and under the active layer structure (105) and two GaAs optical guide layers (104, 106) containing the active layer structure (105). In a case where the substrate (101) comprises GaAs, and the first clad layer (102, 108) is constituted With AlGaAs in view of the lattice matching, the Al composition is, preferably, less than 0.4, more preferably, less than 0.3 and, further preferably, less than 0.2. This is because thermal resistance for the entire device can be lowered by decreasing the Al composition in the clad layer (102, 108) which is most thick among the layers constituting the entire LD except for the substrate (101) and the contact layer (109) and a structure suitable for high power operation can be provided. Further, in a case where the substrate (101) comprises GaAs, In_{0.49}Ga_{0.51}P is applicable to the first clad layer (102, 108). Further, it is not necessary that the first clad layer (102, 108) are constituted with a single material but they may comprise plural layers that function in an equivalent manner with the single layer relative to light. In this case, the light is controlled by an average refractive index of the plural layers.

The thickness tₓ (nm) of the first clad layer (102, 108) preferably has the following relation to the oscillation wavelength λ (nm) since it is necessary to sufficiently decay the light in the layer in the direction receding from the side of the active layer.
λ<tₓ
Particularly, in a case where the substrate is transparent to the oscillation wavelength and the refractive index is larger than that of the first clad layer (102, 108) and the second clad layer (103, 107) as in a case of the 980 nm band LD, it is known that the substrate-mode overlaps the inherent LD mode since the light leaked from the clad layer (102, 103) to the substrate (101) propagates through the substrate. In order to suppress the same, it is desirable that the thickness of the first clad layer (102, 108) is increased appropriately relative to the wavelength.

Further, for attaining the optical confinement, it is necessary that the optical guide layer (104, 106) is constituted with a material of a larger refractive index than that of the first clad layer (102, 108). In a case where the substrate (101) comprises GaAs and the optical guide layer (104, 106) is constituted with an AlGaAs material system, it is preferred that, also in the optical guide layer (104, 106), the Al composition is, preferably, less than 0.4, more preferably, less than 0.2 and, further preferably, less than 0.1. Use of GaAs not containing Al is a most preferred case. Particularly, with a view point of the reliability, an optical guide layer not containing Al is desired.

In a case of constituting a usual SCH structure (Separated Confinement Hetero-structure) with an AlGaAs material system, the first clad layer (102, 108) and the optical guide layer (104, 106) are in contact directly with each other. However, the invention has a feature in that the layers have the second clad layer (103, 107) therebetween. It is necessary that the refractive index of the layer is set lower than the optical guide layer (104, 106) and, further, lower than the first clad layer (102, 108).

As a result, as shown on the left side of FIG. 5, the second clad layer (103, 107) is a layer having the least value as the refractive index. On the left side of FIG. 5, the direction of the arrow described below n means a direction in which the refractive index increases. The second clad layer (103, 107) has a function as a barrier against the electrons on the side of the conduction band (also against holes in the valence band although not illustrated). The direction of the arrow described above Eg on the left side of FIG. 5 means the direction along which the potential increases relative to electrons.

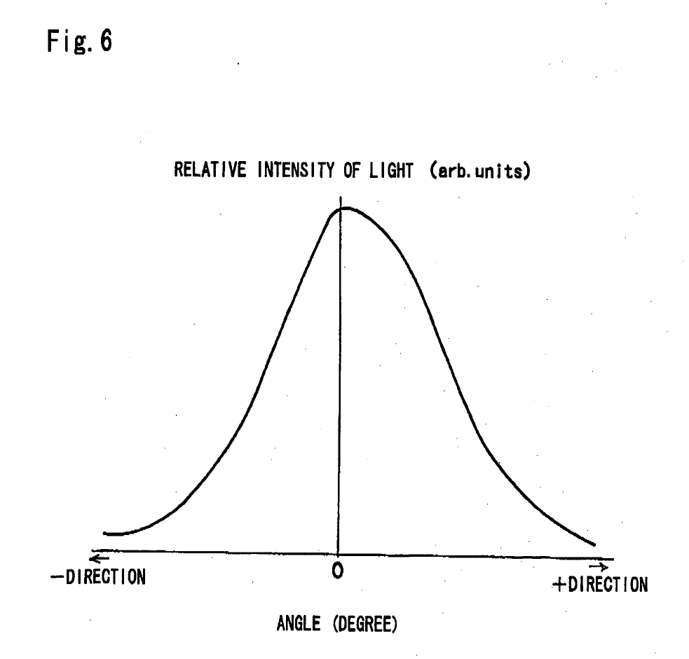

Accordingly, the second clad layer (103, 107) has an extremely important function regarding the optical confinement in the vertical direction as will be described next. Since second clad layer (103, 107) is selected such that the refractive index is lower than the optical guide layer (104, 106) and lower than the first clad layer (102, 108), the second clad layer (103, 107) provides a function of expanding the distribution of light to the outside thereof, that is, to both sides of the first clad layer (102, 108) and the optical guide layer (104, 106). Accordingly, the component of NFP_{V} with a distribution being expanded properly to the side of the first clad layer (102, 108) contributes to attain a relatively narrow FFP. That is, in a case where the anti-waveguide property of the second clad layer (103, 107) functions adequately, relatively narrow FFP can be attained by the presence of the function. Further, in a case where the anti-waveguide property of the second clad layer (103, 107) exerts properly, an extremely characteristic shape appears in the FFP of the device. Generally, the FFP_{V} of a semiconductor laser designed such that only the fundamental-mode propagates in the vertical direction, that is, a semiconductor, with the normalized frequency in the vertical direction being π/2 or less shows a single peak as shown in FIG. 6 except for auxiliary matters such as overlaps of noises and light interference pattern. However, the invention has a feature in that one main peak (intensity: I_{Vmain}) and two sub-peaks (intensity: I_{Vsub-} and I_{Vsub+}, peak of larger intensity being described also as I_{Vsub}) are observed and they satisfy 0<I_{Vsub}/I_{Vmain}<0.5. The sub-peak is generated when the second clad layer (103, 107) drives the light toward the optical guide layer (104, 106) by which the component of the NFP_{V} concentrated to a portion relatively nearer to the active layer causes large diffraction. Accordingly, existence of the second clad layer (103, 107) not only expands the distribution of the NFP toward the first clad layer (102, 108) but also has an effect of keeping the optical confinement near the active layer which is indispensable for the semiconductor laser. Then, according to the invention, it is possible to narrow the FFP with no undesired side effects such as increase in the threshold current, lowering of the slope efficiency and increase of the driving current of the LD generated upon narrowing the FFP (extension of NFP). For this purpose, the degree of concentration near the active layer, that is, presence of two sub-peaks observed in the FFP is extremely important in the optical confinement in the vertical direction. In the invention, 0<I_{Vsub}/I_{Vmain}<0.5 is essential and it is, preferably, 0<I_{Vsub}/I_{Vmain}<0.3, and more preferably, 0.05<I_{Vsub}/I_{Vmain}<0.2. The indexes are defined due to absolute or relative relation such as (average) refractive index or thickness of the first clad layer (102, 108), the second clad layer (103, 107), the optical guide layer (104, 106), and the active layer structure (105). For example, extreme lowering of the refractive index or increase of the thickness of the second clad layer (103, 107) or extreme reduction for the thickness of the optical guide layer (104, 106), etc. are not desired since the waveguide tends to exhibit excessively anti-waveguide property to weaken the optical confinement in the vertical direction in the LD structure and, as a result, lead to extreme increase in the threshold current, lowering of the slope efficiency and increase in the driving current.

Further, assuming the angle at which the main peak appears as P(I_{Vmain}), and angles at which the two sub-peaks at I_{Vsub-} and I_{Vsub+} appear as P(I_{Vsub-}), P(I_{Vsub+}), respectively, it is desirable in the invention to satisfy the following formulae:
|P(I_{Vmain})−P(I_{Vsub-)|>}40 degrees
|P(I_{sub+})−P(I_{Vmain})|>40 degrees
|P(I_{Vsub+})−P(I_{Vsub-})|>80 degrees

They are important indexes showing the degree of concentration near the active layer in the component for the NFP_{V} and it is more preferred to satisfy the following formulae:
|P(I_{Vmain})−P(I_{Vsub-)|>}50 degrees
|P(I_{Vsub+})−P(I_{Vmain})|>50 degrees
|P(I_{Vsub+})−P(I_{Vsub-})|>100 degrees

Further preferred are those cases satisfying the following formulae:
60 degrees>|P(I_{Vmain})−P(I_{Vsub-})|>55 degrees
60 degrees>|P(I_{sub+})−P(I_{Vmain})|>55 degrees
120 degrees>|P(I_{Vsub+})−P(I_{Vsub-})|>110 degrees

Another function of the second clad layer (103, 107) is to suppress thermal leakage of carriers (overflow) from the In_{0.16}Ga_{0.84}As strain quantum well layer (121, 123) to the first clad layer (102, 108), for example, in a case where the LD is driven at high temperature or the temperature of the active layer increases considerably by the self heat generation of the LD during high power operation. In this structure, since the barrier height for the second clad layer (103, 107) is higher than the barrier height between the optical guide layer (104, 106) and the first clad layer (102, 108) in view of the carriers that leak from the active layer structure (105) through the optical guide layer (104, 106) to first clad layer (102, 108) as shown in FIG. 5, this is desirable also with a view point of suppressing the carrier overflow. However, since an extremely high barrier height inhibits the injection of carriers that are injected from the first clad layer (102, 108) to the active layer structure (105), the difference of the band gap between the first clad layer (102, 108) and the second clad layer (103, 107) is, preferably, about from 0.05 eV to 0.45 eV and, more preferably, about from 0.1 eV to 0.3 eV.

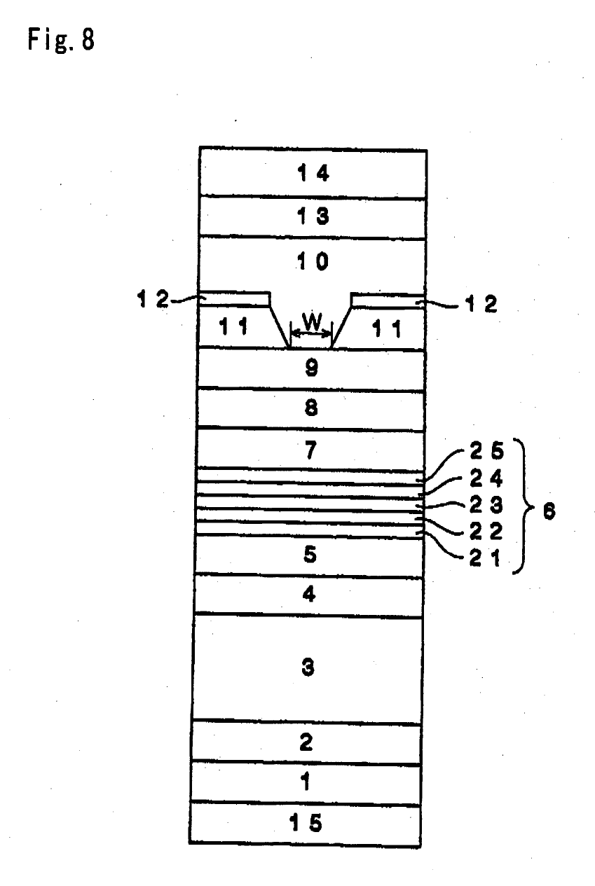

Next, description is to be made to a semiconductor laser capable of single transverse-mode operation as an example of the semiconductor laser according to the invention with reference to FIG. 8. FIG. 8 is a schematic cross sectional view showing the constitution of a buried-stripe type semiconductor laser as an example of an epitaxial structure in the semiconductor laser according to the invention.

The semiconductor laser is formed over a semiconductor substrate (1), has a refractive-index-guided structure in which a second-conduction-type first clad layer consists of two layers of a second-conduction-type upper first clad layer (10) and a second-conduction-type lower first clad layer (9), the second-conduction-type upper first clad layer (10) and the current block layer (11)/cap layer (12) attain current confinement and optical confinement and, further, has a contact layer (13) for lowering the contact resistance with the electrode. The laser of this type is used as a light source for optical fiber amplifiers used in optical communication, as a pick-up light source of a large scaled opto-magnetic memory for use in information processing, a high-power semiconductor laser for medical use and, further, can be applied to various uses by properly selecting the layer constitution or materials to be used.

As the substrate (1), GaAs, InP, GaP, GaN, etc. can be used for the semiconductor substrate, and AlOₓ, etc. can be used for the dielectric substrate. For the substrate (1), not only a so-called just substrate but also a so-called off angle substrate (miss oriented substrate) can be used with a viewpoint of improving the crystallinity upon epitaxial growth. The off angle substrate has an effect of promoting good crystal growth in the step-flow mode and used generally. For the off angle substrate, those having an inclination of about from 0.5 degree to 2 degrees are used generally, and the inclination may sometimes be about 10 degrees depending on the type of the materials constituting the quantum well structure to be described later.

The substrate (1) may be previously applied with chemical etching or heat treatment, etc, for manufacturing a semiconductor laser by utilizing the crystal growth technique such as MBE or MOCVD. The thickness of the substrate (1) to be used is usually about 350 μm so as to ensure the mechanical strength in the process for manufacturing the device and it is usually polished thinly to about 100 μm in the course of the process for forming the facet of the semiconductor laser.

The buffer layer (2) is preferably disposed so as to moderate the incompleteness of substrate bulk crystals and facilitate the formation of a thin epitaxial film with that of the crystallographic axes being identical. The buffer layer (2) is preferably constituted with a compound identical with the substrate (1) and GaAs is usually used in a case where the substrate (1) comprises GaAs, and InP is used in a case where the substrate comprises InP. However, a super lattice layer is also used generally for the buffer layer (2) and, for example, an AlGaAs/GaAs super lattice structure is sometimes used over the GaAs substrate not being formed with an identical compound. Further, the composition of the buffer layer (2) can be changed gradually in the layer. On the other hand, in a case of using the dielectric substrate, it is not always formed of the substance identical with the substrate (1) and materials different from the substrate may be sometimes selected properly in view of the desired emission wavelength and the entire device structure.

The first-conduction-type first clad layer (3) can be constituted with various kinds of materials and they are properly selected in accordance with the active layer structure (6) or the substrate (1) selected depending on the oscillation wavelength intended to be attained. For example, in a case of attaining the invention over the GaAs substrate, AlGaAs material systems, InGaP material systems, AlGaInP material systems, etc. can be used. For example, in a case of attaining on the InP substrate, InGaAsP material systems, etc. can be used.

Particularly, in a case of using the AlGaAs material systems, it is preferred that the Al composition of the first-conduction-type first clad layer (3) is, preferably, less than 0.40, more preferably, 0.3 or less and, further preferably, 0.2 or less in order to decrease the thermal resistance of the entire device and obtain a structure suitable for high power operation. Further, the thickness tₓₙ (nm) of the first-conduction-type first clad layer (3) is preferably made larger than the oscillation wavelength λ (nm) since it is necessary to decay the light sufficiently in the direction receding from the active layer structure (6).

Further, a case of using AlGaAs for the first-conduction-type first clad layer (3) as described above, since the Al composition of the AlₓₙGa₁₋ₓₙAs layer is less than that of the LD having a usual SCH structure or GRIN-SCH structure, an effect capable of increasing the activation ratio of the dopant can also be expected. Particularly, for example, in a case where the first conduction type is an n-type and Si is used as the dopant, when it is assumed to conduct crystal growth by an MBE method, it is known that the ionization energy of the Si doner greatly depends on the Al composition as described by N. Chand et al., in Physical Review B, vol. 30 (1984), p. 4481, and this is extremely desirable since a layer of a sufficiently low resistance can be formed even when the doping is set to a relatively low level in AlGaAs at a less Al composition. Accordingly, the doping level in the first-conduction-type first clad layer (3) is, preferably, 1.0×10¹⁷ cm⁻³to 1.0×10¹⁸ cm⁻³ and, more preferably, 3.0×10¹⁷ cm⁻³ to 7.5×10¹⁷ cm⁻³.

Further, it is not necessary that the doping is conducted uniformly in the first-conduction-type first clad layer (3) but it is preferably set such that the level is higher toward the substrate (1) and lower on the side nearer to the active layer structure (6). This is an effective method of suppressing absorption by free electrons in the portion where the optical density is high.

The first-conduction-type second clad layer (4) can be constituted with various kinds of materials, which are selected properly in accordance with the active layer structure (6) or substrate, etc, selected depending on the oscillation wavelength to be attained. For example, in a case where the invention is intended to be attained on a GaAs substrate, AlGaAs material systems, InGaP material systems, AlGaInP material systems, etc. can be used and, in a case where it is intended to be attained, for example, on an InP substrate, InGaAsP material systems, etc. can be used.

Further, in a case of constituting the first-conduction-type second clad layer (4) with an AlGaAs material system and defining it as AlₛₙGa₁₋ₛₙAs, the Al composition sn is preferably less than 0.5. Further, the Al composition of the first-conduction-type second clad layer (4) is made more than the Al composition of the first-conduction-type first clad layer (3) and the Al composition of the first optical guide layer (5) adjacent therewith.

By the use of such a constitution, the second-conduction-type second clad layer (4) becomes a layer with least refractive index and has a function as a barrier against electrons on the side of the conduction band and holes in the valence band. Further, the difference between the Al composition of the first-conduction-type second clad layer (4) and the Al composition of the first-conduction-type first clad layer (3) is preferably larger than 0.08. With this constitution, the first-conduction-type second clad layer (4) can sufficiently suppress the overflow of carriers from the active layer structure (6) to the first-conduction-type first clad layer (3). However, the difference between the Al composition of the two layers is preferably less than 0.4 so as not to excessively inhibit the injection of carriers from the first-conduction-type first clad layer (3) to the active layer structure (6).

The thickness tₛₙ (nm) of the first-conduction-type second clad layer (4) is, preferably, less than the thickness t_{gn} (nm) of the first optical guide layer (5). Use of such a constitution can avoid extreme increase of the threshold current, lowering of the slope efficiency and increase of the driving current. In order to obtain an appropriate NFP expanding effect in the vertical direction, it is preferred that tₛₙ/t_{gn} is more than 0.3. Further, the thickness tₛₙ of the first-conduction-type second clad layer (4) is preferably larger than 10 nm and smaller than 100 nm. In a case where the thickness tₛₙ of the first-conduction-type second clad layer (4) is 10 nm or smaller, the optical effect is sometimes reduced. On the other hand, when it is 100 nm or larger, the optical confinement is sometimes weakened extremely and the LD oscillates no more.

Further, in a case of constituting the first-conduction-type second clad layer (4) with an AlGaAs material system and defined as AlₛₙGa₁₋ₛₙAs, since the Al composition sn is relataively high in the LD structure of the invention, it is preferred that the doping level of the dopant is set higher compared with that for the first-conduction-type first clad layer (3). Particularly, assuming the crystal growth is conducted by the MBE method, for example, in a case where the first conduction type is an n-type and Si is used as the dopant, the doping level is, preferably, from 3.0×10¹⁷ cm⁻³ to 1.0×10¹⁸ cm⁻³ and, more preferably, from 4.0×10¹⁷ cm⁻³ to 7.5×10¹⁷ cm⁻³.

Assuming the average refractive index of the first-conduction-type first clad layer (3) as Nₓₙ, the average refractive index of the first-conduction-type second clad layer (4) as Nₛₙ, and the average refractive index of the active layer structure (6) to be described later as Nₐ, it is desirable that the refractive indexes satisfy: Nₛₙ<Nₓₙ<Nₛ. In the FFP_{V} of the completed device, three maximal values are present essentially which comprise a main peak having a maximum value for the intensity of I_{Vmain}, and two sub-peaks having maximal value for the respective intensities of I_{Vsub-} and I_{Vsub+}, as one of means for attaining 0<I_{Vsub}/I_{Vmain}<0.5 (I_{Vsub} is I_{Vsub-} or I_{Vmain+} which has larger intensity).

Although not illustrated in FIG. 8, a layer comprising a material such as AlGaAs material systems, InGaP material systems, etc. selected properly with a view point of the lattice matching with the substrate (1) or with a view point of rather introducing strains intentionally with the band gap being closer to the first-conduction-type first clad layer (3) on the side of the first-conduction-type first clad layer (3) and being closer to the first-conduction-type second clad layer (4) on the side of the first-conduction-type second clad layer (4) can be inserted between the first-conduction-type first clad layer (3) and the first-conduction-type second clad layer (4). Such a transition layer is extremely preferred since this can decrease electric resistance upon injection of carriers from the side of the first-conduction-type first clad layer (3) through the first-conduction-type second clad layer (4) into the active layer structure (6).

The first optical guide layer (5) over the first-conduction-type second clad layer (4) can be constituted with various kinds of materials which are properly selected in accordance with the active layer structure (6) or the substrate (1) selected in accordance with the oscillation wavelength intended to be attained. For example, in a case of attaining the invention on a GaAs substrate, AlGaAs material systems, InGaP material systems, AlGaInP material systems, etc. can be used and, in a case, for example, of attaining the invention on an InP substrate, InGaAsP material systems, etc. can be used.

In a case of constituting the first optical guide layer (5) with an AlGaAs material system, it is necessary to constitute the first optical guide layer (5) with a material of a less Al composition than that of the first-conduction-type first clad layer (3) in order to attain optical confinement. Specifically, the Al composition of the first optical guide layer (5) is, preferably, less than 0.4, more preferably, less than 0.2 and, further preferably, less than 0.1. A most preferred is a case of using GaAs not containing Al. Particularly, with a view point of the reliability, an optical guide not containing Al is desired.

Further, the thickness t_{gn} (nm) of the first optical guide layer (5) preferably satisfies the following formula in order that the first-conduction-type second clad layer (4) provides the function sufficiently:
0.5×[λ/(4×N_{gn})]nm<t_{gn}<1.5×[λ/(4×N_{gn})]nm
In the formula, N_{gn} is a refractive index of the first optical guide (5). By restricting the thickness t_{gn} of the first optical guide layer (5) to smaller than the upper limit in the formula, it is particularly possible to sufficiently provide the effect of suppressing the overflow of carriers in the first-conduction-type second clad layer (4) and effectively avoid lowering of the kink level, etc. Further, by restricting the thickness t_{gn} of the first optical guide layer (5) to larger than the lower limit in the formula, it is possible to suppress the first-conduction-type second clad layer (4) from exhibiting excessive anti-waveguide property.

Particularly, in a case of constituting the first optical guide layer (5) with an AlGaAs material system, it is not always necessary that the first optical guide layer (5) comprising AlGaAs with a thickness of t_{gn} is a layer having a constant Al composition but the Al composition can also be changed in the first optical guide layer (5). In a case where regions of different Al compositions are present in the first optical guide (5), an average refractive index thereof can be considered as the refractive index of the first optical guide layer.

The conduction type of the first optical guide layer (5) may be a p-type, n-type or undoped type and the effect of the invention does not change depending on the type.

The situation described above is identical also for the second optical guide layer (7) situated over the active layer structure (6).

The active layer structure (6) referred to in the invention includes a case of a bulk single active layer having such a sufficient film thickness as not developing the quantum effect, or a case of a single quantum well layer (SQW) comprising such a thin film as the quantum effect becomes remarkable in which the optical guide layer has a role as a barrier layer. Further, since barrier layers each having a band gap larger than that of the quantum well layer are often provided on both sides of the quantum well layer, it can also include a case in which a barrier layer, a quantum well layer and a barrier layer are stacked in an identical SQW structure. Further, the active layer structure may be a so-called strained double quantum well structure (S-DQW) as shown in FIG. 8 in which a barrier layer (21), a quantum well layer (22), a barrier layer (23), a quantum well layer (24), and a barrier layer (25) are stacked from the side of the substrate (1). Further, a multi-quantum well structure in which three or more multiple quantum well layer are sometimes used. Further, strains are sometimes introduced intentionally to the quantum well layers and, for example, compressive stress is generally incorporated in order to lower the threshold current. Further, in a semiconductor laser having a wavelength of about 900 nm to 1350 nm which is applied preferably in the invention, this is preferably attained by including a strained quantum well layer containing In, Gs, and As and not lattice matched to a substrate on a GaAs substrate.

The specific material for the strained quantum well layer can include, for example, InGaAs and GaInNAs. Increase of the optical gain, etc. can be expected by the quantum well layer having strains due to the strain effect thereof. Accordingly, even for appropriately weak optical confinement in the vertical direction between the first clad layer (3, 9, 10) and the active layer structure (6), a sufficient LD characteristic can be attained. Therefore, the strained quantum well layer is desirable in the invention.

While the effect of the invention does not change when the conduction type of the barrier layer (21, 23, 25) is a p-type, n-type or undoped type, it is desirable that the barrier layer (21, 23, 25) has a portion showing the n-conduction type. Under such a situation, since electrons are supplied from the barrier layer (21, 23, 25) to the quantum well layer (22, 24) in the active layer structure, the gain characteristics of the LD can be attained desirably for the wider band region effectively. In the device described above, the oscillation wavelength can be fixed effectively by an external cavity such as a grating fiber as will be described later. In this case, then-type dopant is preferably Si. Further, the n-type dopant such as Si is not doped uniformly in the barrier layer (21, 23, 25) but it is most preferred that doping is not applied near the boundary with respect to other layers such as the strained quantum well layer (22, 24) and doping is selectively applied near the center of the barrier layer (21, 23, 25).

The second-conduction-type second clad layer (8) can be constituted with various kinds of materials which are properly selected in accordance with the active layer structure (6) or substrate (1), etc selected depending on the oscillation wavelength to be attained. For example, in a case of attaining the invention on a GaAs substrate, AlGaAs material systems, InGaP material systems, AlGaInP material systems, etc. can be used. Further, in a case of attaining the invention, for example, on an InP substrate, InGaAsP material systems, etc. can be used.

In a case of constituting the second-conduction-type second clad layer (8) with an AlGaAs material system, the Al composition is preferably less than 0.5. The Al composition in the second-conduction-type second clad layer (8) has to be larger than the Al composition in the second-conduction-type lower first clad layer (9) and the Al composition in the second optical clad layer (7) adjacent therewith. By the use of such a constitution, the second-conduction-type second clad layer (8) becomes a layer with least refractive index and has a function as a barrier against electrons on the side of the conduction band and holes in the valence band. Further, the difference between the Al composition of the second-conduction-type second clad layer (8) and the Al composition of the second-conduction-type lower first clad layer (9) is preferably larger than 0.08. With this constitution, the second-conduction-type second clad layer (8) can sufficiently suppress the overflow of carriers from the active layer structure (6) to the second-conduction-type lower first clad layer (9). However, the difference of the Al composition is preferably less than 0.4 so as not to excessively inhibit the injection of carriers from the second-conduction-type lower first clad layer (9) to the active layer structure (6).

The thickness tₛₚ (nm) of the second-conduction-type second clad layer (8) is preferably smaller than the thickness t_{gp} (nm) for the second optical guide layer (7). Use of such a constitution can avoid extreme increase of the threshold current, lowering of the slope efficiency and increase of the driving current. In order to obtain an appropriate NFP expanding effect in the vertical direction, it is preferred that tₛₚ/t_{gp} is larger than 0.3. Further, the thickness top of the second-conduction-type second clad layer (8) is, preferably, larger than 10 nm and smaller than 100 nm. In a case where the tₛₚ of the second-conduction-type second clad layer (8) is 10 nm or smaller, the optical effect is sometimes reduced. On the other hand, when it is 100 nm or larger, the optical confinement is sometimes weakened extremely and the LD oscillates no more.

It is not always necessary that the second-conduction-type second clad layer (8) has the same refractive index, same thickness and same material as those of the first-conduction-type second clad layer (4), but it is desirable that it has an optically equivalent refractive index and an identical thickness with an aim of ensuring the symmetricity of the beam in the vertical direction.

Further, assuming the average refractive index of the active layer structure (6) as Nₐ, the average refractive index of the second-conduction-type second clad layer (8) as Nₛₚ, and the average refractive index of the second-conduction-type first clad layer (9, 10) to be described as Nₓₚ, it is desirable that the refractive indexes satisfy: Nₛₚ<Nₓₚ<Nₐ. This is one of means for realizing: 0<I_{Vsub}/I_{Vmain}<0.5 for a main peak having a maximum value for the intensity of I_{Vmain}, and two sub-peaks having maximal values for the respective intensities of I_{Vsub-} and I_{Vsub+} present in the FFP_{V} of the completed device (I_{Vsub} is I_{Vsub-} of I_{Vmain+} which has larger intensity).

Particularly, assuming the crystal growth is conducted by an MBE method, for example, in a case where the second conduction type is an p-type and Be is used as the dopant, the doping level is, preferably, from 3.0×10¹⁷ cm⁻³ to 1.0×18 cm⁻³ and, more preferably, from 4.0×10¹⁷ cm⁻³ to 7.5×10¹⁷ cm⁻³.

Although not illustrated in FIG. 8, a layer comprising a material such as AlGaAs material systems, InGaP material systems, etc. in which the material is selected properly with a view point of the lattice-matching with the substrate (1) or with a view point of intentionally introducing strains contrarily with the band gap being closer to the second-conduction-type second clad layer (8) on the side of the second-conduction-type second clad layer (8) and being closer to the second-conduction-type lower first clad layer (9) on the side of the second-conduction-type lower first clad layer (9) can be inserted between the second-conduction-type second clad layer (8) and the second-conduction-type lower first clad layer (9). Such a transition layer is extremely preferred since this can decrease electric resistance upon injection of carriers from the side of the second-conduction-type first clad layer (9, 10) through the second-conduction-type second clad layer (8) into the active layer structure (6).

The second-conduction-type first clad layer consists of two layers of a second-conduction-type lower first clad layer (9) and a second-conduction-type upper first clad layer (10) in the embodiment of FIG. 8. In this case, the two layers may have an etching stop layer therebetween in order to facilitate the fabrication of the device.

The material for the second-conduction-type first clad layer (9, 10) can be selected in the same manner as the second-conduction-type second clad layer (8) described above. Particularly, in a case of using the AlGaAs material system as the material for the second-conduction-type first clad layer (9, 10), in order to lower thermal resistance of the entire device and provide a structure suitable for high power operation, the Al composition in the second-conduction-type first clad layer (9, 10) is, preferably, less than 0.40, more preferably, 0.3 or less and, further preferably, 0.2 or less. Further, the entire thickness of the second-conduction-type lower first clad layer (9) and the second-conduction-type upper first clad layer (10) is preferably made larger than the oscillation wavelength λ since it is necessary to sufficiently decay the light in the direction receding from the active layer structure (6).

The thickness of the second-conduction-type first clad layer (9) is preferably about from 10 nm to 200 nm so that the current injection path to the active layer is not widened extremely due to the horizontal diffusion of the current. More preferably, it is about from 20 nm to 70 nm.

Further, the doping level for the second-conduction-type lower first clad layer (9) and second-conduction-type upper first clad layer (10) is, preferably, from 1.0×10¹⁷ cm⁻³ to 1.0×10¹⁸ cm⁻³ and, more preferably, from 3.0×10¹⁷ cm⁻³ to 7.5×10¹⁷ cm⁻³.

Further, it is not necessary that doping is conducted uniformly in the second-conduction-type lower first clad layer (9) or the second-conduction-type upper first clad layer (10) and, it is preferably set higher on the side nearer to the contact layer (13) and lower on the side nearer to the active layer structure (6). This is an effective method for suppressing the absorption by free electrons in a portion where the optical density is high.

The second-conduction-type upper first clad layer (10) provides two functions of the current confinement and the optical confinement in the horizontal direction, together with the current block (11) formed on the sides thereof. This is a preferred constitution when the invention is applied to an LD that operates in a single transverse-mode. For this purpose, the conduction type of the current block layer (11) is preferably a first conduction type or an undoped type with a view point of the current confinement in the horizontal direction. Further, with the view point of the optical confinement in the horizontal direction and, particularly, for satisfying the characteristics as the waveguide based on the index waveguide, the current block layer (11) is formed of a material having a refractive index smaller than that of the second-conduction-type first clad layer (9, 10). In this case, the FFP_{H} fundamentally has one maximal value in the radiation pattern of the main peak which is desirable in the invention. Further, the optical confinement in the horizontal direction can also be constituted as a so-called loss guide type. In this case, since the FFP_{H} in the horizontal direction in the radiation pattern of the main peak can fundamentally have one maximal value by adapting such that the effective band gap of the material constituting the current block layer (11) absorbs the oscillation wavelength, it is desirable in the invention.

Further, in the invention, the material constituting the current block layer (11) can be selected properly depending on the substrate (1), the active layer structure (6) or depending on the waveguide structure in the horizontal direction. For example, in a case where the current block layer (11) is also formed of an AlGaAs material together with the second-conduction-type first clad layer (9, 10) and they are defined as AlₓₚGa₁₋ₓₚAs and Al_{z}Ga_{1-z}As, respectively, a real-refractive-index-guided structure can be realized when the Al composition is defined as: z>xp. In a case of manufacturing a semiconductor laser which is a real refractive index waveguide type and operates in a single transverse-mode, the effective refractive index difference in the horizontal direction defined mainly by the difference of refractive index between the current block layer (11) and the second-conduction-type upper first clad type (10) is preferably at the order of 10⁻³. Further, the width W in the horizontal direction for a portion where the second-conduction-type upper first clad layer (10) is in contact with the second-conduction-type lower first clad layer (9), which is the width for the current injection channel and corresponds to the width of the waveguide is preferably uniform within a range of an error in the direction of the cavity vertical to the drawing and the width is preferably 6 μm or less and, more preferably, 3 μm or less with a view point of operating the LD in the single transverse-mode. However, for making the high power operation and the single transverse-mode operation compatible, the waveguide is not necessarily uniform in the direction of the cavity but it is preferred that the width for the waveguide is relatively increased on the side of the front facet as the main light emitting direction of the semiconductor laser so as to be suitable for the high power operation, whereas the width for the waveguide is narrowed on the side of the back facet to enable the single transverse-mode operation. Further, in this case, it is desirable to satisfy the following formula assuming the width for the current injection channel near one of light emission points as Wₑₓₚ and the width for the narrowest current injection channel in the device as W_{std}:
1.5<Wₑₓₚ/W_{std}<5.0
It is further preferred to satisfy the following formula:
2.5<Wₑₓₚ/W_{std}<3.5

The cap layer (12) is used as a protective layer for the current block layer (11) in the first growth, as well as used for facilitating the growth of the second-conduction-type upper first clad layer (10) and it is partially or entirely removed before obtaining a device structure.

A contact layer (13) is preferably disposed over the second-conduction-type upper first clad layer (10) with an aim of lowering the contact resistivity to the electrode (14), etc. The contact layer (13) is usually constituted with a GaAs material system. In the layer, the carrier concentration is usually made higher than in other layers so as to lower the contact resistivity to the electrode (14). Further, the conduction type is a second conduction type.

The thickness for each of the layers constituting the semiconductor laser is properly selected within such a range as providing the function of the respective layers effectively.

Further, in the semiconductor laser according to the invention, the first conduction type is preferably an n-type and the second conduction type is preferably a p-type. This is because an n-type substrate often has a good quality.

The semiconductor laser shown in FIG. 8 is fabricated by further forming electrodes (14) and (15). The electrode (14) on the side of the epitaxial layer is formed, for example, in a case where the second conduction type is the p-type, evaporated Ti/Pt/Au are successively formed on the surface of the contact layer (13) and then applying an alloying treatment. On the other hand, the electrode (15) on the side of the substrate is formed on the surface of the substrate (1) and, in a case where the first conduction type is the n-type, evaporated AuGe/Ni/Au are successively formed on the surface of the substrate (1) and then applying an alloying treatment.

A facet as a light emitting surface is formed to the fabricated semiconductor wafer. The facet is a mirror that constitutes a cavity. Preferably, the facet is formed by cleaving. Cleaving is a generally used method and the facet formed by cleaving is different depending on the orientation of the substrate (1) to be used. For example, in a case of forming a device such as an edge-emission-type laser by using a substrate having a surface crystallographically equivalent with the nominally (100) plane utilized suitably, a (110) plane or a plane crystallographically equivalent therewith constitutes a surface that forms a cavity. On the other hand, in a case of using an off angle substrate, the facet does not sometimes form 90 degrees with respect to the direction of the cavity depending on the relation between the inclined direction and the direction of the cavity. For example, in a case of using the substrate (1) which is inclined by an angle of 2 degrees from the (100) substrate to the (1-10) direction, the facet is also inclined by 2 degree.

The cavity length of the device is also decided by cleaving. Generally, longer cavity length is suitable for the high power operation, and it is, preferably, from 600 μm or more and, more preferably, from 900 μm to 3000 μm in the semiconductor laser to which the invention is applied. The upper limit is defined for the cavity length as described above, because a semiconductor laser having an extremely long cavity length may rather result in deterioration of characteristics such as increase in the threshold current and lowering of the efficiency.

In the invention, coating layer (16, 17) each comprising a dielectric material or a combination of a dielectric material and a semiconductor are formed preferably formed on the exposed facet of the semiconductor as shown in FIG. 3. The coating layer (16, 17) is formed mainly for two purpose of increasing the efficiency for taking out a light from the semiconductor laser and for protecting the facet. Further, in order to take out the light output power from the device efficiently from the facet on one side, it is preferred to conduct asymmetric coating of applying a coating layer with a low reflectivity (for example, 10% or less of reflectivity) relative to the oscillation wavelength to the front facet as the main light emission direction, while applying a coating layer with a high reflectivity (for example, 80% or more) relative to the oscillation wavelength to the other back facet. This is extremely important not only for enhancing the power of the device higher but also for positively taking a light returned from an external cavity such as a grating fiber used for the stabilization of wavelength into the laser thereby promoting the stabilization of the wavelength. Further, for the purposes described above, the reflectivity at the front facet is, preferably, 5% or less and, more preferably, 2.5% or less.

For the coating layer (16, 17), various materials can be used. For example, it is preferred to use one member selected from the group consisting of AlOₓ, TiOₓ, SiOₓ, SiN, Si and ZnS or a combination of two or more of them. AlOₓ, TiOₓ, SiOₓ, etc. are used for the coating layer at low reflectivity, while AlOₓ/Si multi-layered films, TiOₓ/SiOₓ multi-layered films, etc. are used for the coating layer at high reflectivity. An aimed reflectivity can be attained by controlling the respective film thickness. However, the film thickness of AlOₓ, TiOₓ, SiOₓ, etc. as the coating layer at low reflectivity is generally controlled so as to be near λ/4n, n being the real number portion of the refractive index at the wavelength λ. Further, also in a case of the highly reflective multi-layered film, each of the materials constituting the film is generally controlled so as to be near λ/4n.

By cleaving the laser bar after completion of the coating again, respective devices can be separated to form semiconductor lasers.

In the thus fabricated device or also in a device further having other layers, a good coupling of a semiconductor laser with an optical system comprising an optical fiber and a lens, etc. can be realized by effectively decreasing the full width of the half maximum of the FFP_{V} without extremely worsening the main characteristics of the semiconductor laser by using the invention. That is, in a semiconductor laser in which the refractive index, thickness and the like of the first clad layer (3, 9, 10), the second clad layer (4, 8), the optical guide layer (5, 7), and the active layer structure (6) are appropriately set and the normalized frequency is π/2 or less so as to allow only the propagation of the fundamental-mode in the vertical direction, 0<I_{Vsub}/I_{Vmain}<0.5 can be attained for a main peak with the maximum intensity of I_{Vmain} and two sub-peaks with maximal intensity of I_{Vsub-} and I_{Vsub+} respectively present in the FFP_{V} in the radiation pattern of light emitted from the semiconductor laser (I_{Vsub} represents I_{Vsub-} or I_{Vsub+} which is larger). In the invention, 0<I_{Vsub}/I_{Vmain}<0.5 is essential and it is preferably: 0<I_{Vsub}/I_{Vmain}<0.3 and, more preferably, 0.05<I_{Vsub}/I_{Vmain}<0.2. The indexes are defined due to absolute or relative relations such as (average) refractive index, thickness, etc. of the first clad layer (3, 9, 10), the second clad layer (4, 8), the optical guide layer (5, 7), and the active layer structure (6). For example, extreme lowering of the refractive index or increase of the thickness of the second clad layer (4, 8) or extreme reduction in the thickness of the optical guide layer (5, 7), etc. are not desired since the waveguide tends to exhibit excessively anti-waveguide property to weaken the optical confinement in the vertical direction in the LD structure and, as a result, lead to extreme increase in the threshold current, lowering of the slope efficiency and increase in the driving current.

Further, in the semiconductor device in which the refractive index, thickness, etc. of the first clad layer (3, 9, 10), the second clad layer (4, 8), the optical guide layer (5, 7), and the active layer structure (6), etc. are set extremely appropriately according to the invention in which only the propagation in the fundamental-mode is allowed with respect to the vertical direction, assuming the angle at which the main peak appears as P(I_{Vmain}), and angles at which the two sub-peaks at I_{Vsub-} and I_{Vsub+} appear as P(I_{Vsub-}), P(I_{Vsub}), respectively, it is desirable to satisfy the following formulae in the invention:

A more preferred range is identical with the preferred range in the description for FIG. 5 described above.
|P(I_{Vmain})−P(I_{Vsub-})|>40 degrees
|P(I_{Vsub+})−P(I_{Vmain})|>40 degrees
|P(I_{Vsub+})−P(I_{Vsub-})|>80 degrees

Further, also in this case, an appropriate design is conducted for the vertical direction as described above and, as a result of having the real-refractive-index-guided structure, it is most preferred that the following formula is satisfied assuming maximum value for the FFP_{H} as I_{Hmain} and the angle at which the same appears as: P(I_{Hmain}):
|P(I_{Vmain})−P(I_{Hmain})|<5 degree

For stabilization of the wavelength to the semiconductor laser of the invention, it is desirable to provide a mirror having selectivity to the wavelength at the outside of the laser and couple the external cavity with a laser of the invention. Particularly, it is preferred to form an external cavity by using a fiber grating. Further, in this case, it is also possible to form a semiconductor laser module incorporated with a fiber grating, a cooler for temperature stabilization, etc. in addition to the semiconductor laser. For the fiber grating, the center wavelength, the reflection or transmission zone, the reflectivity of light to the laser of the fiber grating, etc. can properly be selected in accordance with the purpose thereof. Particularly, it is preferred that the reflectively of light of the fiber grating to the laser is from 2 to 15%, preferably, 5 to 10% at the oscillation wavelength of the laser and the reflection zone thereof is from 0.1 to 5.0 nm, preferably, from 0.5 to 1.5 nm relative to the center wavelength.

Semiconductor Light Emitting Device Satisfying Condition 3

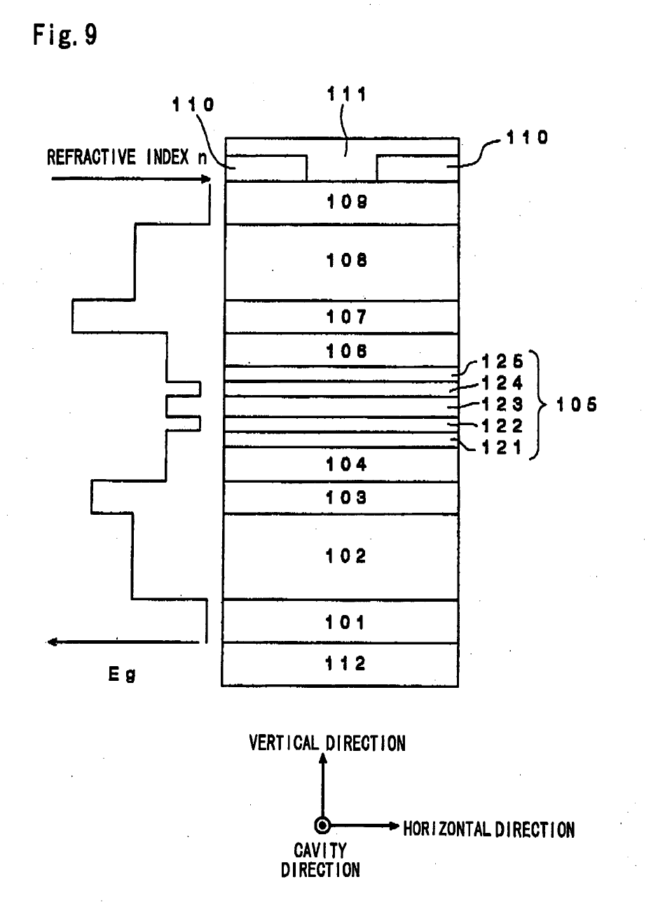

Next, main features of a semiconductor light emitting device according to the invention satisfying the condition 3 are to be described with reference to an LD shown in FIG. 9, FIG. 9 shows a spatial distribution in the vertical direction of the refractive index obtained by the structure for each of the layers on the left side, and FIG. 9 shows the designation for the directions used in the drawings on the lower side.

FIG. 9 shows a broad area type LD comprising, on an n-type substrate (101), an n-type first clad layer (102) comprising Al_{0.25}Ga_{0.75}As at a thickness of tₙ₁ (nm), an n-type second clad layer (103) comprising In_{0.49}Ga_{0.51}P at a thickness of tₙ₂ (nm), a first optical guide layer (104) comprising undoped GaAs at a thickness of t_{ng} (nm), an active layer structure (105) at a thickness of tₐ (nm), a second optical guide layer (106) comprising undoped GaAs at a thickness of t_{pg} (nm), a p-type second clad layer (107) comprising Al_{0.47}Ga_{0.53}As at a thickness of tₚ₂ (nm), and a p-type first clad layer (108) comprising Al_{0.23}Ga_{0.77}As at a thickness of tₚ₁ (nm), and a contact layer (109) for lowering the contact resistance with an electrode (111), as well as an SiN layer (110) for restricting the current injection region relative to the horizontal direction, a p-side electrode (111) and an n-side electrode (112). In the semiconductor light emitting device of the invention, paired layers such as the n-type first clad layer (102) and the p-type first clad layer (108), etc. may be symmetrical but description will be made to an asymmetric case.

Further, active layer structure (105) is a strained double quantum well structure having a structure in which a GaAs barrier layer (121) of 5 nm thickness, an In_{0.16}Ga_{0.94}As strained quantum well layer (122) of 6 nm thickness, a GaAs barrier layer (123) of 8 nm thickness, an In_{0.16}Ga_{0.84}As strained quantum well layer (124) of 6 nm thickness, and a GaAs barrier layer (125) of 5 nm thickness, are stacked from the side of the substrate (101), and has an oscillation wavelength λ (nm).

In the invention, the confinement in the vertical direction to the active layer structure (105) as a basis for the waveguide mechanism in the device of the semiconductor laser is attained by the difference of the refractive index between the Al_{0.25}Ga_{0.75}As n-type first clad layer (102), the Al_{0.23}Ga_{0.77}As p-type first clad layer (108) situated under and over the active layer structure (105), and the two GaAs optical guide layers (104, 106) between which the active layer structure (105) is sandwiched. In a case where the GaAs substrate (101) is used, and the first clad layer (102) is constituted with AlₓGa₁₋ₓAs in view of the lattice matching, the Al composition x is, preferably, less than 0.4, more preferably, less than 0.3 and, further preferably, less than 0.2. With this composition, thermal resistance for the entire device can be lowered by decreasing the Al composition in the clad layer which is most thick among the layers constituting the entire semiconductor laser except for the substrate (101) and the contact layer (109), and a structure suitable for high power operation can be provided. Further, in a case where the GaAs substrate (101) is used, In_{0.49}Ga_{0.51}P is applicable to the n-type first clad layer (102) in view of the lattice matching. Further, it is not necessary that the first clad layer (102, 108) is constituted with a single material but they may comprise plural layers that function in an equivalent manner with the single layer relative to light. In this case, the light is controlled by an average refractive index of the plural layers.

The thickness tₙ₁ (nm) and tₚ₁ (nm) of the first clad layers (102, 108) preferably satisfy the following formulae to the oscillation wavelength λ (nm) since it is necessary to sufficiently decay the light in the layer in the direction receding from the side of the active layer structure (105):
λ<tₙ₁ λ<tₚ₁
Particularly, in a case where the substrate (101) is transparent to the oscillation wavelength and the refractive index is larger than that of the n-type first clad layer (102) and the n-type second clad layer (103) as in a case of the 980 nm band LD, it is known that the substrate-mode overlaps the inherent LD mode since the light leaked from the clad layer (102, 103) to the substrate (101) propagates through the substrate. In order to suppress the same, it is desirable that the thickness of the n-type first clad layer (102) is increased relative to the wavelength.

Further, for attaining the waveguide structure in the vertical direction near the active layer structure (105), it is necessary that both the second optical guide layer (106) and the first optical guide layer (104) are constituted with a material of a larger refractive index than the first clad layer (102, 108). In a case where the substrate (101) comprises GaAs and the clad layers (102, 103, 107, 108) is constituted with an AlGaAs material system, it is preferred that also the optical guide layer (104, 106) is constituted with an AlGaAs material system. Further, the Al composition is, preferably, less than 0.4, more preferably, less than 0.2 and, further preferably, less than 0.1. Use of GaAs not containing Al is a most preferred case. Particularly, with a view point of the reliability, an optical guide layer (104, 106) not containing Al is desired. On the other hand, in a case where the substrate (101) comprises GaAs, In_{0.49}Ga_{0.51}P can also be selected with a view point of the lattice matching and with a view point of not containing Al as the constituent element.

The active layer structure (105) referred to in the invention means an active layer structure containing a quantum well comprising a thin film which is so thin as the quantum effect becomes remarkable and includes, for example, a case of a single quantum well layer (SQW) in which the optical guide layer has a role of the barrier layer. Further, since barrier layers each having a larger band gap than the quantum well layer are often provided on both sides of the quantum well layer, it can include also a case of the identical SQW structure in which a barrier layer are stacked, a quantum well layer, and a barrier layer are stacked. Further, as shown in FIG. 9, the active layer structure may be a so-called strained double quantum well structure (S-DQW) comprising a barrier layer (121), a quantum well layer (122), a barrier layer (123), a quantum well layer (124), and a barrier layer (125) stacked from the side of a substrate (101). Further, a multiple quantum well structure using multiple quantum well layers by three or more layers may also be used. Further, strains are sometimes introduced intentionally in the quantum well layer and, for example, compressive stress is generally incorporated for lowering the threshold current. Further, a semiconductor laser having a wavelength of about 900 nm to 1350 nm applied preferably in the invention is attained by including a strained quantum well layer containing In, Ga and As and not lattice matched to the substrate over GaAs substrate.

In the invention, it is essential that the following two values calculated from the first clad layer (102, 108), the optical guide layer (104, 106), and the active layer structure (105) are within a desired range. Specifically, the semiconductor light emitting device of the invention has a feature in that Vₙ calculated such that the n-side first clad layer (102) is present not only on the n-side where it is actually present but also is assumed to be present on the p-side instead of the p-side first clad layer (108) satisfies: 0.35<Vₙ<0.75, and in that Vₚ calculated such that the p-side first clad layer (108) is present not only on the p-side where it is actually present but also is assumed to be present on the n-side instead of the n-side first clad layer (102), independently thereof, satisfies: 0.35<Vₙ<0.75. Vₙ and Vₚ are defined by the following formulae respectively (k represents the wave number of 2π/λ), and are provided with physical meanings to be described later.
Vₙ=k/2×(tₐ+t_{ng}+t_{pg})×(n_{ng}²−nₙ₁²)^{1/2}
Vₚ=k/2×(tₐ+t_{ng}+t_{pg})×(n_{pg}−nₙ₂)^{1/2}

Since the active layer structure (105) and the optical guide layer (104, 106), etc., have relatively higher refractive index relative to the clad layers (102, 103, 107, 108), they provide a waveguide function. Vₙ and Vₚ are defined by primary normalization of the entire thickness for the layers having the waveguide function with the oscillation waveguide of the device also taking the refractive index difference between the first clad layer (102, 108) and the optical guide layer (104, 106) into consideration. That is, it can be said that Vₙ and Vₚ are index for defining the optical confinement near the active layer. In the definition for Vₙ and Vₚ, the average refractive index of the active layer structure is not included, because the thickness of the active layer structure (105) in the invention is sufficiently thin to the oscillation wavelength since it basically has the quantum well structure, and the difference of the refractive index between the optical guide layer (104, 106) and the first clad layer (102, 108) is a main factor in view of the description of the waveguide function. From the view point, in a case where the thickness of the barrier layer constituting the active layer structure, particularly, the barrier layer (121, 125) as the outermost layer of the active layer structure is set extremely thick and the waveguide function is not negligible, this is considered to be the thickness of the optical guide layer.

In a case where the structure of the light emitting device is asymmetrical with respect to the vertical direction, Vₙ and Vₚ have respectively different values and it is essential that both of them are larger than 0.35 and smaller than 0.75. Further, in a case of a structure which is symmetrical with respect to the vertical direction, Vₙ=Vₚ. It is essential that both Vₙ and Vₚ are more than 0.35 and less than 0.75 also in this case.

Further, it is further preferred for a case where Vₙ is: 0.4<Vₙ<0.6 and, in the same manner, it is further preferred for a case where Vₚ is: 0.4<Vₚ<0.6. The ranges described above are essential factors for narrowing the FFP_{V} of the device without deteriorating the characteristics of the semiconductor light emitting device in view of the balance with the anti-waveguide factor due to the second clad layer (103, 107) to be described later.

In a case of a usual SCH structure (Separated Confinement Hetero-structure), the first clad layer (102, 108) and the optical guide layer (104, 106) are in contact directly with each other, but the invention has a feature in that the layers have the second clad layer (103, 107) therebetween. It is necessary that the refractive index of the layer is set lower than that of the optical guide layer (104, 106) and, further, lower than that of the first clad layer (102, 108).

As a result, as shown on the left side of FIG. 9, the second clad layer (103, 107) is a layer having the least value as the refractive index. On the left side of FIG. 9, the direction of the arrow described below “In” means a direction in which the refractive index increases. The second clad layer (103, 107) has a function as a barrier against the electrons in the conduction band (also against holes in the valence band although not illustrated). The direction of the arrow described above Eg on the left side of FIG. 9 means the direction along which the potential increases relative to electrons.

Accordingly, the second clad layer (103, 107) has an extremely important function regarding the optical confinement in the vertical direction as will be described next. Since the second clad layer (103, 107) is selected such that the refractive index is lower than that of the optical guide layer (104, 106) and the first clad layer (102, 108), the second clad layer (103, 107) provides a function of expanding the distribution of light to the outside thereof, that is, to both sides of the first clad layer (102, 108) and the optical guide layer (104, 106) owing to the relative relation of the refractive index. Accordingly, the component of the NFP_{V} with a distribution being expanded properly to the side of the first clad layer (102, 108) contributes to attain a relatively narrow FFP. That is, in a case where the anti-waveguide property of the second clad layer (103, 107) functions adequately, a relatively narrow FFP can be attained without worsening the characteristic of the semiconductor laser.

The important feature of the invention is that the waveguide function near the active layer is selected so as to satisfy: 0.35<Vₙ<0.75 and 0.35<Vₚ<0.75 and that the anti-waveguide function developed by the second clad layer (103, 107) satisfies the two factors shown below. One of them is that a relative thickness tₙ₂/t_{ng} of the n-side second clad layer (103) to the first guide layer (104) is: 0.3<Rₙ<0.7 and the other of them is that the relative thickness tₚ₂/t_{pg} of the p-side second clad layer (107) to the second guide layer (106) is: 0.3<Rₚ<0.7, that is, the upper limits for the latter two conditions are essential in order that the waveguide structure in the vertical direction prepared in the semiconductor laser do not exhibit anti-waveguide property as a whole and the lower limits show the necessary thickness for effectively narrowing the width of the FFP_{V}.

Further, it is more preferred that the relative thickness of the second clad layer (103, 107) to the optical guide layer (104, 106) satisfies: 0.35<Rₙ<0.55 and also satisfies: 0.35<Rₚ<0.55.

Another function of the second clad layer (103, 107) is to suppress thermal leakage of carriers (overflow) from the In_{0.16}Ga_{0.84}As strained quantum well layer (122, 124) to the first clad layer (102, 108), for example, in a case where the LD is driven at high temperature or the temperature of the active layer increases considerably by the self heat generation of the LD during high power operation. In this structure, since the barrier height for the second clad layer (103, 107) is higher than the barrier height between the optical guide layer (104, 106) and the first clad layer (102, 108) in view of the carriers that leak from the active layer structure (105) through the optical guide layer (104, 106) to the first clad layer (102, 108) as shown in FIG. 9, this is desirable also with a view point of suppressing the carrier overflow. However, since an extremely high barrier height inhibits the injection of carriers that are injected from the first clad layer (102, 108) to the active layer structure (105), the difference of the band gap between the first clad layer (102, 108) and the second clad layer (103, 107) is, preferably, about from 0.05 eV to 0.45 eV and, more preferably, about from 0.1 eV to 0.3 eV.

Further, with the view point described above, it is also preferred that the n-side second clad layer (103) and the p-side second clad layer (107) are constituted with different kinds of materials having approximately identical refractive index. While In_{0.49}Ga_{0.51}P used for the n-side second clad layer (103) and Al_{0.47}Ga_{0.53}As used for the p-side second clad layer (107) as exemplified above have approximately identical refractive indexes at 980 nm (3.259 and 3.268, respectively), the state of forming the band offset to the GaAs barrier layer (121, 125) as the outmost layer of the active layer structure (105) or GaAs as the optical guide layer (104, 106) are greatly different. It is considered that about 70 to 80% of the barrier height is distributed on the side of the conduction band to GaAs in Al_{0.47}Ga_{0.53}As, whereas it is considered that about 60% of the barrier height is distributed on the side of the valence band in In_{0.49}Ga_{0.51}P. Accordingly, for suppressing the overflow of carriers, it is desirable to use the InGaP material system on the n-side and the AlGaAs material system on the p-side as the second clad layer (103, 107).

Further, for suppressing the carrier overflow in the second clad layer (103, 107), it is not desirable that the second clad layer (103, 107) is situated extremely apart from the active layer structure (105) and, as a result, it is preferred that the thickness t_{ng} and t_{pg} for the optical guide layers (104, 106) are: 40 nm<t_{ng}<100 nm, and 40 nm<t_{pg}<100 nm as the absolute values thereof.

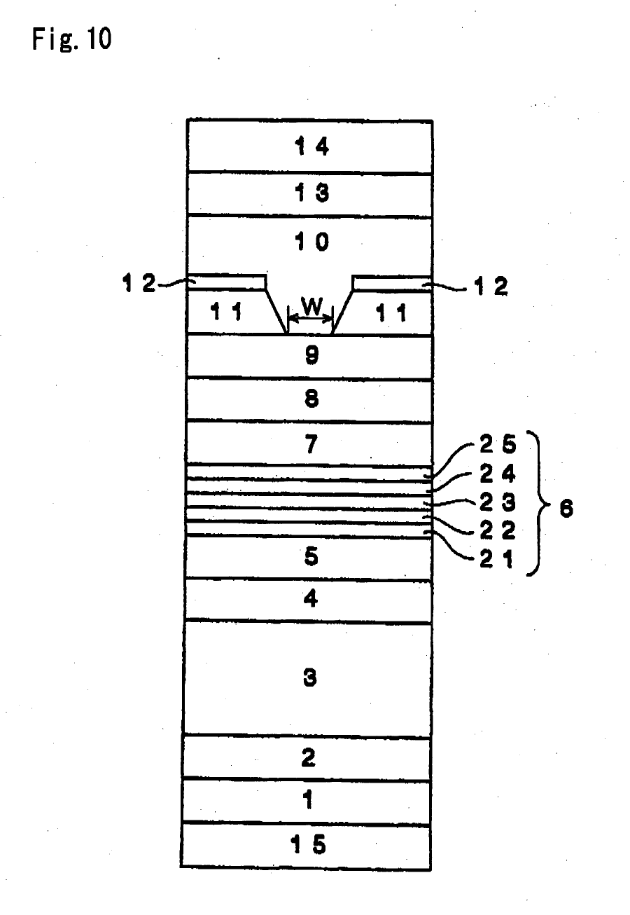

Next, description is to be made to a semiconductor laser capable of single transverse-mode operation as an example of the semiconductor light emitting device according to the invention with reference to FIG. 10. FIG. 10 is a schematic cross sectional view showing the constitution of a buried-stripe type semiconductor laser as an example of an epitaxial structure in the semiconductor laser according to the invention.

The semiconductor laser is formed over a first-conduction-type semiconductor substrate (1), has a refractive-index-guided structure in which a second-conduction-type first clad layer consists of two layers of a second-conduction-type upper first clad layer (10) and a second-conduction-type lower first clad layer (9), the second-conduction-type upper first clad layer (10) and the current block layer (11)/cap layer (12) attain current confinement and optical confinement and, further, has a contact layer (13) for lowering the contact resistance with the electrode (14). The laser of this type is used as a light source for optical fiber amplifiers used in optical communication, as a pick-up light source for large scaled opto-magnetic memories used in information processing, a high-power semiconductor laser for medical use and, further, can be applied to various uses by properly selecting the layer constitution or materials to be used.

As the substrate (1), GaAs, InP, GaP, GaN, etc. can be used for the semiconductor substrate, and AlOₓ, etc. can be used for the dielectric substrate. For the substrate (1), not only a so-called just substrate but also a so-called off angle substrate (miss oriented substrate) can be used with a viewpoint of improving the crystallinity upon epitaxial growth. The off angle substrate has an effect of promoting good crystal growth in the step-flow mode and used generally. For the off angle substrate, those having an inclination of about from 0.5 degree to 2 degree are used generally, and the inclination may sometimes be about 10 degree depending on the type of the materials constituting the quantum well structure to be described later.

The substrate (1) may be previously applied with chemical etching or heat treatment, etc. for manufacturing a semiconductor laser by utilizing the crystal growth technique such as MBE or MOCVD. Usually, the thickness of the substrate (1) to be used is about 350 μm, so as to ensure the mechanical strength in the process for manufacturing the device and it is usually polished thinly to about 100 μm in the course of the process for forming the facet of the semiconductor light emitting device.

The buffer layer (2) is preferably disposed so as to moderate the incompleteness of substrate bulk crystals and facilitate the formation of a thin epitaxial film having a crystallographic axis identical therewith. The buffer layer (2) is preferably constituted with a compound identical with the substrate (1) and GaAs is usually used in a case where the substrate (1) comprises GaAs, and InP is used in a case where the substrate (1) comprises InP. However, a super lattice layer is also used generally for the buffer layer (2) and, for example, an AlGaAs/GaAs super lattice structure is sometimes used over the GaAs substrate, not being formed with an identical compound. Further, the composition of the buffer layer (2) can be changed gradually in the layer, On the other hand, in a case of using the dielectric substrate, it is not always formed of the substance identical with that of the substrate and materials different from those of the substrate may be sometimes selected properly in view of the desired oscillation wavelength and the entire device structure.

The first-conduction-type first clad layer (3) can be constituted with various kinds of materials and they are properly selected in accordance with the active layer structure (6) or the substrate (1) selected depending on the oscillation wavelength intended to be attained. For example, in a case of attaining the invention over the GaAs substrate (1), AlGaAs material systems, InGaP material systems, AlGaInP material systems, etc. can be used. For example, in a case of attaining the same on the InP substrate, InGaAsP material systems, etc. can be used.

Particularly, in a case of using the AlGaAs material systems, the Al composition of the first-conduction-type first clad layer (3) is, preferably, less than 0.40, more preferably, 0.3 or less and, further preferably, 0.2 or less in order to decrease the thermal resistance of the entire device and obtain a structure suitable for high power operation. Further, the thickness tₙ₁ (nm) of the first-conduction-type first clad layer (3) is preferably made larger than the oscillation wavelength λ (nm) since it is necessary to decay the light sufficiently in the direction receding from the active layer structure (6).

Further, in a case of using AlGaAs for the first-conduction-type first clad layer (3) and setting the Al composition lower, an effect capable of increasing the activation ratio of the dopant can also be expected. Particularly, for example, in a case where the first conduction type is an n-type and Si is used as the dopant, when it is assumed to conduct crystal growth by an MBE method, it is known that the ionization energy of the Si donor greatly depends on the Al composition as described by N. Chand et al., in Physical Review Br vol. 30 (1984), p. 4481, and this is extremely desirable since a layer of a sufficiently low resistance can be formed even when the doping is set to a relatively low level in AlGaAs at a less Al composition. Accordingly, the doping level in the first-conduction-type first clad layer (3) is, preferably, 1.0×10¹⁷ cm⁻³ to 1.0×10¹⁸ cm⁻³ and, more preferably, 3.0×10¹⁷ cm⁻³ to 7.5×10¹⁷ cm⁻³.

Further, it is not necessary that the doping is conducted uniformly in the first-conduction-type first clad layer (3) but it is preferably set such that the level is higher toward the substrate (1) and lower on the side nearer to the active layer structure (6). This is an effective method of suppressing absorption by free electrons in the portion where the optical density is high.

The first-conduction-type second lad layer (4) can be constituted with various kinds of materials, which are selected properly in accordance with the active layer structure (6) or substrate (1), etc. selected depending on the oscillation wavelength to be attained. For example, in a case where the invention is intended to be attained on a GaAs substrate, AlGaAs material systems, InGaP material systems, AlGaInP material systems, etc. can be used and, in a case where it is intended to be attained, for example, on an InP substrate, InGaAsP material systems, etc. can be used.

Further, in a case of constituting the first-conduction-type second clad layer (4) with AlGaAs material systems, the Al composition is preferably less than 0.5. Further, the Al composition of the first-conduction-type second clad layer (4) is made more than the Al composition of the first-conduction-type first clad layer (3) and the Al composition of the first optical guide layer (5) adjacent therewith, By the use of such a constitution, the second-conduction-type second clad layer (4) becomes a layer with least refractive index and has a function as a barrier against electrons on the side of the conduction band and holes in the valence band. Further, the difference between the Al composition of the first-conduction-type second clad layer (4) and the Al composition of the first-conduction-type first clad layer (3) is preferably larger than 0.08. With this constitution, the first-conduction-type second clad layer (4) can sufficiently suppress the overflow of carriers from the active layer structure (6) to the first-conduction-type first clad layer (3). However, the difference between the Al composition of the two layers is preferably less than 0.4 so as not to excessively inhibit the injection of carriers from the first-conduction-type first clad layer (3) to the active layer structure (6).

The thickness tₙ₂ (nm) of the first-conduction-type second clad layer (4) is, preferably, less than the thickness t_{ng} (nm) of the first optical guide layer (5). Use of such a constitution can avoid extreme increase of the threshold current, lowering of the slope efficiency and increase of the driving current. In the invention an appropriate NFP expanding effect in the vertical direction can be attained since tₙ₂/t_{ng} is made to more than 0.3. Further, the thickness tₙ₂ of the first-conduction-type second clad layer (4) is, preferably, larger than 10 nm and smaller than 100 nm. In a case where the tₙ₂ of the first-conduction-type second clad layer (4) is 10 nm or smaller, the optical effect is sometimes reduced. On the other hand, when it is 100 nm or larger, the optical confinement is sometimes weakened extremely and the LD oscillates no more.

Further, in a case of constituting the first-conduction-type second clad layer (4) with an AlGaAs material system, since the Al composition is relatively higher in the LD structure of the invention, it is preferred that the doping level of the dopant is set higher compared with that for the first-conduction-type first clad layer (3). Particularly, assuming the crystal growth is conducted by the MBE method, for example, in a case where the first conduction type is an n-type and Si is used as the dopant, the doping level is, preferably, from 3.0×10¹⁷ cm⁻³ to 1.0×10¹⁸ cm⁻³ and, more preferably, from 4.0×10¹⁷ cm⁻³ to 7.5×10¹⁷ cm⁻³. The difference of the band gap between the first-conduction-type first clad layer (3) and the first-conduction-type second clad layer (4) is about from 0.05 eV to 0.45 eV and, more preferably, about from 0.1 eV to 0.3 eV.

In the invention it is also preferred that the first-conduction-type second clad layer (4) and the second-conduction-type second clad layer (8) are constituted with different kinds of materials having approximately identical refractive indexes with each other. For suppressing the overflow of carriers, it is preferred that the first-conduction-type second clad layer (4) is constituted with an InGaP material system and the second-conduction-type second clad layer (8) is constituted with an AlGaAs material system. For example, the combination of In_{0.49}Ga_{0.51}P and Al_{0.47}Ga_{0.53}As described above can be exemplified.

In the invention, it is selected such that Vₙ defined as described above satisfies: 0.35<Vₙ<0.75. Further, it is preferred that Rₙ which is a relative thickness tₙ₂/t_{ng} of the second-conduction-type second clad layer (4) to the second guide layer (5) is selected so as to satisfy: 0.3<Rₙ<0.7 and selected so as to satisfy: 0.35<Rₙ<0.55. The upper limit is essential in order that the waveguide structure in the vertical direction prepared in the semiconductor laser does not show anti-waveguide property as a whole, while the lower limit shows the thickness necessary for effectively narrowing the width of the FFP_{V}.

Although not illustrated in FIG. 10, a layer comprising a material such as AlGaAs material systems, InGaP material systems, etc. selected properly with a view point of the lattice matching with the substrate (1) or with a view point of intentionally introducing strains contrarily with the band gap being closer to the first-conduction-type first clad layer (3) on the side of the first-conduction-type first clad layer (3) and being closer to the first-conduction-type second clad layer (4) on the side of the first-conduction-type second clad layer (4) can be inserted between the first-conduction-type first clad layer (3) and the first-conduction-type second clad layer (4). Such a transition layer is extremely preferred since this can decrease electric resistance upon injection of carriers from the side of the first-conduction-type first clad layer (3) through the first-conduction-type second clad layer (4) into the active layer structure (6).

The first optical guide layer (5) over the first-conduction-type second clad layer (4) can be constituted with various kinds of materials which are properly selected in accordance with the active layer structure (6) or the substrate (1) selected in accordance with the oscillation wavelength intended to be attained. For example, in a case of attaining the invention on a GaAs substrate, AlGaAs material systems, InGaP material systems, AlGaInP material systems, etc. can be used and, in a case, for example, of attaining the invention on an InP substrate, InGaAsP material systems, etc. can be used.

In a case of constituting the first optical guide layer (5) with an AlGaAs material system, it is necessary to constitute the first optical guide layer (5) with a material of a less Al composition than that of the first-conduction-type first clad layer (3) in order to attain optical confinement. Specifically, the Al composition of the first optical guide layer (5) is, preferably, less than 0.4, more preferably, less than 0.2 and, further preferably, less than 0.1. A most preferred is a case of using GaAs not containing Al. Particularly, with a viewpoint of the reliability, an optical guide not containing Al is desired.

Further, the thickness t_{ng} (nm) of the first optical guide layer (5) preferably satisfies the following formula in order that the first-conduction-type second clad layer (4) provides the function sufficiently:
0.5×[λ/(4×n_{ng})]nm<t_{ng}<1.5×[λ/(4×n_{ng})]nm
In the formula, n_{ng} is a refractive index of the first optical guide (5). By restricting the thickness t_{ng} of the first optical guide layer (5) to smaller than the upper limit in the formula, it is particularly possible to sufficiently provide the effect of suppressing the overflow of carriers in the first-conduction-type second clad layer (4) and effectively avoid lowering of the kink level, etc. Further, by restricting the thickness t_{ng} of the first optical guide layer (5) to larger than the lower limit in the formula, it is possible to suppress the first-conduction-type second clad layer (4) from exhibiting excessive anti-waveguide property.

Particularly, in a case of constituting the first optical guide layer (5) with an AlGaAs material system, it is not always necessary that the first optical guide layer (5) comprising AlGaAs with a thickness of t_{ng} is a layer having a constant Al composition but the Al composition can also be changed in the first optical guide layer (5). In a case where regions of different Al compositions are present in the first optical guide (5), an average refractive index thereof can be considered as the refractive index of the first optical guide layer (5).

The conduction type of the first optical guide layer (5) may be a p-type, n-type or undoped type and the effect of the invention does not change depending on the type.

The situation described above is identical also for the second optical guide layer (7) situated over the active layer structure (6).

The active layer structure (6) in the invention means a structure containing a quantum well comprising a thin film which becomes thinner as the quantum effect becomes remarkable and includes, for example, a single quantum well (SQW) layer, or a double quantum well (DQW) structure having a barrier layer provided for separation and coupling between two quantum well in which the quantum well layer, the barrier layer and the quantum well layer are stacked or further a multiple quantum well structure having a structure comprising three or more quantum well layer and barrier layers for properly separating the respective quantum well. Strains are sometimes introduced intentionally to the quantum well layers and, for example, compressive stress is generally incorporated in order to lower the threshold current. Further, in a semiconductor laser having a wavelength of about 900 nm to 1350 nm which is applied preferably in the invention, this is preferably attained by including a strained quantum well layer containing In, Gs, and As and not lattice matched to a substrate on a GaAs substrate.

The specific material for the strained quantum well layer can include, for example, InGaAs, GaInNAs, etc. Increase of the optical gain, etc. can be expected by the quantum well layer having strains due to the strain effect thereof. Accordingly, even for appropriately weak optical confinement in the vertical direction between the first clad layer (3, 9, 10) and the active layer structure (6), a sufficient LD characteristic can be attained. Therefore, the strained quantum well layer is desirable in the invention.

While the effect of the invention does not change when the conduction type of the barrier layer (21, 23, 25) is a p-type, n-type or undoped type, it is desirable that the barrier layer (21, 23, 25) has a portion showing the n-conduction type. Under such a situation, since electrons are supplied from the barrier layer (21, 23, 25) to the quantum well layer (22, 24) in the active layer structure (6), the gain characteristics of the LD can be attained desirably for the wider band region effectively. In the device described above, the oscillation wavelength can be fixed effectively by an external cavity such as a grating fiber as will be described later. In this case, the n-type dopant is preferably Si. Further, the n-type dopant such as Si is not doped uniformly in the barrier layer but it is most preferred that doping is not applied near the boundary with respect to other layers such as the strained quantum well layer (22, 24) and doping is selectively applied near the center of the barrier layer (21, 23, 25).

The second-conduction-type second clad layer (3) can be constituted with various kinds of materials which are properly selected in accordance with the active layer structure (6) or substrate (1), etc. selected depending on the oscillation wavelength to be attained. For example, in a case of attaining the invention on a GaAs substrate, AlGaAs material systems, InGaP material systems, AlGaInP material systems, etc. can be used. Further, in a case of attaining the invention, for example, on an InP substrate, InGaAsP material systems, etc. can be used.

In a case of constituting the second-conduction-type second clad layer (8) with an AlGaAs material system, the Al composition is preferably less than 0.5. The Al composition of the second-conduction-type second clad layer (8) has to be larger than the Al composition of the second-conduction-type lower first clad layer (9) and the Al composition in the second optical clad layer (7) adjacent therewith. By the use of such a constitution, the second-conduction-type second clad layer (8) becomes a layer with least refractive index and has a function as a barrier against electrons on the side of the conduction band and holes in the valence band. Further, the difference between the Al composition of the second-conduction-type second clad layer (8) and the Al composition of the second-conduction-type lower first clad layer (9) is preferably larger than 0.08. With this constitution, the second-conduction-type second clad layer (8) can sufficiently suppress the overflow of carriers from the active layer structure (6) to the second-conduction-type lower first clad layer (9). However, the difference of the Al composition is preferably less than 0.4 so as not to excessively inhibit the injection of carriers from the second-conduction-type lower first clad layer (9) to the active layer structure (6).

The thickness tₚ₂ (nm) of the second-conduction-type second clad layer (8) is made smaller than the thickness t_{pg} (nm) for the second optical guide layer (7). Use of such a constitution can avoid extreme increase of the threshold current, lowering of the slope efficiency and increase of the driving current. An appropriate NFP expanding effect in the vertical direction can be obtained by setting tₚ₂/t_{pg} to larger than 0.3. Further, the thickness tₚ₂ of the second-conduction-type second clad layer (8) is, preferably, larger than 10 nm and smaller than 100 nm. In a case where the tₚ₂ of the second-conduction-type second clad layer (8) is 10 nm or smaller, the optical effect is sometimes reduced. On the other hand, when it is 100 nm or larger, the optical confinement is sometimes weakened extremely and the LD oscillates no more.

It is not always necessary that the second-conduction-type second clad layer (B) has the same refractive index, same thickness and same material as those of the first-conduction-type second clad layer (4), but it is desirable that it has an optically equivalent refractive index and an identical thickness with an aim of ensuring the symmetricity of the beam with respect to the vertical direction, However, as described above, it is also preferred that the first-conduction-type second clad layer (4) and the second-conduction-type second clad layer (8) are constituted with different kinds of materials having approximately identical refractive indexes with each other.

Particularly, assuming the crystal growth is conducted by an MBE method, for example, in a case where the second conduction type is an p-type and Be is used as the dopant, the doping level is, preferably, from 3.0×10¹⁷ cm⁻³ to 1.0×10¹⁸ cm⁻³ and, more preferably, from 4.0×10¹⁷ cm⁻³ to 7.5×10¹⁷ cm⁻³.

In the invention, it is selected such that Vₚ defined as described above satisfies: 0.35<Vₚ<0.75. Further, it is preferred that Rₚ which is a relative thickness tₚ₂/t_{pg} of the second-conduction-type second clad layer (8) to the second guide layer (7) is selected so as to satisfy: 0.3<Rₚ<0.7 and selected so as to satisfy: 0.35<Rₚ<0.55. The upper limit is essential in order that the waveguide structure in the vertical direction prepared in the semiconductor laser does not show anti-waveguide property as a whole, while the lower limit shows the thickness necessary for effectively narrowing the width of the FFP_{V}.

Although not illustrated in FIG. 10, a layer comprising a material such as AlGaAs material systems, InGaP material systems, etc. in which the material is selected properly with a view point of the lattice-matching with the substrate or with a view point of intentionally introducing strains contrarily with the band gap being closer to the second-conduction-type second clad layer (8) on the side of the second-conduction-type second clad layer (8) and being closer to the second-conduction-type lower first clad layer (9) on the side of the second-conduction-type lower first clad layer (9) can be inserted between the second-conduction-type second clad layer (8) and the second-conduction-type lower first clad layer (9). Such a transition layer is extremely preferred since this can decrease electric resistance upon injection of carriers from the side of the second-conduction-type first clad layer (9, 10) through the second-conduction-type second clad layer (8) into the active layer structure (6).

The second-conduction-type first clad layer consists of two layers of a second-conduction-type lower first clad layer (9) and a second-conduction-type upper first clad layer (10) in the embodiment of FIG. 10. In this case, the two layers may have an etching stop layer therebetween in order to facilitate the fabrication of the device.

The material for the second-conduction-type first clad layer (9, 10) can be selected in the same manner as the second-conduction-type second clad layer (8) described above. Particularly, in a case of using the AlGaAs material system as the material for the second-conduction-type first clad layer (9, 10), in order to lower thermal resistance of the entire device and provide a structure suitable for high power operation, the Al composition in the second-conduction-type first clad layer (9, 10) is, preferably, less than 0.40, more preferably, 0.3 or less and, further preferably, 0.2 or less. Further, the entire thickness of the second-conduction-type lower first clad layer (9) and the second-conduction-type upper first clad layer (10) is preferably made larger than the oscillation wavelength k since it is necessary to sufficiently decay the light in the direction receding from the active layer structure (6).

The thickness of the second-conduction-type first clad layer (9) is preferably about from 10 nm to 200 nm so that the current injection path to the active layer structure (6) is not widened extremely due to the horizontal diffusion of the current. More preferably, it is about from 20 nm to 70 nm.

Further, the doping level for the second-conduction-type lower first clad layer (9) and second-conduction-type upper first clad layer (10) is, preferably, from 1.0×10¹⁷ cm⁻³ to 1.0×10¹⁸ cm⁻³ and, more preferably, from 3.0×10¹⁷ cm⁻³ to 7.5×10¹⁷ cm⁻³.

Further, it is not necessary that doping is conducted uniformly in the second-conduction-type lower first clad layer (9) or the second-conduction-type upper first clad layer (10) and it is preferably set higher as receding from the active layer structure (6) and lower as approaching the active layer structure (6). This is an effective method for suppressing the absorption by free electrons in a portion where the optical density is high.

The second-conduction-type upper first clad layer (10) provides two functions of the current confinement and the optical confinement in the horizontal direction, together with the current block (11) formed on the sides thereof. This is a preferred constitution when the invention is applied to an LD that operates in a single transverse-mode. For this purpose, the conduction type of the current block layer (11) is preferably a first conduction type or an undoped type with a view point of the current confinement in the horizontal direction. Further, with the view point of the optical confinement in the horizontal direction and, particularly, for satisfying the characteristics as the waveguide based on the index waveguide, the current block layer (11) is formed of a material having a refractive index smaller than that of the second-conduction-type first clad layer (9, 10). Further, the optical confinement in the horizontal direction can also be constituted as a so-called loss guide type. In this case, optical confinement in the horizontal direction can be attained by absorpting the oscillation wavelength by the effective band gap of the material constituting the current block layer (11).

Further, in the invention, the material constituting the current block layer can be selected properly depending on the substrate (1), the active layer structure (6) or depending on the waveguide structure in the horizontal direction. For example, in a case where the current block layer (10) is also formed of an AlGaAB material system together with the second-conduction-type first clad layer (9, 10) and they are defined as AlₓₚGa₁₋ₓₚAs and Al_{z}Ga_{1-z}As, respectively, a real-refractive-index-guided structure can be realized when the Al composition is defined as: z>xp. In a case of manufacturing a semiconductor laser which is a real refractive index waveguide type and operates in a single transverse-mode, the effective refractive index difference in the horizontal direction defined mainly by the difference of refractive index between the current block layer (11) and the second-conduction-type upper first clad type (10) is preferably at the order of 10⁻³. Further, the width W in the horizontal direction for a portion where the second-conduction-type upper first clad layer (10) is in contact with the second-conduction-type lower first clad layer (9), which is the width for the current injection channel and corresponds to the width of the waveguide is preferably uniform within a range of an error in the direction of the cavity vertical to the drawing and the width is preferably 6 μm or less and, more preferably, 3 μm or less with a view point of operating the LD in the single transverse-mode. However, for making the high power operation and the single transverse-mode operation compatible, the waveguide is not necessarily uniform in the direction of the cavity but it is preferred that the width for the waveguide is relatively increased on the side of the front facet as the main light emitting direction of the semiconductor laser so as to be suitable for the high power operation, whereas the width for the waveguide is narrowed on the side of the back facet to enable the single transverse-mode operation. Further, in this case, it is desirable to satisfy the following formula assuming the width for the current injection channel near one of light emission points as W_{wxp} and the width for the narrowest current injection channel in the device as W_{std}:
1.5<Wₑₓₚ/W_{std}<5.0
It is further preferred to satisfy the following formula:
2.5<Wₑₓₚ/W_{std}<3.5

The semiconductor light emitting device of the invention has a feature of satisfying the condition shown by (formulae 2) described above. Out of the conditions described above, it is no more possible to narrow the full width of the half maximum of the FFP_{V} without worsening various characteristics of the semiconductor laser. For example, in a case where Vₙ and Vₚ are 0.35 or less and Rₙ and Rₚ are 0.7 or more, since the waveguide function in the vertical direction of the entire semiconductor laser is weakened excessively, the threshold current current increases, the slope efficiency is lowered, etc. in the device. Further, in an extreme case, the waveguide function itself is sometimes lost and the device oscillates no more. On the other hand, in a case where Vₙ and Vₚ are 0.75 or more and Rₙ and Rₚ are 0.35 or less, the waveguide function itself in the vertical direction of the device becomes excessive, and the FFP_{V} is extremely widened and no good coupling can be attained to an external optical system. Further, under the situations described above, since the optical density on the facet is also increased excessively, it results in a disadvantages, for example, that the device is not suitable also for the high power operation, which is not desired.

The cap layer (12) is used as a protective layer for the current block layer (11) in the first growth, as well as used for facilitating the growth of the second-conduction-type upper first clad layer (10) and it is partially or entirely removed before obtaining a device structure.

A contact layer (13) is preferably disposed over the second-conduction-type upper first clad layer (10) with an aim of lowering the contact resistivity to the electrode (14), etc. The contact layer (13) is usually constituted with a GaAs material system. In the layer, the carrier concentration is usually made higher than in other layers so as to lower the contact resistivity to the electrode (14). Further, the conduction type is a second conduction type.

The thickness for each of the layers constituting the semiconductor laser is properly selected within such a range as providing the function of the respective layers effectively.

Further, in the semiconductor light emitting device according to the invention, the first conduction type is preferably an n-type and the second conduction type is preferably a p-type. This is because an n-type substrate often has a good quality.

The semiconductor laser shown in FIG. 3 is fabricated by further forming electrodes (14) and (15). The electrode (14) on the side of the epitaxial layer is formed, for example, in a case where the second conduction type is the p-type, evaporated Ti/Pt/Au are successively formed on the surface of the contact layer (12) and then applying an alloying treatment. On the other hand, the electrode (15) on the side of the substrate is formed on the surface of the substrate (1) and, in a case where the first conduction type is the n-type, it is formed, for example, evaporated AuGe/Ni/Au are successively formed to the surface of the substrate (1) and then applying an alloying treatment.

A facet as a light emitting surface is formed to the fabricated semiconductor wafer. The facet is a mirror that constitutes a cavity. Preferably, the facet is formed by cleaving. Cleaving is a generally used method and the facet formed by cleaving is different depending on the orientation of the substrate to be used. For example, in a case of forming a device such as an edge-emission-type laser by using a substrate having a surface crystallographically equivalent with the nominally (100) plane utilized suitably, a (110) plane or a plane crystallographically equivalent therewith constitutes a surface that forms a cavity. On the other hand, in a case of using an off angle substrate, the facet does not sometimes form 90 degree with respect to the direction of the cavity depending on the relation between the inclined direction and the direction of the cavity. For example, in a case of using a substrate (1) which is inclined by an angle of 2 degrees from the (100) substrate to the (1-10) direction, the facet is also inclined by 2 degrees.

The cavity length of the device is also decided by cleaving. Generally, longer cavity length is suitable for the high power operation, and it is, preferably, from 600 μm or more and, more preferably, from 900 μm to 3000 μm in the semiconductor laser to which the invention is applied. The upper limit is defined for the cavity length as described above, because a semiconductor laser having an extremely long cavity length may rather result in deterioration of characteristics such as increase in the threshold current and lowering of the efficiency.

In the invention, coating layer (16, 17) each comprising a dielectric material or a combination of a dielectric material and a semiconductor are preferably formed on the exposed facet of the semiconductor. The coating layer (16, 17) are formed mainly for two purpose of increasing the efficiency for taking out a light from the semiconductor laser and for protecting the facet. Further, in order to take out the light output power from the device efficiently from the facet on one side, it is preferred to conduct asymmetric coating of applying a coating layer (16) with a low reflectivity (for example, 10% or less of reflectivity) relative to the oscillation wavelength to the front facet as the main light emission direction, while applying a coating layer (17) with a high reflectivity (for example, 80% or more) relative to the oscillation wavelength to the other back facet. This is extremely important not only for enhancing the power of the device higher but also for positively taking a light returned from an external cavity such as a grating fiber used for the stabilization of wavelength into the laser thereby promoting the stabilization of the wavelength. Further, for the purposes described above, the reflectivity at the front facet is, preferably, 5% or less and, more preferably, 2.5% or less.

For the coating layer (16, 17), various materials can be used. For example, it is preferred to use one member selected from the group consisting of AlOₓ, TiOₓ, SiOₓ, SiN, Si and ZnS or a combination of two or more of them. AlOₓ, TiOₓ, SiOₓ, etc. are used for the coating layer at low reflectivity, while AlOₓ/Si multi-layered films, TiOₓ/SiOₓ multi-layered films, etc. are used for the coating layer at high reflectivity. An aimed reflectivity can be attained by controlling the respective film thickness. However, the film thickness of AlOₓ, TiOₓ, SiOₓ, etc. as the coating layer at low reflectivity is generally controlled so as to be near λ/4n, n being the real number portion of the refractive index at the wavelength λ. Further, also in a case of the highly reflective multi-layered film, each of the materials constituting the film is generally controlled so as to be near λ/4n.

By cleaving the laser bar after completion of the coating again, respective devices can be separated to form semiconductor lasers.

A semiconductor light emitting device module can be formed by disposing an optical fiber to the light emission end of the semiconductor light emitting device of the invention including the semiconductor laser fabricated as described above. It is preferred that the top end of the optical fiber is fabricated to show a light focusing effect and to be optically coupled directly to the front facet of the semiconductor light emitting device.

For stabilizing the wavelength of the semiconductor light emitting device according to the invention including the semiconductor laser, it is preferred to provide a mirror having a wavelength selectivity at the outside and couple the external cavity and the semiconductor light emitting device of the invention. It is particularly preferred to form the external cavity by using a fiber grating. In this case, it is also possible to form a semiconductor light emitting device module incorporating a fiber grating, a cooler for temperature stabilization, etc. in addition to the semiconductor laser. For the fiber grating, the center wavelength, the reflection or transmission region, the reflectivity of light of the fiber grating to the side of the semiconductor light emitting device, etc. can be selected optionally in accordance with the purpose thereof. Particularly, the reflectivity of the light of the fiber grating to the side of the semiconductor light emitting device is, preferably, from 2 to 15%, more preferably, from 5 to 10% at the emission wavelength of the semiconductor light emitting device, and the reflection region is, preferably, from 0.1 to 5.0 nm and, more preferably, from 0.5 to 1.5 nm relative to the center wavelength.

The present invention is to be described further specifically. Material, concentration, thickness, operation procedure, etc. shown in following examples can be changed appropriately so long as they do not depart from the gist of the invention. Accordingly, the scope of the invention is not restricted to specific examples shown in the following examples.

### EXAMPLE 1

A semiconductor laser shown in FIG. 2 as a cross sectional view in the light emitting direction was fabricated by the following procedures.

At first, on the (100) plane of an n-type GaAs substrate (1) at a carrier concentration of 1.0×10¹⁸ cm⁻³, were stacked successively by an MBE method, an Si doped n-type GaAs layer of 0.5 μm thickness at a carrier concentration of 1.0×10¹⁸ cm⁻³ as a buffer layer (2); an Si-doped n-type Al_{0.19}Ga_{0.92}As layer of 2.3 μm thickness at a carrier concentration of 7.5×10¹⁷ cm⁻³ for 1.3 μm from the side of the substrate and 3.0×10¹⁷ cm⁻³ for 1 μm thereover as a first conductive type first clad layer (3); an Si doped n-type Al_{0.45}Ga_{0.58}As layer of 35 nm thickness at a carrier concentration of 8.0×10¹⁷ cm⁻³ as a first-conduction-type second clad layer (4); an GaAs layer of 75 nm thickness at a doping level of Si of 2.0×10¹⁷ cm⁻³ for 35 nm from the side of the substrate and undoped for 40 nm thereover as a first optical guide layer (5) (refractive index of 3.525245 at an oscillation wavelength of 980 nm to be described later); an active layer structure comprising five layers of an Si-doped n-type GaAs barrier layer of 5 nm thickness at a carrier concentration of 7.5×10¹⁷ cm⁻³ (undoped for 1 nm on the side of the quantum well layer), an undoped In_{0.16}Ga_{0.84}As strained quantum well layer of 6 nm thickness, an Si-doped n-type GaAs barrier layer of 7 nm thickness at a carrier concentration of 7.5×10¹⁷ cm⁻³ (undoped for 1 nm on the side of both quantum well layers), an undoped In_{0.16}Ga_{0.84}As strained quantum well layer of 6 nm thickness and an Si-doped n-type GaAs barrier layer at a carrier concentration of 7.5×10¹⁷ cm⁻³ (undoped for 1 nm on the side of the quantum well layer) as an active layer structure (6); a GaAs layer of 75 nm thickness undoped for 40 nm from the side of the substrate and at a Be doping level of 3.0×10¹⁷ cm⁻³ for 35 nm thereover (refractive index of 3.525245 at an oscillation wavelength of 980 nm to be described later) as a second optical guide layer (7); Be-doped p-type Al_{0.45}Ga_{0.55}As layer of 35 nm thickness at a carrier concentration of 7.5×10¹⁷ cm⁻³ as a second-conduction-type second clad layer (8); a Be doped p-type Al_{0.19}Ga_{0.81}As layer of 25 nm thickness at a carrier concentration of 5.0×10¹⁷ cm⁻³ as a second-conduction-type lower first clad layer (9); an Si doped n-type Al_{0.23}Ga_{0.78}As layer of 0.3 μm thickness at a carrier concentration of 5.0×10¹⁷ cm⁻³ as a current block layer (11); and an Si-doped n-type GaAs layer of 10 nm thickness at a carrier concentration of 7.5×10¹⁷ cm⁻³ as a cap layer (12).

A mask of silicon nitride was provided to the uppermost layer excluding a current injection region portion. In this case, the width for the opening of the silicone nitride mask was 1.5 μm. Using the same as a mask, etching was conducted at 20° C. for 150 sec to remove the cap layer and the current block layer in the current injection region portion. For the etchant, a liquid mixture formed by mixing phosphoric acid (65% by weight), hydrogen peroxide (30% by weight of aqueous solution) and water at a volume ratio of 1:1:30 was used.

Then, a Zn-doped p-type Al_{0.19}Ga_{0.81}As layer of 2.3 μm thickness at a carrier concentration of 4.0×10¹⁷ cm⁻³ for one μm from the side of the substrate and 7.5×10¹⁷ cm⁻³ for 1.3 μm thereover as the second-conduction-type upper first clad layer (10); and a Zn-doped GaAs layer of 3.0 μm thickness at a carrier concentration of 1.0×10¹⁸ cm⁻³ for 2.7 μm from the side of the substrate and at 6.0×10¹⁸ cm⁻³ for 0.3 μm thereover as the contact layer (13) were grown again by an MOCVD method.

Further, Ti/Pt/Au were evaporated by 70 nm/70 nm/80 nm as the epitaxial layer side (p-side) electrode (14) further, AuGeNi/Au were evaporated by 50 nm/80 nm as the substrate side (n-side) electrode (15) respectively after polishing the substrate and then alloying was conducted at 400° C. for 5 min to complete a wafer for a semiconductor laser.

The width W of the current injection region of the completed semiconductor laser was 2.3 μm.

Successively, it was cleaved in atmospheric air into the shape of a laser bar at a cavity length of 1600 μm to expose the (110) plane and an AlOₓ film was formed by 165 nm such that the reflectivity on the front facet at an oscillation wavelength of 980 nm was 2.5%, to form a coating layer 16 (FIG. 3). Further, for processing the back facet, a coating layer (17) comprising four layers of AlOₓ layer of 170 nm thickness/amorphous Si layer of 60 nm thickness/AlOₓ layer of 170 nm thickness/amorphous Si layer of 60 nm thickness was formed, to prepare a back facet at 92% reflectivity.

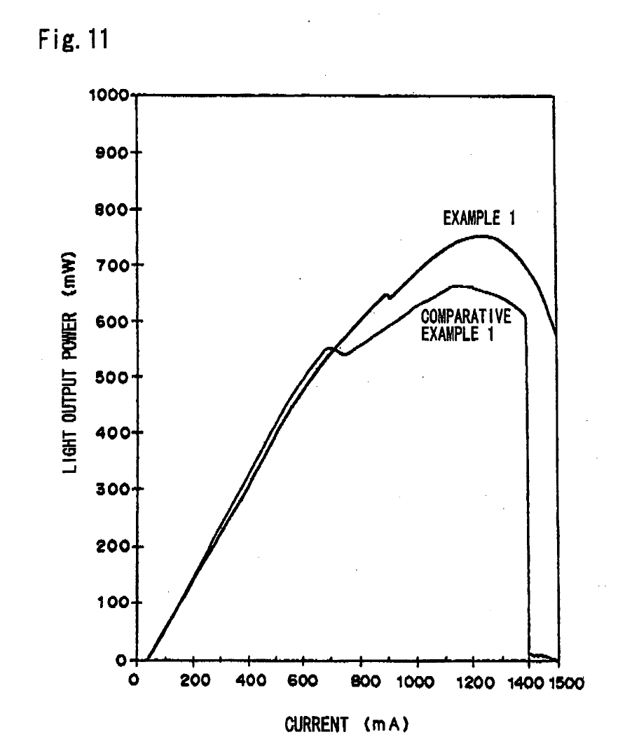

FIG. 11 shows current-light output power characteristics of the fabricated device at 25° C.

The threshold current was 32.6 mA, the slop efficiency was 0.87W/A and the kink level was 652 mW. Further, the maximum light output power upon injection of current up to 1.5 A was 755 mW and destruction of the device was not observed till current injection up to 1.5 A.

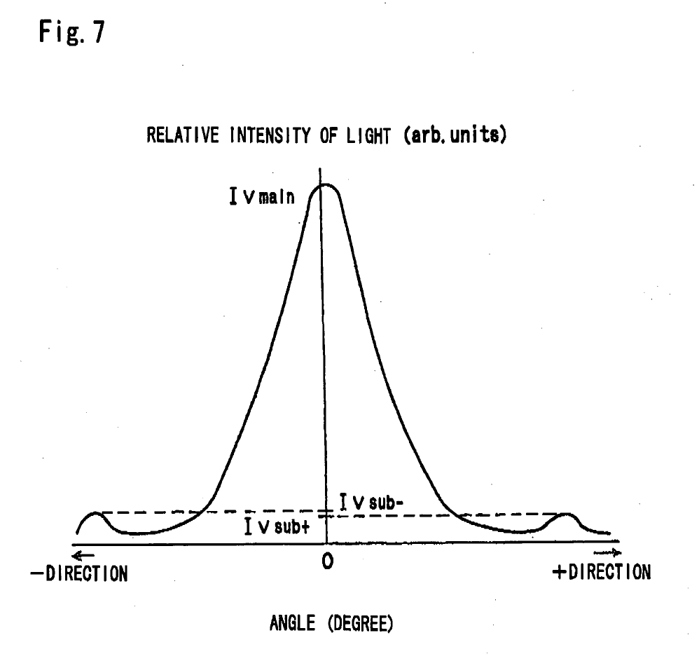

Further, the full width of the half maximum of the FFP in the vertical direction (FFP_{V}) was 22.1 degrees, and the full width of the half maximum of the FFP in the horizontal direction (FFP_{H}) was 8.8 degree at 450 mW light output power. In this case, as typically shown in FIG. 7, three peaks were confirmed for the FFP_{V} in the order of a sub peak, main peak and a sub peak in which the respective peak positions were −55.2 degrees, 0.7 degree, and 55.1 degrees in the order of the angle. Further, the relative intensity assuming the intensity of the main peak as 1 was 0.14, 1, and 0.04 in the order of the angle. On the other hand, only one peak was confirmed for the FFP_{H} for the portion of the main peak of the FFP_{V} and the peak position was at 0.6 degree. The oscillation wavelength of the device was 984 nm.

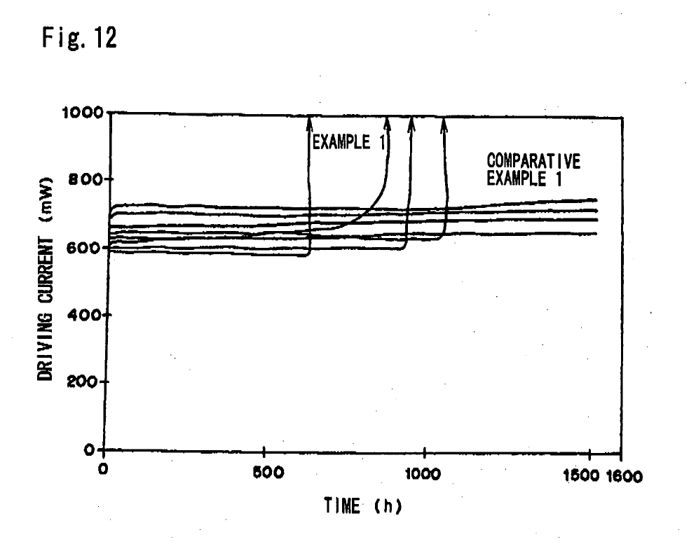

Further, FIG. 12 shows the change with time of a driving current when the device was driven continuously at a constant light output power (500 mW) at 50° C. As shown in the chart, stable driving for 1500 hors was confirmed.

### EXAMPLE 2

Using the device fabricated in Example 1, an optical fiber with a grating, having a fiber lens of a wedged top end, was mounted on the side of the front facet of the device to fabricate a semiconductor laser module having a butterfly type package. The grating fiber has a reflection center of 982 nm and a reflectivity of 3%. At 25° C., the threshold current was 27.6 mA and the slope efficiency was 0.71 mW/mA for the light emitted from the fiber end. The coupling efficiency was good as about 81.6%.

### EXAMPLE 3

A semiconductor laser was fabricated by following procedures.

At first, on the (100) plane of an n-type GaAs substrate at a carrier concentration of 1.0×10¹⁸ cm⁻³, were stacked successively by an MBE method, an Si doped n-type GaAs layer of 1 μm thickness at a carrier concentration of 1.0×10¹⁸ cm⁻³ as a buffer layer; an Si-doped n-type Al_{0.175}Ga_{0.825}As layer of 2.5 μm thickness at a carrier concentration of 6.0×10¹⁷ cm⁻³ for 1.5 μm from the side of the substrate and 4.0×10¹⁷ cm⁻³ for 1 μm thereover as a first conductive type first clad layer; then, an Si-doped n-type AlₜGa₁₋ₜAs layer of 35 nm thickness at a carrier concentration of 5.0×10¹⁷ cm⁻³ in which the Al composition is; t=0.175 on the side of the first-conduction-type first clad layer and the Al composition increases therefrom linearly in the layer up to: t=0.35 on the side of the first-conduction-type second clad layer as the first conduction type transition layer; an Si doped n-type Al_{0.35}Ga_{0.65}As layer of 35 nm thickness at a carrier concentration of 3.0×10¹⁷ cm⁻³ as a first-conduction-type second clad layer; an Si-doped n-type GaAs layer of 75 nm thickness at a carrier concentration of 2.0×10¹⁷ cm⁻³ as the first optical guide layer (refractive index of 3.525245 at an oscillation wavelength of 980 nm to be described later); an active layer structure comprising five layers of an Si-doped n-type GaAs barrier layer of 5 nm thickness at a carrier concentration of 7.5×10¹⁷ cm⁻³ (undoped for 1 nm on the side of the quantum well layer), undoped In_{0.16}Ga_{0.84}As strained quantum well layer of 6 nm thickness, an Si-doped n-type GaAs barrier layer of 7 nm thickness at a carrier concentration of 7.5×10¹⁷ cm⁻³ (undoped for 1 nm on the side of both quantum well layers), an undoped In_{0.16}Ga_{0.84}As strained quantum well layer of 6 nm thickness and an Si-doped n-type GaAs barrier layer of 5 nm thickness at a carrier concentration of 7.5×10¹⁷ cm⁻³ (undoped for 1 nm on the side of the quantum well layer) as an active layer structure; a Be-doped p-type GaAs layer of 75 nm thickness at a carrier concentration of 3.0×10¹⁷ cm⁻³ as a second optical guide layer (refractive index of 3.525245 at an oscillation wavelength of 980 nm to be described later); a Be-doped p-type Al_{0.35}Ga_{0.65}As layer of 35 nm thickness at a carrier concentration of 4.0×10¹⁷ cm⁻³ as a second-conduction-type second clad layer, then, a Be doped p-type AlₜGa₁₋ₜAs layer of 35 nm thickness at a carrier concentration of 5.0×10¹⁷ cm⁻³, in which the Al composition is; t=0.35 on the side of the second-conduction-type second clad layer and the Al composition decreases linearly therefrom in the layer to: t=0.175 on the side of the second-conduction-type second clad layer as a second-conduction-type transition layer; a Be doped p-type Al_{0.17}Ga_{0.825}As layer of 30 nm thickness at a carrier concentration of 5.0×10¹⁷ cm⁻³ as a second-conduction-type lower first clad layer, an Si doped n-type Al_{0.225}Ga_{0.775}As layer of 0.5 μm thickness at a carrier concentration of 5.0×10¹⁷ cm⁻³ as a current block layer; and an Si-doped n-type GaAs layer of 10 nm thickness at a carrier concentration of 7.5×10¹⁷ cm⁻³ as a cap layer.

A mask of silicon nitride was provided to the uppermost layer excluding a current injection region portion. In this case, the width for the opening of the silicone nitride mask was changed in the semiconductor laser of a cavity length of 1600 μm in the direction of the cavity as described below. The width for the opening was 1.7 μm for 1200 μm from the portion as the back facet to the front facet of the device, and 5.1 μm for 250 μm from the portion as the front facet to the side of the back facet of the device. Further, the width was changed linearly between 1.7 μm and 5.1 μm over the length of 150 μm for the portion connecting the different regions. Using the same as a mask, etching was conducted at 20° C. for 185 sec to remove the cap layer and the current block layer in the current injection region portion. For the etchant, a liquid mixture formed by mixing phosphoric acid (85% by weight), hydrogen peroxide (30% by weight of aqueous solution) and water at a volume ratio of 1:1:30 was used.

Then, a Zn-doped p-type Al_{0.175}Ga_{0.825}As layer of 2.47 μm thickness at a carrier concentration of 4.0×10¹⁷ cm⁻³ for one μm from the side of the substrate and 6.0×10¹⁷ cm⁻³ for 1.47 μm thereover as the second-conduction-type upper first clad layer; and a Zn-doped GaAs layer of 3.5 μm thickness at a carrier concentration of 1.0×10¹⁸ cm⁻³ for 3.0 μm from the side of the substrate and at 5.0×10¹⁸ cm⁻³ for 0.5 μm thereover as the contact layer were grown again by an MOCVD method.

Ti/Pt/Au were evaporated by 70 nm/70 nm/80 nm respectively as the epitaxial layer side (p-side) electrode, further, AuGeNi/Au were evaporated by 150 nm/80 nm respectively as the substrate side (n-side) electrode after polishing the substrate and then alloying was conducted at 410° C. for 5 min to complete a wafer for a semiconductor laser.

The width Wb of the current injection region of the completed semiconductor laser was 2.3 μm on the front facet and 5.6 μm on the back facet of the device.

Successively, it was cleaved in atmospheric air into the shape of a laser bar at a cavity length of 1600 μm to expose the (110) plane and an AlOₓ film was formed by 165 nm such that the reflectivity on the front facet at an oscillation wavelength of 980 nm was 2.5%, to form a coating layer. Further, for processing the back facet, a coating layer comprising four layers of AlOₓ layer of 170 nm thickness/amorphous Si layer of 60 nm thickness/AlOₓ layer of 170 nm thickness/amorphous Si layer of 60 nm thickness was formed, to prepare a back facet at 92% reflectivity.

After the end of the coating, the semiconductor laser bar was put to secondary cleaving and a semiconductor laser was mounted on a heat dissipation plate to complete a semiconductor laser.

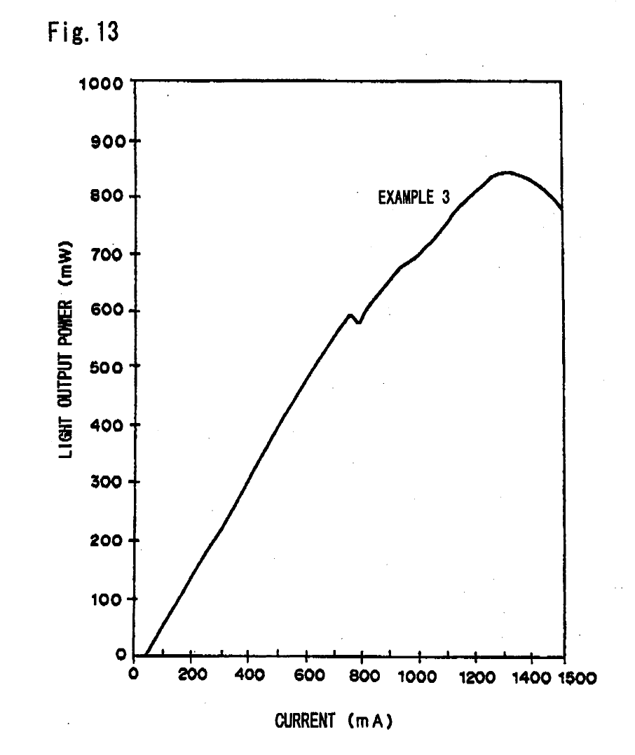

FIG. 13 shows current-light output power characteristics of the fabricated device at 25° C.

The threshold current was 34.1 mA, the slop efficiency was 0.88 W/A, and the kink level was 608 mW. Further, the maximum light output power upon injection of current up to 1.5 A was 830 mW and destruction of the device was not observed till current injection up to 1.5 A.

Further, the full width of the half maximum of the FFP in the vertical direction (FFP_{V}) was 21.4 degrees, and the full width of the half maximum of the FFP in the horizontal direction (FFP_{H}) was 7.2 degrees at 450 mW light output power. In this case, as typically shown in FIG. 7, three peaks were confirmed for the FFPᵥ in the order of a sub peak, a main peak and a sub peak in which the respective peak positions were −54.0 degrees, 0.9 degree and 55.9 degrees in the order of the angle. Further, the relative intensity assuming the intensity of the main peak as 1 was 0.10, 1, and 0.03 in the order of the angle. On the other hand, only one peak was confirmed for the FFP_{H} for the portion of the main peak of the FFP_{V} and the peak position was at −0.2 degree. The oscillation wavelength of the device was 978 nm.

### COMPARATIVE EXAMPLE 1

A semiconductor laser was fabricated in the same manner as in Example 1 except for not stacking a first-conduction-type second clad layer and a second-conduction-type second clad layer.

As shown in FIG. 11, the threshold current was 29.1 mA, and the slope efficiency was 0.9 W/A and they were better than those in Example 1 but the kink level was as low as 540 mW. Further, also the maximum light output power upon injection of current up to 1.5 A was 671.2 mW which was lower compared with Example 1. When current was injected at 1.5A, the device was destroyed at 1.4 A.

The full width of the half maximum of the FFP in the vertical direction (FFP_{V}) at the light output power of 450 mW was 29.7 degrees which was wider than that in Example 1 and it was suspicious that the optical density was high in the active layer. Further, the full width of the half maximum of the FFP in the horizontal direction (FFP_{H}) was about identical as being 9.0 degree. Further, FIG. 12 shows the change with time of the driving current when the device was driven continuously at 50° C. in a constant light output power (500 mW). As shown in the chart, all devices were failed up to 1500 hours and they were not suitable for high power operation.

### COMPARATIVE EXAMPLE 2

A semiconductor laser module was fabricated quite in the same constitutions as in Example 2 except for using the device fabricated in Comparative Example 1. The threshold current was 26.1 mA and the slop efficiency was 9.64 mW/mA to a light emitted from the fiber end at 25° C. The coupling efficiency was about 71.1% which was inferior to Example 2.

### COMPARATIVE EXAMPLE 3

A semiconductor laser was fabricated in the same manner as in Example 1 except for changing the thickness of the first optical guide layer and the second optical guide layer to 45 nm and the undoped region therein to 10 nm, and changing the thickness both for the first-conduction-type second clad layer and the second-conduction-type second clad layer to 50 nm and setting tₛₙ/t_{gn}=tₛₚ/t_{gp} to about 1.1.

The threshold current was 39.7 mA, the slope efficiency was 0.69 W/A, and the kink level was 422 mW which were inferior to Example 1. Further, also the maximum light output power upon injection of the current up to 1.5 A was 529 mW which was lower compared with the Example 1. When current was injected up to 1.5 A, the device was destroyed at 1.45 A.

Further, since the kink level was low, the FFP was measured at 400 mW. In this case, the full width of the half maximum of the FFP in the vertical direction upon optical output was 16.5 degrees and it was suspicious that optical confinement near the active layer was not sufficient. The full width of the half maximum of the FFP in the horizontal direction was 8.5 degrees. Further, the oscillation wavelength of the device was 985.5 nm.

### EXAMPLE 4

A semiconductor laser shown in FIG. 8 as a cross sectional view from the light emitting direction was fabricated by the following procedures.

At first, on the (100) plane of an n-type GaAs substrate (1) at a carrier concentration of 1.0×10¹⁸ cm⁻³, were stacked successively by an MBE method, an Si doped n-type GaAs layer of 0.5 μm thickness at a carrier concentration of 1.0×10¹⁸ cm⁻³ as a buffer layer (2); an Si-doped n-type Al_{0.19}Ga_{0.81}As layer of 2.3 μm thickness at a carrier concentration of 7.5×10¹⁷ cm⁻³ for 1.3 μm from the side of the substrate and 3.0×10¹⁷ cm⁻³ for 1 μm thereover as a first conductive type first clad layer (3); an Si doped n-type In_{0.49}Ga_{0.51}P layer of 35 nm thickness at a carrier concentration of 8.0×10¹⁷ cm⁻³ as a first-conduction-type second clad layer (4); an GaAs layer of 80 nm thickness at a doping level of Si of 2.0×10¹⁷ cm⁻³ for 35 nm from the side of the substrate and undoped for 45 nm thereover as a first optical guide layer (5); an active layer structure comprising five layers of an Si-doped n-type GaAs barrier layer of 5 nm thickness at a carrier concentration of 7.5×10¹⁷ cm⁻³ (undoped for 1 nm on the side of the quantum well layer), an undoped In_{0.16}Ga_{0.84}As strained quantum well layer of 6 nm thickness, an Si-doped n-type GaAs barrier layer of 7 nm thickness at a carrier concentration of 7.5×10¹⁷ cm⁻³ (undoped for 1 nm on the side of both quantum well layers), an undoped In_{0.16}Ga_{0.84}As strained quantum well layer of 6 nm thickness, and an Si-doped n-type GaAs barrier layer of 5 nm thickness at a carrier concentration of 7.5×10¹⁷ cm⁻³ (undoped for 1 nm on the side of the quantum well layer) as an active layer structure (6); a GaAs layer of 80 nm thickness undoped for 45 nm from the side of the substrate and at a Be doping level of 3.0×10¹⁷ cm⁻³ for 35 nm thereover as a second optical guide layer (7); a Be-doped p-type In_{0.49}Ga_{0.51}P layer of 35 nm thickness at a carrier concentration of 7.5×10¹⁷ cm⁻³ as a second-conduction-type second clad layer (8), a Be-doped p-type Al_{0.19}Ga_{0.81}As layer of 25 nm thickness at a carrier concentration of 5.0×10¹⁷ cm⁻³ as a second-conduction-type lower first clad layer (9), an Si doped n-type Al_{0.23}Ga_{0.78}As layer of 0.3 μm thickness at a carrier concentration of 5.0×10¹⁷ cm⁻³ as a current block layer (11); and an Si-doped n-type GaAs layer of 10 nm thickness at a carrier concentration of 7.5×10¹⁷ cm⁻³ as a cap layer (12).

A mask of silicon nitride was provided to the uppermost layer excluding a current injection region portion. In this case, the width for the opening of the silicone nitride mask was 1.5 μm. Using the same as a mask, etching was conducted at 20° C. for 105 sec to remove the cap layer and the current block layer in the current injection region portion. For the etchant, a liquid mixture formed by mixing phosphoric acid (85% by weight), hydrogen peroxide (30% by weight of aqueous solution) and water at a volume ratio of 1:1:30 was used.

Then, a Zn-doped p-type Al_{0.19}Ga_{0.81}As layer of 2.3 μm thickness at a carrier concentration of 4.0×10¹⁷ cm⁻³ for one μm from the side of the substrate and 7.5×10¹⁷ cm⁻³ for 1.3 μm thereover as the second-conduction-type upper first clad layer (10); and a Zn-doped GaAs layer of 3.0 μm thickness at a carrier concentration of 1.0×10¹⁸ cm⁻³ for 2.7 μm from the side of the substrate and at 6.0×10¹⁸ cm⁻³ for 0.3 μm thereover as the contact layer (13) were grown again by an MOCVD method.

Further, Ti/Pt/Au were evaporated by 70 nm/70 nm/80 nm respectively as the epitaxial layer side (p-side) electrode (14), further, AuGeNi/Au were evaporated by 150 nm/80 nm respectively as the substrate side (n-side) electrode (15) respectively after polishing the substrate and then alloying was conducted at 400° C. for 5 min to complete a wafer for a semiconductor laser.

The width W of the current injection region of the completed semiconductor laser was 2.2 μm.

Successively, it was cleaved in atmospheric air into the shape of a laser bar at a cavity length of 1600 μm to expose the (110) plane and an AlOₓ film was formed by 165 nm such that the reflectivity on the front facet at an oscillation wavelength of 980 nm was 2.5%, to form a coating layer 16 (FIG. 3). Further, for processing the back facet, a coating layer (17) comprising four layers of AlOₓ layer of 170 nm thickness/amorphous Si layer of 60 nm thickness/AlOₓ layer of 170 nm thickness/amorphous Si layer of 60 nm thickness was formed, to prepare a back facet at 92% reflectivity.

In the current-light output power characteristics at 25° C. of the fabricated device, the threshold current was 29.9 mA, the slope efficiency was 0.91 W/A and the kink level was 620 mW. Further, the maximum light output power upon injection of current at 1.22 A was 761 mW.

Further, the full width of the half maximum FFP_{V} at 450 mW light output power was 23.5 degrees, and the full width of the half maximum FFP_{H} in the horizontal direction was 8.5 degrees. In this case, as typically shown in FIG. 7, three peaks were confirmed for the FFP_{V} in the order of a sub peak, a main peak and a sub peak in which the position for the respective peaks were −54.6 degrees, 0.9 degree, and 55.3 degrees in the order of the angle. Further, the relative intensity assuming the intensity of the main peak as 1 was 0.07, 1, and 0.04 in the order of the angle. On the other hand, only one peak was confirmed for the FFP_{H} for the portion of the main peak of the FFP_{V} and the peak position was at −0.2 degree. The oscillation wavelength of the device at 450 mA light output power was 984 nm.

Using the device, an optical fiber with a grating, having a fiber lens of a wedged top end, was mounted on the side of the front facet of the device to fabricate a semiconductor laser module having a butterfly type package. The grating fiber had a reflection center of 982 nm and a reflectivity of 3%. At 25° C., the threshold current was 25.6 mA and the slope efficiency was 0.75 mw/mA for the light emitted from the fiber end. The coupling efficiency was good as about 82.4%.

### EXAMPLE 5

A semiconductor laser shown in FIG. 8 as a cross sectional view from the light emitting direction was fabricated by the following procedures.

At first, on the (100) plane of an n-type GaAs substrate (1) at a carrier concentration of 1.0×10¹⁸ cm⁻³, were stacked successively by an MOCVD method, an Si doped n-type GaAs layer of 0.5 μm thickness at a carrier concentration of 1.0×10¹⁸ cm⁻³ as a buffer layer (2); an Si-doped n-type Al_{0.45}Ga_{0.55}As layer of 2.3 μm thickness at a carrier concentration of 7.5×10¹⁷ cm⁻³ for 1.3 μm from the side of the substrate and 3.0×10¹⁷ cm⁻³ for 1 μm thereover as a first conductive type first clad layer (3); an Si doped n-type Al_{0.71}Ga_{0.29}As layer of 35 nm thickness at a carrier concentration of 1.0×10¹⁸ cm⁻³ as a first-conduction-type second clad layer (4); an Al_{0.26}Ga_{0.74}As layer of 72 nm thickness at a doping level of Si of 2.0×10¹⁷ cm⁻³ for 32 nm from the side of the substrate and undoped for 40 nm thereover as a first optical guide layer (5); an active layer structure comprising five layers of an Si-doped n-type GaAs barrier layer of 5 nm thickness at a carrier concentration of 7.5×10¹⁷ cm⁻³ (undoped for 1 nm on the side of the quantum well layer), an undoped In_{0.16}Ga_{0.84}As strained quantum well layer of 6 nm thickness; an Si-doped n-type GaAs barrier layer of 7 nm thickness at a carrier concentration of 7.5×10¹⁷ cm⁻³ (undoped for 1 nm on the side of both quantum well layers), an undoped In_{0.16}Ga_{0.84}As strained quantum well layer of 6 nm thickness, and an Si-doped n-type GaAs barrier layer at a carrier concentration 7.5×10¹⁷ cm⁻³ (undoped for 1 nm on the side of the quantum well layer) as an active layer structure (6); a Al_{0.26}Ga_{0.74}As layer of 72 nm thickness undoped for 32 nm from the side of the substrate and at a Zn doping level of 3.0×10¹⁷ cm⁻³ for 40 nm thereover as a second optical guide layer (7); a Zn-doped p-type Al_{0.71}Ga_{0.29}As layer of 35 nm thickness at a carrier concentration of 7.5×10¹⁷ cm⁻³ as a second-conduction-type second clad layer (8); a Zn doped p-type Al_{0.45}Ga_{0.35}As layer of 25 nm thickness at a carrier concentration of 5.0×10¹⁷ cm⁻³ as a second-conduction-type lower first clad layer (9); an Si doped n-type Al_{0.49}Ga_{0.51}As layer of 0.3 μm thickness at a carrier concentration of 5.0×10¹⁷ cm⁻³ as a current block layer (11); and an Si-doped n-type GaAs layer of 10 nm thickness at a carrier concentration of 7.5×10¹⁷ cm⁻³ as a cap layer (12).

A mask of silicon nitride was provided to the uppermost layer excluding a current injection region portion. In this case, the width for the opening of the silicone nitride mask was 1.5 μm. Using the same as a mask, etching was conducted at 20° C. for 97 sec to remove the cap layer and the current block layer in the current injection region portion. For the etchant, a liquid mixture formed by mixing phosphoric acid (85% by weight), hydrogen peroxide (30% by weight of aqueous solution) and water at a volume ratio of 1:1:30 was used.

Then, a Zn-doped p-type Al_{0.45}Ga_{0.55}As layer of 2.3 μm thickness at a carrier concentration of 4.0×10¹⁷ cm⁻³ for one μm from the side of the substrate and 7.5×10¹⁷ cm⁻³ for 1.3 μm thereover as the second-conduction-type upper first clad layer (10); and a Zn-doped GaAs layer of 3.0 μm thickness at a carrier concentration of 1.0×10¹⁸ cm⁻³ for 2.7 μm from the side of the substrate and at 6.0×10¹⁸ cm⁻³ for 0.3 μm thereover as the contact layer (13) were grown again by an MOCVD method.

Further, Ti/Pt/Au were evaporated by 70 nm/70 nm/80 nm respectively as the epitaxial layer side (p-side) electrode (14), and AuGeNi/Au were evaporated by 150 nm/80 nm respectively as the substrate side (n-side) electrode (15) respectively after polishing the substrate and then alloying was conducted at 400° C. for 5 min to complete a wafer for a semiconductor laser.

The width W of the current injection region of the completed semiconductor laser was 2.3 μm.

Successively, it was cleaved in atmospheric air into the shape of a laser bar at a cavity length of 1600 μm to expose the (110) plane and an AlOₓ film was formed by 165 nm such that the reflectivity on the front facet at an oscillation wavelength of 980 nm was 2.5%, to form a coating layer 16 (FIG. 3). Further, for processing the back facet, a coating layer (17) comprising four layers of AlOₓ layer of 170 nm thickness/amorphous Si layer of 60 nm thickness/AlOₓ layer of 170 nm thickness/amorphous Si layer of 60 nm thickness was formed, to prepare a back facet at 92% reflectivity.

In the current-light output power characteristics at 25° C. of the fabricated device, the threshold current was 27.1 mA, the slope efficiency was 0.94 W/A and the kink level was 580 mW. Further, the maximum light output power was 682 mW.

Further, the full width of the half maximum of the FFP in the vertical direction (FFP_{V}) was 21.8 degrees, and the full width of the half maximum of the FFP in the horizontal direction (FFP_{H}) was 8.7 degrees. In this case, as typically shown in FIG. 7, three peaks were confirmed for the FFP_{V} in the order of a sub peak, a main peak and a sub peak in which the respective peak positions were −53.5 degrees, −0.2 degree, and 53.9 degrees in the order of the angle. Further, the relative intensity assuming the intensity of the main peak as 1 was 0.1, 1, and 0.07 respectively in the order of the angle. On the other hand, only one peak was confirmed for the FFP_{H} for the portion of the main peak of the FFP_{V} and the peak position was at 0.5 degree. The oscillation wavelength of the device was 984 nm.

Using the device, an optical fiber with a grating, having a fiber lens of a wedged top end, was mounted on the side of the front facet of the device to fabricate a semiconductor laser module having a butterfly type package. The grating fiber has a reflection center of 982 nm and a reflectivity of 3%. At 25° C., the threshold current was 23.6 mA and the slope efficiency was 0.78 mW/mA for the light emitted from the fiber end. The coupling efficiency was good as about 82.9%.

### EXAMPLE 6

A loss guide type semiconductor laser having an oscillation wavelength near 780 nm was fabricated by the following procedures.

At first, on the (100) plane of an n-type GaAs substrate (1) at a carrier concentration of 1.0×10¹⁸ cm⁻³, were stacked successively by an MOCVD method, an Si doped n-type GaAs layer of 1.0 μm thickness at a carrier concentration of 1.0×10¹⁸ cm⁻³ as a buffer layer (2); an Si-doped n-type Al_{0.55}Ga_{0.45}As layer of 1.5 μm thickness at a carrier concentration of 1.0×10¹⁸ cm⁻³ for 1.0 μm from the side of the substrate and 6.0×10¹⁷ cm⁻³ for 0.5 μm thereover as a first conductive type first clad layer (3); an Si doped n-type Al_{0.8}Ga_{0.2}As layer of 25 nm thickness at a carrier concentration of 1.0×10¹⁸ cm⁻³ as a first-conduction-type second clad layer (4); a bulk active layer as an undoped Al_{0.15}Ga_{0.85}As single layer of 100 nm thickness as an active layer structure (6); a Zn-doped p-type Al_{0.8}Ga_{0.2}As layer of 25 nm thickness at a carrier concentration of 1.0×10¹⁸ cm⁻³ as a second-conduction-type second clad layer (8), a Zn-doped p-type Al_{0.55}Ga_{0.45}As layer of 350 nm thickness at a carrier concentration of 8.0×10¹⁷ cm⁻³ as a second-conduction-type lower first clad layer (9); and an Si doped n-type GaAs layer of 0.7 μm thickness at a carrier concentration of 3.0×10¹⁸ cm⁻³ as a current block layer (11).

A mask of silicon nitride was provided to the uppermost layer excluding a current injection region portion. In this case, the width for the opening of the silicone nitride mask was 1.2 μm. Using the same as a mask, the current block layer in the current injection region portion was removed. For the etchant, a liquid mixture formed by mixing phosphoric acid (85% by weight), hydrogen peroxide (30% by weight of aqueous solution) and water at a volume ratio of 1:1:30 was used.

Then, a Zn-doped p-type Al_{0.55}Ga_{0.45}As layer of 1.15 μm thickness at a carrier concentration of 1.4×10¹⁸ cm⁻³ as the second-conduction-type upper first clad layer (10); and a Zn-doped GaAs layer of 7.0 μm thickness at a carrier concentration of 7.0×10¹⁸ cm⁻³ as the contact layer (13) were grown again.

Further, Ti/Pt/Au were evaporated by 70 nm/70 nm/80 nm respectively as the epitaxial layer side (p-side) electrode, further, AuGeNi/Au were evaporated by 150 nm/80 nm respectively as the substrate side (n-side) electrode respectively after polishing the substrate and then alloying was conducted at 400° C. for 5 min to complete a wafer for a semiconductor laser.

The width W of the current injection region of the completed semiconductor laser was 3.2 μm.

Successively, it was cleaved in atmospheric air into the shape of a laser bar at a cavity length of 250 μm to expose the (110) plane and an AlOₓ film was farmed such that the reflectivity was 33% at an oscillation wavelength of 780 nm on both back and front facets.

In the current-optical output power characteristic at 25° C. of the fabricated device, the threshold current was 43.5 mA and the slope efficiency was 0.29 W/A. Further, the full width of the half maximum of the FFP in the vertical direction (FFP_{V}) at 3 mW light output power was 22.8 degrees, and the full width of the half maximum of the FFP in the horizontal direction (FFP_{H}) was 8.7 degree. In this case, three peaks were confirmed in the vertical direction for the FFP in the order of a sub peak, a main peak and a sub peak. Further, the relative intensity assuming the intensity of the main peak as 1 was 0.21, 1, and 0.11 in the order of the angle. On the other hand, only one peak was confirmed for the FFP_{H} for the portion of the main peak of the FFP_{V} and the peak position was at 0.7 degree. The oscillation wavelength of the device at 3 mw optical output was 775 nm.

### COMPARATIVE EXAMPLE 4

A semiconductor laser was fabricated in the same manner as in Example 4 except for changing the thickness of the first optical guide layer (5) and the second optical guide layer (7) to 40 nm, the undoped region therein to 10 nm and the thickness of both the first-conduction-type second clad layer (4) and the second-conduction-type second clad layer (8) to 50 nm.

The threshold current was 39.5 mA and the slope efficiency was 0.7 W/A and the kink level was 485 mW which were inferior to Example 4 in view of the entire device-characteristics. Also the maximum light output power of the device was 520 mW which was lower compared with that of Example 4.

Further, three peaks were observed in the order of a sub peak, a main peak and a sub peak in the FFP in the vertical direction (FFP_{V}) at the light output power of 450 mW and the respective peak positions were at −55.5 degrees, 0.3 degree, and 57.6 degrees in the order of the angle. The relative intensity assuming the intensity of the main peak as 1 was 0.61, 1.0, and 0.4 respectively in the order of the angle, and the intensity of the sub peak was much larger than that of Example 4. The full width of the half maximum is of the FFP in the vertical direction (FFP_{V}) was 15.2 degrees, and the full width of the half maximum of the FFP in the horizontal direction (FFP_{H}) was 8.4 degrees, with respect to only the peak portion. The oscillation wavelength of the device at 450 mW power was 992 nm.

Using the device, a semiconductor laser module, having a butterfly type package, identical with that in Example 4 was fabricated. The threshold current was 36.1 mA and the slope efficiency was 0.48 mW/mA to the light emitted from the fiber end at 25° C. The coupling efficiency was about 68.6% which was inferior to Example 4.

### EXAMPLE 7

A semiconductor laser shown in FIG. 10 as across sectional view from the light emitting direction was fabricated by the following procedures.

At first, on the (100) plane of an n-type GaAs substrate (1) at a carrier concentration of 1.0×10¹⁸ cm⁻³, were stacked successively by an MBE method, an Si doped n-type GaAs layer of 0.5 μm thickness at a carrier concentration of 1.0×10¹⁸ cm⁻³ (refractive index of 3.525 at 980 nm) as a buffer layer (2); an Si-doped n-type Al_{0.19}Ga_{0.81}As layer of 2.3 μm thickness at a carrier concentration of 7.5×10¹⁷ cm⁻³ for 1.3 μm from the side of the substrate and 3.0×10¹⁷ cm⁻³ for 1 μm thereover (refractive index of 3.422 at 980 nm) as a first conductive type first clad layer (3); an Si doped n-type Al_{0.4}Ga_{0.6}As layer of 35 nm thickness at a carrier concentration of 8.0×10¹⁷ cm⁻³ (refractive index of 3.307 at 980 nm) as a first-conduction-type second clad layer (4); an GaAs layer of 80 nm thickness at a doping level of Si of 2.0×10¹⁷ cm⁻³ for 40 nm from the side of the substrate and undoped for 40 n thereover as a first optical guide layer (5) (refractive index of 3.525 at 980 nm); an active layer structure comprising five layers of an Si-doped n-type GaAs barrier layer of 5 nm thickness at a carrier concentration of 7.5×10¹⁷ cm⁻³ (undoped for 1 nm on the side of the quantum well layer), an undoped In_{0.16}Ga_{0.84}As strained quantum well layer of 6 nm thickness, an Si-doped n-type GaAs barrier layer of 8 nm thickness at a carrier concentration of 7.5×10¹⁷ cm⁻³ (undoped for 1 nm on the side of both quantum well layers), an undoped In_{0.16}Ga_{0.84}As strained quantum well layer of 6 nm thickness, and an Si-doped n-type GaAs barrier layer of 5 nm thickness at a carrier concentration of 7.5×10¹⁷ cm⁻³ (undoped for 1 nm on the side of the quantum well layer) as an active layer structure (6); a GaAs layer of 80 nm thickness undoped for 40 nm from the side of the substrate and at a Be doping level of 3.0×10¹⁷ cm⁻³ for 40 nm thereover (refractive index of 3.525 at 980 nm) as a second optical guide layer (7); Be doped p-type Al_{0.4}Ga_{0.6}As layer of 35 nm thickness at a carrier concentration of 7.5×10¹⁷ cm⁻³ (refractive index of 3.307 at 980 nm) as a second-conduction-type second clad layer (8); a Be doped p-type Al_{0.19}Ga_{0.81}As layer of 25 nm thickness at a carrier concentration of 5.0×10¹⁷ cm⁻³ (refer to index of 3.422 at 980 nm) as a second-conduction-type lower first clad layer (9); an Si doped n-type Al_{0.23}Ga_{0.78}As layer of 0.3 μm thickness at a carrier concentration of 4.0×10¹⁷ cm⁻³ (refractive index of 3.401 at 980 nm) as a current block layer (11); and an Si-doped n-type GaAs layer of 10 nm thickness at a carrier concentration of 7.5×10¹⁷ cm⁻³ as a cap layer (12).

A mask of silicon nitride was provided to the uppermost layer excluding a current injection region portion. In this case, the width for the opening of the silicone nitride mask was 1.5 μm. Using the same as a mask, etching was conducted at 20° C. for 105 sec to remove the cap layer (12) and the current block layer (11) in the current injection region portion. For the etchant, a liquid mixture formed by mixing phosphoric acid (85% by weight), hydrogen peroxide (30% by weight of aqueous solution) and water at a volume ratio of 1:1:30 was used.

Then, a Zn-doped p-type Al_{0.19}Ga_{0.81}As layer of 2.3 μm thickness at a carrier concentration of 4.0×10¹⁷ cm⁻³ for one μm from the side of the substrate (1) and 7.5×10¹⁷ cm⁻³ for 1.3 μm thereover (refractive index of 3.422 at 980 nm) as the second-conduction-type upper first clad layer (10); and a Zn-doped GaAs layer of 3.0 μm thickness at a carrier concentration of 1.0×10¹⁸ cm⁻³ for 2.7 μm from the side of the substrate (1) and at 7.0×10¹⁸ cm⁻³ for 0.3 μm thereover as the contact layer (13) were grown again by an MOCVD method.

In the device, Vₙ was 0.515222, Vₚ was 0.515222, and Rₙ was 0.4375, and Rₚ was also 0.4375.

In the fabrication of the device, Ti/Pt/Au were evaporated by 70 nm/70 nm/BO nm respectively as the epitaxial layer side (p-side) electrode (14), further, AuGeNi/Au were evaporated by 150 nm/80 nm respectively as the substrate side (n-side) electrode (15) after polishing the substrate (1) and then alloying was conducted at 400° C. for 5 min to complete a wafer for a semiconductor laser.

The width W of the current injection region of the completed semiconductor laser was 2.2 μm.

Successively, it was cleaved in atmospheric air into the shape of a laser bar at a cavity length of 1600 μm to expose the (110) plane and an AlOₓ film was formed by 165 nm such that the reflectivity on the front facet at an oscillation wavelength of 980 nm was 2.5%, to form a coating layer 16. Further, for processing the back facet, a coating layer (17) comprising four layers of AlOₓ layer of 170 nm thickness/amorphous Si layer of 60 nm thickness/AlOₓ layer of 170 nm thickness/amorphous Si layer of 60 nm thickness was formed, to prepare a back facet at 92% reflectivity.

In the current/power characteristics at 25° C. of the fabricated device, the threshold current was 29.8 mA, the slope efficiency was 0.92 W/A and the kink level was 622 mW. Further, the maximum light output power was 773 mW.

Further, the full width of the half maximum of the FFP in the vertical direction (FFP_{V}) at 450 mW light output power was 24.1 degrees, and the full width of the half maximum of the FFP in the horizontal direction (FFP_{H}) was 8.5 degrees. In this case, as typically shown in FIG. 7, three peaks were confirmed for the FFP_{V} in the order of a sub peak, main peak and a sub peak in which the respective peak positions were −52.0 degrees, 0.5 degree, and 53.2 degrees in the order of the angle. Further, the relative intensity assuming the intensity of the main peak as 1 was 0.10, 1, and 0.03 in the order of the angle. On the other hand, only one peak was confirmed for the FFP_{H} for the portion of the main peak of the FFP_{V}, and the peak position was at 0.9 degree. The oscillation wavelength of the device was 984 nm.

Using the device, an optical fiber with a grating, having a fiber lens of a wedged top end, was mounted on the side of the front facet of the device to fabricate a semiconductor laser module having a butterfly type package. The grating fiber has a reflection center of 982 nm and a reflectivity of 3%. At 25° C., the threshold current was 25.3 mA and the slope efficiency was 0.76 mW/mA for the light emitted from the fiber end. The coupling efficiency was good as about 82.6%.

### EXAMPLE 8

A semiconductor laser shown in FIG. 10 as a cross sectional view from the light emitting direction was fabricated by the following procedures.

At first, on the (100) plane of an n-type GaAs substrate (1) at a carrier concentration of 1.0×10¹⁸ cm⁻³, were stacked successively by an MOCVD method, an Si doped n-type GaAs layer of 0.5 μm thickness at a carrier concentration of 1.0×10¹⁸ cm⁻³ (refractive index of 3.525 at 980 nm) as a buffer layer (2); an Si-doped n-type Al_{0.25}Ga_{0.75}As layer of 2.3 μm thickness at a carrier concentration of 7.5×10¹⁷ cm⁻³ for 1.3 μm from the side of the substrate and 3.0×10¹⁷ cm⁻³ for 1 μm thereover (refractive index of 3.390 at 980 nm) as a first conductive type first clad layer (3); an Si doped n-type Al_{0.45}Ga_{0.55}As layer of 40 nm thickness at a carrier concentration of 1.0×10¹⁸ cm⁻³ (refractive index of 3.279 at 980 nm) as a first-conduction-type second clad layer (4); an GaAs layer of 80 nm thickness at a doping level of Si of 2.0×10¹⁷ cm⁻³ for 40 nm from the side of the substrate and undoped for 40 nm thereover (refractive index of 3.525 at 980 nm) as a first optical guide layer (5); an active layer structure comprising five layers of an Si-doped n-type GaAs barrier layer of 5 nm thickness at a carrier concentration of 7.5×10¹⁷ cm⁻³ (undoped for 1 nm on the side of the quantum well layer), an undoped In_{0.16}Ga_{0.94}As strained quantum well layer of 6 nm thickness, an Si-doped n-type GaAs barrier layer of 8 nm thickness at a carrier concentration of 7.5×10¹⁷ cm⁻³ (undoped for 1 nm on the side of both quantum well layers), an undoped In_{0.16}Ga_{0.84}As strained quantum well layer of 6 nm thickness, and an Si-doped n-type GaAs barrier layer at 5 nm thickness at a carrier concentration of 7.5×10¹⁷ cm⁻³ (undoped for 1 nm on the side of the quantum well layer) as an active layer structure (6); a GaAs layer of 80 nm thickness undoped for 40 nm from the side of the substrate and at a Be doping level of 3.0×10¹⁷ cm⁻³ for 40 nm thereover (refractive index of 3.525 at 980 nm) as a second optical guide layer (7); Zn doped p-type Al_{0.45}Ga_{0.55}As layer of 40 nm thickness at a carrier concentration of 7.5×10¹⁷ cm⁻³ (refractive index of 3.279 at 980 nm) as a second-conduction-type second clad layer (8); a Zn-doped p-type Al_{0.25}Ga_{0.75}As layer of 25 nm thickness at a carrier concentration of 5.0×10¹⁷ cm⁻³ (refractive index of 3.390 at 980 nm) as a second-conduction-type lower first clad layer (9); an Si doped n-type Al_{0.275}Ga_{0.725}As layer of 0.3 μm thickness at a carrier concentration of 5.0×10¹⁷ cm⁻³ (refractive index of 3.376 at 980 nm) as a current block layer (11); and an Si-doped n-type GaAs layer of 10 nm thickness at a carrier concentration of 7.5×10¹⁷ cm⁻³ as a cap layer (12).

A mask of silicon nitride was provided to the uppermost layer excluding a current injection region portion. In this case, the width for the opening of the silicone nitride mask was 1.5 μm. Using the same as a mask, etching was conducted at 20° C. for 97 sec to remove the cap layer and the current block layer in the current injection region portion. For the etchant, a liquid mixture formed by mixing phosphoric acid (85% by weight), hydrogen peroxide (30% by weight of aqueous solution) and water at a volume ratio of 1:1:30 was used.

Successively, a Zn-doped p-type Al_{0.25}Ga_{0.75}As layer of 2.3 μm thickness at a carrier concentration of 4.0×10¹⁷ cm⁻³ for one μm from the side of the substrate (1) and 7.5×10¹⁷ cm⁻³ for 1.3 μm thereover (refractive index of 3.390 at 980 nm) as the second-conduction-type upper first clad layer (10); and a Zn-doped GaAs layer of 3.0 μm thickness at a carrier concentration of 1.0×10¹⁸ cm⁻³ for 2.7 μm from the side of the substrate (1) and at 6.0×10¹⁸ cm⁻³ for 0.3 μm thereover as the contact layer (13) were grown again.

In the device, Vₙ was 0.588492, Vₚ was 0.588492. Further, Rₙ was 0.5 and Rₚ was also 0.5.

Further, Ti/Pt/Au were evaporated by 70 nm/70 nm/80 nm respectively as the epitaxial layer side (p-side) electrode (14), further, AuGeNi/Au were evaporated by 150 nm/80 nm respectively as the substrate side (1) (n-side) electrode (15) after polishing the substrate and then alloying was conducted at 400° C. for 5 min to complete a wafer for a semiconductor laser.

The width W of the current injection region of the completed semiconductor laser was 2.3 μm.

Successively, it was cleaved in atmospheric air into the shape of a laser bar at a cavity length of 1600 μm to expose the (110) plane and an AlOₓ film was formed by 165 nm such that the reflectivity on the front facet at an oscillation wavelength of 980 nm was 2.5%, to form a coating layer 16. Further, for processing the back facet, a coating layer (17) comprising four layers of AlOₓ layer of 170 nm thickness/amorphous Si layer of 60 nm thickness/AlOₓ layer of 170 nm thickness/amorphous Si layer of 60 nm thickness was formed, to prepare a back facet at 92% reflectivity.

In the current-optical output power characteristics at 25° C. of the fabricated device, the threshold current was 27.3 mA, the slope efficiency was 0.93 W/A and the kink level was 603 mW. Further, the maximum light output power was 728 mW.

Further, the full width of the half maximum of the FFP in the vertical direction was 23.1 degrees, and the full width of the half maximum of the FFP in the horizontal direction was 8.7 degrees at 450 mW light output power. The oscillation wavelength of the device at 450 mW power was 983 nm.

Using the device, an optical fiber with a grating, having a fiber lens of a wedged top end, was mounted on the side of the front facet of the device to fabricate a semiconductor laser module having a butterfly type package. The grating fiber has a reflection center of 982 nm and a reflectivity of 3%. At 25° C., the threshold current was 21.6 mA and the slope efficiency was 0.78 mW/mA for the light emitted from the fiber end. The coupling efficiency was good as about 83.8%.

### EXAMPLE 9

A semiconductor laser was fabricated in the same manner as in Example B except for changing the first-conduction-type second clad layer (4) in the semiconductor laser described in Example 8 to In_{0.49}Ga_{0.51}P (refractive index of 3.259 at 980 nm) of 30 nm thickness.

In the device, Vₙ was 0.588492 and Vₚ was 0.588492. Further, Rₙ was 0.375 and Rₚ was 0.5.

In the current-optical output power characteristics at 25° C. of the fabricated device, the threshold current was 26.5 mA, the slope efficiency was 0.94 W/A and the kink level was 582 mW. Further, the maximum light output power was 699 mW.

Further, the full width of the half maximum of the FFP in the vertical direction was 23.8 degrees and full width of the half maximum of the FFP in the horizontal direction was 8.8 degrees at 450 mW light output power. The oscillation wavelength of the device at 450 mW power was 983 nm.

### EXAMPLE 10

A semiconductor laser was fabricated in the same manner as in Example 7 except for changing the first-conduction-type first clad layer (3), the second-conduction-type lower first clad layer (9), and the second-conduction-type upper first clad layer (10) to In_{0.49}Ga_{0.51}P, changing the both optical guide layers (5, 7) to an undoped GaAs of 34 nm thickness, changing the first-conduction-type second clad layer (4) and the second-conduction-type second clad layer (8) to an Al_{0.5}Ga_{0.42}As layer of 23 nm thickness, changing the current block layer (11) to an Al_{0.5}Ga_{0.5}As layer and further changing the etching time for the current block layer (11) to 100 sec.

In the device Vₙ was 0.422089 and Vₚ was 0.422089. Further, Rₙ was 0.67647 and Rₚ was also 0.67647.

In the current-light output power characteristics at 25° C. of the fabricated device, the threshold current was 28.3 mA, the slope efficiency was 0.92 W/A, and the kink level was 580 mW. Further, the maximum light output power of the device was 685 mW.

Further, the full width of the half maximum of the FFP in the vertical direction was 24.1 degree and the full width of the half maximum of the FFP in the horizontal direction was 9.0 degree at 450 mW light output power. Further, the oscillation wavelength of the device at 450 mW output was 985 nm.

Using the device, a semiconductor laser module, having a butterfly type package, identical with that of Example 7 was fabricated. At 25° C., the threshold current was 23.9 mA, and the slope efficiency was 0.74 mW/mA to the light emitted from the fiber end. The coupling efficiency was about 80.4%.

### COMPARATIVE EXAMPLE 5

A device was fabricated in the same manner as the semiconductor laser descried in Example 7, except for changing the thickness of both for the first optical guide layer (5) and the second optical guide layer (7) to 32.5 nm while being left undoped for all the layers in the semiconductor laser described in Example 7.

In the device, Vₙ was 0.257015 and Vₚ was also 0.257015. Further, Rₙ was 1.0770 and Rₚ was also 1.0770.

In the fabricated device, the threshold current was 45.7 mA, the slope efficiency was 0.62 W/A, and the kink level was 403 mW which were inferior to those in Example 7. Further, the maximum light output power of the device was 495 mW, which was lower compared with Example 7. The full width of the half maximum of the FFP in the vertical direction measured at 450 mW was 15.1 degrees, and it was suspicious that optical confinement was not sufficient near the active layer. The full width of the half maximum of the FFP in the horizontal direction was 8.2 degrees. Further, the oscillation wavelength of the device was 985.5 nm.

### EXAMPLE 11

A device was fabricated in the same manner as the semiconductor laser described in Example 7 except for changing the thickness both for the first optical guide layer (5) and the second optical guide layer (7) to 85 nm, changing the doping level of Si to 1.0×10¹⁷ cm⁻³ for all of them, changing all of the first-conduction-type first clad layer (3), the second-conduction-type lower first clad layer (9), and the second-conduction-type upper first clad layer (10) to Al_{0.4}Ga_{0.6}As (refractive index of 3.307 at 980 nm), and changing the thickness both for the first-conduction-type second clad layer (4) and the second-conduction-type second clad layer (8) to Al_{0.65}Ga_{0.35}As of 25 nm thickness (refractive index of 3.167 at 980 nm).

In this device Vₙ was 0.782449 and Vₚ was also 0.782449. Further, Rₙ was 0.2941 and Rₚ was also 0.2941.

In the fabricated device, the threshold current was 23.6 mA, and the slope efficiency was 0.98 W/A which were favorable. Further, the maximum light output power of the device was 580 nW.

The semiconductor light emitting device of the invention is capable of easy optical coupling to an optical fiber, etc. and excellent in the high power operation characteristics. Accordingly, the semiconductor light emitting device of the invention can be utilized suitably in a case where high coupling efficiency to an optical system is desired such as in excitation light sources for optical fiber amplifiers, optical light sources for optical information processing and semiconductor lasers for medical use. Further, the semiconductor light emitting device according to the invention can be utilized suitably also in a case of intending to attain a direct coupling at high efficiency between a light emitting device and an optical fiber.

The present disclosure relates to the subject matter contained in PCT/JP2003/011351 filed on Sep. 5, 2003; Japanese Patent Application No. 260863/2002 filed on Sep. 6, 2002; Japanese Patent Application No. 260864/2002 filed on Sep. 6, 2002; and Japanese Patent Application No. 260865/2002 filed on Sep. 6, 2002, which are expressly incorporated herein by reference in their entirety.

The foregoing description of preferred embodiments of the invention has been presented for purposes of illustration and description, and is not intended to be exhaustive or to limit the invention to the precise form disclosed. The description was selected to best explain the principles of the invention and their practical application to enable others skilled in the art to best utilize the invention in various embodiments and various modifications as are suited to the particular use contemplated. It is intended that the scope of the invention not be limited by the specification, but be defined claims set forth below.

1. A semiconductor light emitting device having an emission wavelength λ(nm) and a structure of stacking, on a first-conduction-type substrate, at least a first-conduction-type first clad layer, a first-conduction-type second clad layer, an active layer structure, a second-conduction-type second clad layer, and a second-conduction-type first clad layer, in this order, and satisfying at least one of the following conditions 1 to 3:
<Condition 1>
the first-conduction-type first clad layer is an AlₓₙGa₁₋ₓₙAs layer (0<xn<0.40) at a thickness of tₓₙ(nm),
the first-conduction-type second clad layer is an AlₛₙGa₁₋ₛₙAs layer (0<sn≦1) at a thickness of tₛₙ(nm),
a first optical guide layer comprising Al_{gn}Ga_{1-gn}As (0≦gn<0.40) at a thickness of t_{gn} (nm) is present between the first-conduction-type second clad layer and the active layer structure,
a second optical guide layer comprising Al_{gp}Ga_{1-gp}As (0≦gp<0.40) at a thickness of t_{gp} (nm) is present between the active layer structure and the second-conduction-type second clad layer,
the second-conduction-type second clad layer is an AlₛₚGa₁₋ₛₚAs layer (0<sp≦1) at a thickness of tₛₚ(nm),
the second-conduction-type first clad layer is an AlₓₚGa₁₋ₓₚAs layer (0<xp<0.40) of tₓₚ(nm) thickness, and the following formulae are satisfied:
gn<xn<sn gp<xp<sp
0.08<sn−xn 0.08<sp−xp
tₛₙ/t_{gn}<1.0 tₛₚ/t_{gp}<1.0
<Condition 2>
the semiconductor light emitting device is a semiconductor laser in which
only the fundamental-mode propagation is allowed with respect to the vertical direction,
the radiation pattern of a light emitted from a semiconductor laser having a main peak with a maximum intensity of I_{Vmain} and two sub peaks with maximal intensities of I_{Vsub-} and I_{Vsub+} respectively are present in the far field pattern in the vertical direction to the substrate (the FFP_{V}), and
the following formula is satisfied:
0<I_{Vsub}/I_{Vmain}<0.5
wherein I_{Vsub} represents I_{Vsub-} or I_{Vsub+} which has a higher intensity;
<Condition 3>
a first-conduction-type first clad layer has an average refractive index of nₙ₁ and a thickness of tₙ₁ (nm),
a first-conduction-type second clad layer has an average refractive index of nₙ₂ and a thickness of tₙ₂ (nm),
a first optical guide layer having an average refractive index of n_{ng} and a thickness of t_{ng} (nm) is present between the first-conduction-type second clad layer and the active layer structure,
the active layer structure has an average refractive index of nₐ and a total thickness of tₐ (nm),
a second optical guide layer having an average refractive index of n_{pg} and a thickness of t_{pg} (nm) is present between the active layer structure and the second-conduction-type second clad layer,
the second-conduction-type second clad layer has an average refractive index of nₚ₂ and a thickness of tₚ₂ (nm),
the second-conduction-type first clad layer has an average refractive index of nₚ₁ and a thickness of tₚ₁ (nm), and, assuming the wave number k, Vₙ, Vₚ, Rₙ, and Rₚ as in (formulae 1):
k=2π/λ
Vₙ=k/2×(tₐ+t_{ng}+t_{pg})×(n_{ng}²−nₙ₁²)^{1/2}
Vₚ=k/2×(tₐ+t_{ng}+t_{pg})×(n_{pg}²−nₚ₁²)^{1/2}
Rₙ=tₙ₂/t_{ng}
Rₚ=tₚ₂/t_{pg} (formulae 1),
each of the relations of (formulae 2) is satisfied:
nₙ₂<nₙ₁<n_{ng}<nₐ
nₚ₂<nₚ₁<n_{pg}<nₐ
0.35<Vₙ<0.75
0.35<Vₚ<0.75
0.3<Rₙ<0.7
0.3<Rₚ<0.7 (formulae 2)

2. The semiconductor light emitting device as claimed in claim 1, wherein the condition 1 is satisfied.

3. The semiconductor light emitting device as claimed in claim 2, wherein the active layer structure contains In, Ga and As and contains a strained quantum well layer not lattice matched to the substrate.

4. The semiconductor light emitting device as claimed in claim 2, wherein the following formulae are satisfied:
λ<tₓₙ λ<tₓₚ

5. The semiconductor light emitting device as claimed in claim 2, wherein the following formulae are satisfied assuming the refractive index of the first optical guide layer as n_{gn} and the refractive index of the second optical guide layer as n_{gp} at a wavelength λ(nm):
0.5×[λ/(4×n_{gn})]nm<t_{gn}<1.5×[λ/(4×n_{gn})]nm
0.5×[λ/(4×n_{gp})]nm<t_{gp}<1.5×[λ/(4×n_{gp})]nm

6. The semiconductor light emitting device as claimed in claim 2, wherein the following formulae are satisfied.
sn<0.5
sp<0.5

7. The semiconductor light emitting device as claimed in claim 2, wherein the following formulae are satisfied.
sn−xn<0.4
sp−xp<0.4

8. The semiconductor light emitting device as claimed in claim 2, wherein the following formulae are satisfied.
0.3<tₛₙ/t_{gn}
0.3<tₛₙ/t_{gn}

9. The semiconductor light emitting device as claimed in claim 2, wherein the following formulae are satisfied.
10 nm<tₛₙ<100 nm
10 nm<tₛₚ<100 nm

10. The semiconductor light emitting device as claimed in claim 2, wherein the following formula is satisfied.
gn=gp=0

11. The semiconductor light emitting device as claimed in claim 2, wherein the barrier layers in the active layer structure contain portions having a conduction type identical with that of the substrate.

12. The semiconductor light emitting device as claimed in claim 11, wherein the dopant for the portion in the barrier layer having the conduction type identical with that of the substrate is Si.

13. The semiconductor light emitting device as claimed in claim 2, wherein the doping level in at least one of the first-conduction-type first clad layer and the second-conduction-type first clad layer is not uniform in the respective layers.

14. The semiconductor light emitting device as claimed in claim 2, wherein a layer comprising AlₜGa₁₋ₜAs is present between the first clad layer and the second clad layer showing at least one of conduction types, and the Al composition t thereof gradually increases from xn to sn or from xp to sp from the side of the first clad layer to the side of the second clad layer.

15. The semiconductor light emitting device as claimed in claim 2, wherein the following formulae are satisfied.
xn=xp
sn=sp tₛₙ=tₛₚ
gn=gp t_{gn}=t_{gp}

16. The semiconductor light emitting device as claimed in claim 2, wherein current injection to the active layer is not conducted at a constant width in the direction of a cavity.

17. The semiconductor light emitting device as claimed in claim 16, wherein the width for the current injection channel is widened in the vicinity of at least one of the light emission points of the device.

18. The semiconductor light emitting device as claimed in claim 17, wherein the width Wₑₓₚ for the current injection channel in the vicinity of one of the light emission points of the device satisfies the following formulae with respect to the width W_{std} of the narrowest current injecting channel in the device:
1.5<Wₑₓₚ/W_{std}<5.0

19. The semiconductor light emitting device as claimed in claim 2, wherein the second-conduction-type first clad layer consists of two layers of a second-conduction-type upper first clad layer and a second-conduction-type lower first clad layer, the second-conduction-type upper first clad layer and the current block layer form a current injection region, and a contact layer is further provided.

20. The semiconductor light emitting device as claimed in claim 2, wherein the semiconductor light emitting device is a semiconductor laser.

21. The semiconductor light emitting device as claimed in claim 20, wherein the semiconductor laser is a semiconductor laser that operates in a single transverse-mode.

22. The semiconductor light emitting device as claimed in claim 2, wherein the first conduction type is an n type and the second conduction type is a p type.

23. The semiconductor light emitting device module comprising the semiconductor light emitting device as claimed in claim 2 and an optical fiber on the side of the light emission end of the semiconductor light emitting device.

24. The semiconductor light emitting device module as claimed in claim 23, wherein the top end of the optical fiber has a light focusing effect and is fabricated to be optically coupled directly to the front facet of the semiconductor light emitting device.

25. The semiconductor light emitting device as claimed in claim 1, wherein the condition 2 is satisfied.

26. The semiconductor light emitting device as claimed in claim 25, wherein the following formulae are satisfied in a case where the angle at which the main peak appears is P(I_{Vmain}), and the angles at which two sub peaks at the maximal intensities of I_{Vsub-} and I_{Vsub+} appear are P(I_{Vsub-}) and P(I_{Vsub+}) respectively:

|P(I_{Vmain})−P(I_{Vsub-})|>40 degrees

|P(I_{Vsub+})−P(I_{Vmain})|>40 degrees

|P(I_{Vsub+})−P(I_{Vsub-})|>80 degrees

27. The semiconductor light emitting device as claimed in claim 25, wherein only one maximal value is present in the far field pattern in the horizontal direction with the substrate (the FFP_{H}) in a radiation pattern of a main peak emitted from the semiconductor light emitting device.

28. The semiconductor light emitting device as claimed in claim 27, wherein the following formula is satisfied in a case where the maximum intensity of the far field in the horizontal direction with the substrate (the FFP_{H}) is I_{Hmain}, and the angle at which the peak having the maximum intensity appears is P(I_{Hmain});

|P(I_{Vmain})−P(I_{Hmain})|<5 degree

29. The semiconductor light emitting device as claimed in claim 25, wherein the oscillation wavelength λ (nm) satisfies the following formula:
900 nm<λ<1350 nm

30. The semiconductor light emitting device as claimed in claim 25, wherein the device has no plural light emission points therein.

31. The semiconductor light emitting device as claimed in claim 25, wherein refractive indexes satisfy the following formulae assuming the average refractive index of the first-conduction-type first clad layer as Nₓₙ, the average refractive index of the first-conduction-type second clad layer as Nₛₙ, the average refractive index of the active layer structure as Nₛ, the average refractive index of the second-conduction-type second clad layer as Nₛₚ, and the average refractive index of the second-conduction-type first clad layer as Nₓₚ:
Nₛₙ<Nₓₙ<Nₐ
Nₛₚ<Nₓₚ<Nₐ

32. The semiconductor light emitting device as claimed in claim 31, wherein the optical guide layer is present on at least one side of the active layer structure and in a case where the refractive index of the optical guide layer is N_{g}, the refractive indexes of the respective layers satisfies the following formulae:
Nₐₙ<Nₓₙ<N_{g}<Nₐ
Nₛₚ<Nₓₚ<N_{g}<Nₐ

33. The semiconductor light emitting device as claimed in claim 25, wherein the substrate comprises GaAs, and at least a portion of the first-conduction-type first clad layer, at least a portion of the first-conduction-type second clad layer, at least a portion of the second-conduction-type second clad layer, and at least a portion of the second-conduction-type first clad layer contain Al, Ga and As.

34. The semiconductor light emitting device as claimed in claim 25, wherein the substrate comprises GaAs, and at least a portion of the first-conduction-type first clad layer, at least a portion of the first-conduction-type second clad layer, at least a portion of the second-conduction-type second clad layer, and at least a portion of the second-conduction-type first clad layer contain In, Ga and P.

35. The semiconductor light emitting device as claimed in claim 25, wherein the active layer structure contains a strained quantum well layer and the quantum well layer contains In, Ga and As.

36. The semiconductor light emitting device as claimed in claim 25, wherein the first conduction type is an n-type and the second conduction type is a p-type.

37. The semiconductor light emitting device module comprising the semiconductor light emitting device as claimed in claim 25, and an optical fiber on the light emission end of the semiconductor light emitting device.

38. The semiconductor light emitting device as claimed in claim 37, wherein the top end of the optical fiber has a light focusing effect and is fabricated to be optically coupled directly to the front facet of the semiconductor light emitting device.

39. The semiconductor light emitting device as claimed in claim 1, wherein the condition 3 is satisfied.

40. The semiconductor light emitting device as claimed in claim 39, wherein the following formula is satisfied.
0.4<Vₙ<0.6

41. The semiconductor light emitting device as claimed in claim 39, wherein the following formula is satisfied.
0.4<Vₚ<0.6

42. The semiconductor light emitting device as claimed in claim 39, wherein the following formula is satisfied.
0.35<Rₙ<0.55

43. The semiconductor light emitting device as claimed in claim 39, wherein the following formula is satisfied.
0.35<Rₚ<0.55

44. The semiconductor light emitting device as claimed in claim 39, wherein the following formulae are satisfied.
nₙ₁=nₚ₁
nₙ₂=nₚ₂
n_{ng}=n_{pg}
Vₚ=Vₙ
Rₙ=Rₚ

45. The semiconductor light emitting device as claimed in claim 39, wherein the following formula is satisfied.
40 nm<t_{ng}<100 nm

46. The semiconductor light emitting device as claimed in claim 39, wherein the following formula is satisfied.
40 nm<t_{pg}<100 nm

47. The semiconductor light emitting device as claimed in claim 39, wherein the substrate comprises GaAs, and at least a portion of the first-conduction-type first clad layer, at least a portion of the first-conduction-type second clad layer, at least a portion of the second-conduction-type second clad layer, and at least a portion of the second-conduction-type first clad layer contain Al, Ga and As.

48. The semiconductor light emitting device as claimed in claim 39, wherein the substrate comprises GaAs, and at least a portion of the first-conduction-type first clad layer, at least a portion of the first-conduction-type second clad layer, at least a portion of the second-conduction-type second clad layer, and at least a portion of the second-conduction-type first clad layer contain In, Ga and P.

49. The semiconductor light emitting device as claimed in claim 39, wherein both the first conduction first clad layer and the second-conduction-type first clad layer comprise an AlₓGa₁₋ₓAs material system and the Al composition x of the two layers satisfies the following formula:
0.15<x<0.25

50. The semiconductor light emitting device as claimed in claim 39, wherein both the first conduction second clad layer and the second-conduction-type second clad layer comprise an AlₛGa₁₋ₛAs material system and the Al composition s of the two layers satisfies the following formula:
0.3<s<0.45

51. The semiconductor light emitting device as claimed in claim 39, wherein a transition layer having a band gap closer to the first clad layer on-side of the first clad layer and closer to the second clad layer on the side of the second clad layer is present between the first clad layer and the second clad layer showing at least one of conduction types.

52. The semiconductor light emitting device as claimed in claim 39, wherein both the first optical guide layer and the second optical guide layer comprise GaAs.

53. The semiconductor light emitting device as claimed in claim 39, wherein the active layer structure contains a strained quantum well layer and the quantum well layer contains In, Ga and As.

54. The semiconductor light emitting device as claimed in claim 39, wherein the barrier layers in the active layer structure contain portions having a first conduction type identical with that of the substrate.

55. The semiconductor light emitting device as claimed in claim 54, wherein the dopant in the barrier layer is Si.

56. The semiconductor light emitting device as claimed in claim 39, wherein the doping level in at least one of the first-conduction-type first clad layer and the second-conduction-type first clad layer is not uniform in the respective layers.

57. The semiconductor light emitting device as claimed in claim 39, wherein the first conduction type is an n-type and the second conduction type is a p-type.

58. The semiconductor light emitting device as claimed in claim 39, wherein the second-conduction-type first clad layer consists of two layers of a second-conduction-type upper first clad layer and a second-conduction-type lower first clad layer, the second-conduction-type upper first clad layer and the current block layer form a current injection region, and a contact layer is further provided.

59. The semiconductor light emitting device as claimed in claim 39, wherein the semiconductor light emitting device is a semiconductor laser.

60. The semiconductor light emitting device as claimed in claim 59, wherein the semiconductor laser is a semiconductor laser that operates in a single transverse-mode.

61. A semiconductor light emitting device module comprising the semiconductor light emitting device as claimed in claim 39, and an optical fiber on the side of the light emission end of the semiconductor light emitting device.

62. The semiconductor light emitting device module as claimed in claim 61, wherein the top end of the optical fiber has a light focusing effect and is fabricated to be optically coupled directly to the front facet of the semiconductor light emitting device.
